(19) United States
(12) Patent Application Publication
(10) Pub. No.: US 2020/0356005 A1
(43) Pub. Date: Nov. 12, 2020

(54) NEGATIVE PHOTOSENSITIVE RESIN COMPOSITION, CURED FILM, ELEMENT PROVIDED WITH CURED FILM, DISPLAY DEVICE AND METHOD FOR PRODUCING SAME

(71) Applicant: TORAY INDUSTRIES, INC., Tokyo (JP)

(72) Inventors: Yukinori TOGO, Otsu-shi (JP); Yugo TANIGAKI, Otsu-shi (JP); Kazuto MIYOSHI, Otsu-shi (JP)

(73) Assignee: TORAY INDUSTRIES, INC., Tokyo (JP)

(21) Appl. No.: 16/961,506

(22) PCT Filed: Jan. 15, 2019
(86) PCT No.: PCT/JP2019/000949

§ 371 Date: Jul. 10, 2020

(30) Foreign Application Priority Data
Jan. 31, 2018 (JP) 2018-014719

(51) Int. Cl. G03F 7/075; G03F 7/031; G03F 7/037

(52) U.S. Cl. CPC G03F 7/0757; G02F 1/133512; G03F 7/037; G03F 7/031

(57) ABSTRACT

A problem to be addressed by the present invention is to obtain: a cured film that has high sensitivity, makes it possible to prevent generation of a development residue arising from a pigment, and has excellent heat resistance and light-blocking ability; and a negative photosensitive resin composition that is formed into the cured film. A main object of the present invention is to obtain and use a negative photosensitive resin composition including: (A) an alkali-soluble resin, (B) a radical polymerizable compound, (C) a photo initiator, and (Da) a black pigment; wherein the (A) alkali-soluble resin contains one or more selected from (A1-1) a polyimide, (A1-2) a polyimide precursor, (A1-3) a polybenzoxazole, and (A1-4) a polybenzoxazole precursor; and wherein the (C) photo initiator contains at least (C1) an oxime ester photo initiator and (C2) an α-hydroxyketone photo initiator, wherein the content ratio of the (C1) oxime ester photo initiator is 51 to 95 mass % in the (C) photo initiator, and the content ratio of the (Da) black pigment is 5 to 50 mass % in all the solid contents of the negative photosensitive resin composition.

### TECHNICAL FIELD

The present invention relates to: negative photosensitive resin compositions; cured films, elements, and display devices produced using the resin compositions; and methods of producing such display devices.

### BACKGROUND ART

Among display devices having a thin display, such as smartphones, tablet PCs, and television sets, many products including an organic electroluminescent (hereinafter, may be referred to as “organic EL”) display have been developed in recent years.

An organic EL display has a self-light-emitting element that emits light using energy generated by recombination between electrons injected from a cathode and positive holes injected from an anode. Because of this, any substance that inhibits the movement of electrons or positive holes, any substance that forms an energy level inhibiting the recombination between electrons and positive holes, or any such substance causes an impact such as a decrease in the light-emitting efficiency of a light-emitting element, the deactivation of a light-emitting material, or the like, and thus leads to a decrease in the life of the light-emitting element. A pixel division layer is formed at a position adjacent to the light-emitting element, and thus, degassing or outflow of ion components from the pixel division layer can be a factor causing a decrease in the life of an organic EL display. For this reason, the pixel division layer needs high heat resistance. A known photosensitive resin composition having high heat resistance is a negative photosensitive resin composition produced using a resin such as a polyimide having high heat resistance (see, for example, Patent Literature 1).

In addition, when light in the outside (external light) such as sunlight in the outdoors is incident upon an organic EL display, which has a self-light-emitting element, the external light is reflected toward the viewer, decreasing the visibility and contrast of the organic EL display. Thus, a technology for decreasing such reflection of external light is needed.

Examples of technologies for blocking external light to decrease the reflection of the external light include a black matrix used for a color filter of a liquid crystal display. That is, this is an approach in which reflection of external light is decreased using a light-blocking pixel division layer formed using a photosensitive resin composition containing a coloring agent such as a pigment. However, allowing a photosensitive resin composition to contain a pigment as a coloring agent to impart light-blocking ability to the resin composition causes active rays such as ultraviolet light used during patterning exposure to be blocked accordingly as the amount of the pigment is increased, and thus, the sensitivity during the exposure is decreased. Under such a situation, use of an oxime ester compound as a photo initiator that can improve the sensitivity of a photosensitive resin composition is proposed (see, for example, Patent Literature 2).

### CITATION LIST

### Patent Literature

Patent Literature 1: WO2017/057281

Patent Literature 2: JP2012-189996A

### SUMMARY OF INVENTION

### Technical Problem

However, any photosensitive resin composition containing a conventionally known pigment lacks at least one of sensitivity, heat resistance, and light-blocking ability needed by the resin composition to be used as a material forming a pixel division layer of an organic EL display.

In addition, allowing a photosensitive resin composition to contain a pigment to enhance the light-blocking ability causes the pigment to be peeled off from the cured portion during alkaline development, and a development residue arising from the pigment results in remaining at the opening. Furthermore, the amount of the development residue arising from the pigment increases with an increase in the amount of the pigment, posing a problem in that both the light-blocking ability and the development residue prevention are difficult to achieve at the same time. Furthermore, such a development residue arising from the pigment also poses a problem in that the development residue causes generation of a failure in an organic EL light-emitting element, such as generation of a dark spot in the light-emitting region formed when the organic EL light-emitting element is formed.

In view of this, an object of the present invention is to obtain a negative photosensitive resin composition that has high sensitivity, can prevent generation of a development residue arising from a pigment, and makes it possible to obtain a cured film having excellent heat resistance and light-blocking ability.

### Solution to Problem

A negative photosensitive resin composition according to the present invention is characterized by containing: (A) an alkali-soluble resin, (B) a radical polymerizable compound, (C) a photo initiator, and (Da) a black pigment;

wherein the (A) alkali-soluble resin contains one or more selected from (A1-1) a polyimide, (A1-2) a polyimide precursor, (A1-3) a polybenzoxazole, and (A1-4) a polybenzoxazole precursor; and

wherein the (C) photo initiator contains at least (C1) an oxime ester photo initiator and (C2) an α-hydroxyketone photo initiator, wherein the content ratio of the (C1) oxime ester photo initiator is 51 to 95 mass % in the (C) photo initiator, and the content ratio of the (Da) black pigment is 5 to 50 mass % in all the solid contents of the negative photosensitive resin composition.

### Advantageous Effects of Invention

A negative photosensitive resin composition according to the present invention makes it possible to obtain a cured film that prevents generation of a development residue arising from a pigment, has high sensitivity, and has excellent heat resistance and light-blocking ability.

### BRIEF DESCRIPTION OF DRAWINGS

FIGS. 1 (1) to 1 (7) depict the process chart illustrating the production processes of an organic EL display, using a cured film of a negative photosensitive resin composition according to the present invention.

FIGS. 2 (1) to 2 (13) depict the process chart illustrating the production processes of a liquid crystal display, using a cured film of a negative photosensitive resin composition according to the present invention.

FIGS. 3 (1) to 3 (10) depict the process chart illustrating the production processes of a flexible organic EL display, using a cured film of a negative photosensitive resin composition according to the present invention.

FIGS. 4 (1) to 4 (4) depict the schematic views of an organic EL display device used for evaluation of light-emitting characteristics.

FIG. 5 depicts a schematic view illustrating an organic EL display not having a polarization layer.

FIG. 6 depicts a schematic view illustrating a flexible organic EL display not having a polarization layer.

### DESCRIPTION OF EMBODIMENTS

A negative photosensitive resin composition according to the present invention is characterized by containing: (A) an alkali-soluble resin, (B) a radical polymerizable compound, (C) a photo initiator, and (Da) a black pigment;

wherein the (A) alkali-soluble resin contains one or more selected from (A1-1) a polyimide, (A1-2) a polyimide precursor, (A1-3) a polybenzoxazole, and (A1-4) a polybenzoxazole precursor; and

wherein the (C) photo initiator contains at least (C1) an oxime ester photo initiator and (C2) an α-hydroxyketone photo initiator, wherein the content ratio of the (C1) oxime ester photo initiator is 51 to 95 mass % in the (C) photo initiator, and the content ratio of the (Da) black pigment is 5 to 50 mass % in all the solid contents of the negative photosensitive resin composition.

<(A1) First Resin>

A negative photosensitive resin composition according to the present invention contains at least (A1) a first resin as the (A) alkali-soluble resin. And one or more resin(s) selected from (A1-1) a polyimide, (A1-2) a polyimide precursor, (A1-3) a polybenzoxazole, and (A1-4) a polybenzoxazole precursor is/are contained as the (A1) first resin.

The above-mentioned resin has a structure containing a structure having polarity, and thus strongly interacts with the (Da) black pigment, making it possible to enhance the dispersion stability of the (Da) black pigment.

In the present invention, the (A1-1) polyimide, the (A1-2) polyimide precursor, the (A1-3) polybenzoxazole, and the (A1-4) polybenzoxazole precursor may each be a homo-polymer or may be copolymerized polymer.

From the viewpoint of enhancing the half-tone characteristics, enhancing the heat resistance of the cured film, and enhancing the reliability of the light-emitting element, the (A) alkali-soluble resin is the (A1) first resin preferably containing one or more selected from the group consisting of the (A1-1) polyimide, the (A1-2) polyimide precursor, the (A1-3) polybenzoxazole, and the (A1-4) polybenzoxazole precursor, more preferably containing one or both of the (A1-1) polyimide and the (A1-3) polybenzoxazole, still more preferably containing the (A1-1) polyimide.

<(A1-1) Polyimide and (A1-2) Polyimide Precursor>

Examples of the (A1-2) polyimide precursors include compounds obtained by allowing a tetracarboxylic acid, the corresponding tetracarboxylic dianhydride or tetracarboxylic diester dichloride, or the like to react with a diamine, the corresponding diisocyanate compound or trimethylsilylated diamine, or the like, and such obtained compounds have a residue of the tetracarboxylic acid or a derivative thereof and a residue of the diamine or a derivative thereof. Examples of the (A1-2) polyimide precursor include polyamic acids, polyamic acid esters, polyamic acid amides, and polyisoimides.

The (A1-2) polyimide precursor is a thermosetting resin, and is thermoset at high temperature to be cyclodehydrated, forming a highly heat-resistant imide bond to obtain the (A1-1) polyimide. Thus, the (A1-2) polyimide precursor is a resin the heat resistance of which is enhanced by the cyclodehydration, and accordingly, the precursor is suitable for use in, for example, applications which need to satisfy both the characteristics of the precursor structure that is yet to be cyclodehydrated and the heat resistance of the cured film.

Examples of the (A1-1) polyimide include compounds obtained by cyclodehydrating the above-mentioned polyamic acid, polyamic acid ester, polyamic acid amide, or polyisoimide by heating or reaction with an acid, base, or the like, and such obtained compounds have a residue of the tetracarboxylic acid or a derivative thereof and a residue of the diamine or a derivative thereof.

Allowing a negative photosensitive resin composition to contain the (A1-1) polyimide having a highly heat-resistant imide bond enables the heat resistance of the resulting cured film to be enhanced markedly. Because of this, the polyimide is suitable, for example, in using the cured film in applications that need high heat resistance.

The (A1-1) polyimide used in the present invention preferably contains a structural unit represented by the following general formula (1) from the viewpoint of enhancing the heat resistance of the cured film.

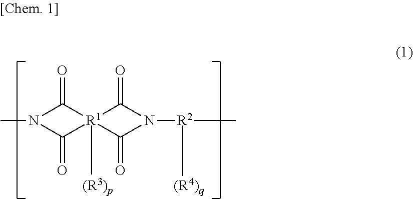

In the general formula (1), R¹ represents a tetravalent to decavalent organic group, and R² represents a divalent to decavalent organic group. R³ and R⁴ independently represent a phenolic hydroxyl group, sulfonic group, mercapto group, or a substituent represented by the general formula (5) or the general formula (6). p represents an integer of 0 to 6, and q represents an integer of 0 to 8.

In the general formula (1), R¹ represents a residue of a tetracarboxylic acid or a derivative thereof, and R² represents a residue of a diamine or a derivative thereof. Examples of tetracarboxylic acid derivatives include tetracarboxylic dianhydrides, tetracarboxylic dichlorides, and tetracarboxylic activated diesters. Examples of diamine derivatives include diisocyanate compounds and trimethylsilylated diamine.

In the general formula (1), R¹ is preferably a tetravalent to decavalent organic group having one or more selected from C₂-C₂₀ aliphatic structures, C₄-C₂₀ alicyclic structures, and C₆-C₃₀ aromatic structures. In addition, R² is preferably a divalent to decavalent organic group having one or more selected from C₂-C₂₀ aliphatic structures, C₄-C₂₀ alicyclic structures, and C₆-C₃₀ aromatic structures. q is preferably 1 to 8. The above-mentioned aliphatic structures, alicyclic structures, and aromatic structures may each have a heteroatom, or may be either an unsubstituted structure or a substituted structure.

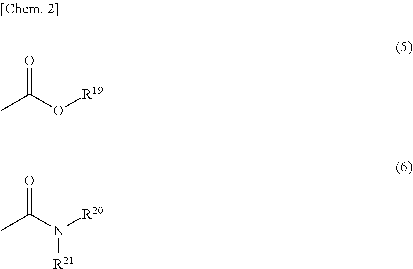

In the general formula (5) and general formula (6), R¹⁹ to R²¹ independently represent hydrogen, a C₁-C₁₀ alkyl group, C₂-C₆ acyl group, or C₆-C₁₅ aryl group. In the general formula (5) and general formula (6), R¹⁹ to R²¹ are each preferably and independently hydrogen, a C₁-C₆ alkyl group, C₂-C₄ acyl group, or C₆-C₁₀ aryl group. The above-mentioned alkyl group, acyl group, and aryl group may each be either an unsubstituted structure or a substituted structure.

The (A1-2) polyimide precursor used in the present invention preferably contains a structural unit represented by the following general formula (3) from the viewpoint of enhancing the heat resistance of the cured film and enhancing the resolution obtained after development.

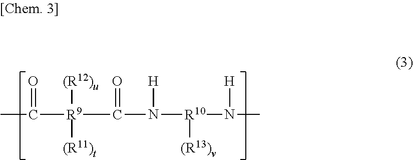

In the general formula (3), R⁹ represents a tetravalent to decavalent organic group, and R¹⁰ represents a divalent to decavalent organic group. R¹¹ represents a substituent represented by the general formula (5) or general formula (6), R¹² represents a phenolic hydroxyl group, sulfonic group, or mercapto group, and R¹³ represents a phenolic hydroxyl group, sulfonic group, mercapto group, or a substituent represented by the general formula (5) or general formula (6). t represents an integer of 2 to 8, u represents an integer of 0 to 6, v represents an integer of 0 to 8, and 2≤t+u≤8 is satisfied.

In the general formula (3), R⁹ represents a residue of a tetracarboxylic acid or a derivative thereof, and R¹⁰ represents a residue of a diamine or a derivative thereof. Examples of tetracarboxylic acid derivatives include tetracarboxylic dianhydrides, tetracarboxylic dichlorides, and tetracarboxylic activated diesters. Examples of diamine derivatives include diisocyanate compounds and trimethylsilylated diamine.

In the general formula (3), R⁹ is preferably a tetravalent to decavalent organic group having one or more selected from C₂-C₂₀ aliphatic structures, C₄-C₂₀ alicyclic structures, and C₆-C₃₀ aromatic structures. In addition, R¹⁰ is preferably a divalent to decavalent organic group having one or more selected from C₂-C₂₀ aliphatic structures, C₄-C₂₀ alicyclic structures, and C₆-C₃₀ aromatic structures. v is preferably 1 to 8. The above-mentioned aliphatic structures, alicyclic structures, and aromatic structures may each have a heteroatom, or may be either an unsubstituted structure or a substituted structure.

<(A1-3) Polybenzoxazole and (A1-4) Polybenzoxazole Precursor>

Examples of the (A1-4) polybenzoxazole precursors include compounds obtained by allowing a dicarboxylic acid, the corresponding dicarboxylic dichloride or dicarboxylic activated diester, or the like to react with a bisaminophenol compound or the like as a diamine, and such obtained compounds have a residue of the dicarboxylic acid or a derivative thereof and a residue of the bisaminophenol compound or a derivative thereof. Examples of the (A1-4) polybenzoxazole precursor include polyhydroxyamides.

The (A1-4) polybenzoxazole precursor is a thermosetting resin, and is thermoset at high temperature to be cyclodehydrated, forming a highly heat-resistant and rigid benzoxazole ring to obtain the (A1-3) polybenzoxazole. Thus, the (A1-4) polybenzoxazole precursor is a resin the heat resistance of which is enhanced by the cyclodehydration, and accordingly, the precursor is suitable for use in, for example, applications which need to satisfy both the characteristics of the precursor structure that is yet to be cyclodehydrated and the heat resistance of the cured film.

Examples of the (A1-3) polybenzoxazole include compounds obtained by cyclodehydrating a dicarboxylic acid and a bisaminophenol compound as a diamine through reaction with a polyphosphoric acid and compounds obtained by cyclodehydrating the above-mentioned polyhydroxyamide by heating or reaction with a phosphoric anhydride, a base, a carbodiimide compound, or the like, and such obtained compounds have a residue of the dicarboxylic acid or a derivative thereof and a residue of the bisaminophenol compound or a derivative thereof.

Allowing a negative photosensitive resin composition to contain the (A1-3) polybenzoxazole having a highly heat-resistant and rigid benzoxazole ring enables the heat resistance of the resulting cured film to be enhanced markedly. Because of this, the polybenzoxazole is suitable, for example, in using the cured film in applications that need high heat resistance.

The (A1-3) polybenzoxazole used in the present invention preferably contains a structural unit represented by the general formula (2) from the viewpoint of enhancing the heat resistance of the cured film.

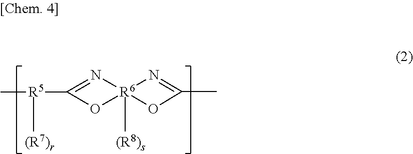

In the general formula (2), R⁵ represents a divalent to decavalent organic group, and R⁶ represents a tetravalent to decavalent organic group having an aromatic structure. R⁷ and R⁸ independently represent a phenolic hydroxyl group, sulfonic group, mercapto group, or a substituent represented by the above-mentioned general formula (5) or general formula (6). r represents an integer of 0 to 8, and s represents an integer of 0 to 6.

In the general formula (2), R⁵ represents a residue of a dicarboxylic acid or a derivative thereof, and R⁶ represents a residue of a bisaminophenol compound or a derivative thereof. Examples of dicarboxylic acid derivatives include dicarboxylic anhydrides, dicarboxylic chlorides, dicarboxylic activated esters, tricarboxylic anhydrides, tricarboxylic chlorides, tricarboxylic activated esters, and diformyl compounds.

In the general formula (2), R⁵ is preferably a divalent to decavalent organic group having one or more selected from C₂-C₂₀ aliphatic structures, C₄-C₂₀ alicyclic structures, and C₆-C₃₀ aromatic structures. In addition, R⁶ is preferably a tetravalent to decavalent organic group having a C₆-C₃₀ aromatic structure. s is preferably 1 to 8. The above-mentioned aliphatic structures, alicyclic structures, and aromatic structures may each have a heteroatom, or may be either an unsubstituted structure or a substituted structure.

The (A1-4) polybenzoxazole precursor used in the present invention preferably contains a structural unit represented by the general formula (4) from the viewpoint of enhancing the heat resistance of the cured film and enhancing the resolution obtained after development.

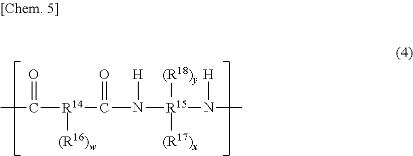

In the general formula (4), R¹⁴ represents a divalent to decavalent organic group, and R¹⁵ represents a tetravalent to decavalent organic group having an aromatic structure. R¹⁶ represents a phenolic hydroxyl group, sulfonic group, mercapto group, or a substituent represented by the above-mentioned general formula (5) or general formula (6), R¹⁷ represents a phenolic hydroxyl group, and R¹⁸ represents a sulfonic group, mercapto group, or a substituent represented by the general formula (5) or general formula (6). w represents an integer of 0 to 8, x represents an integer of 2 to 8, y represents an integer of 0 to 6, and 2≤x+y≤8 is satisfied.

In the general formula (4), R¹⁴ represents a residue of a dicarboxylic acid or a derivative thereof, and R¹⁵ represents a residue of a bisaminophenol compound or a derivative thereof. Examples of dicarboxylic acid derivatives include dicarboxylic anhydrides, dicarboxylic chlorides, dicarboxylic activated esters, tricarboxylic anhydrides, tricarboxylic chlorides, tricarboxylic activated esters, and diformyl compounds.

In the general formula (4), R¹⁴ is preferably a divalent to decavalent organic group having one or more selected from C₂-C₂₀ aliphatic structures, C₄-C₂₀ alicyclic structures, and C₆-C₃₀ aromatic structures. In addition, R¹⁵ is preferably a tetravalent to decavalent organic group having a C₆-C₃₀ aromatic structure. The above-mentioned aliphatic structures, alicyclic structures, and aromatic structures may each have a heteroatom, or may be either an unsubstituted structure or a substituted structure.

<Tetracarboxylic Acid, Dicarboxylic Acid, and Derivatives Thereof>

Examples of tetracarboxylic acids include aromatic tetracarboxylic acids, alicyclic tetracarboxylic acids, and aliphatic tetracarboxylic acids. These tetracarboxylic acids may have a heteroatom besides the oxygen atoms of the carboxy group.

Examples of aromatic tetracarboxylic acids and derivatives thereof include: 1,2,4,5-benzenetetracarboxylic acid (pyromellitic acid), 3,3′,4,4′-biphenyltetracarboxylic acid, 1,2,5,6-naphthalenetetracarboxylic acid, 3,3′,4,4′-benzophenonetetracarboxylic acid, 2,2-bis(3,4-dicarboxyphenyl)propane, 2,2-bis(3,4-dicarboxyphenyl)hexafluoropropane, bis(3,4-dicarboxyphenyl)sulfone, bis(3,4-dicarboxyphenyl)ether, 2,3,5,6-pyridinetetracarboxylic acid, 3,4,9,10-perylenetetracarboxylic acid, and N,N′-bis[5,5′-hexafluoropropane-2,2-diyl-bis(2-hydroxyphenyl)]bis(3,4-dicarboxybenzoic acid amide); and tetracarboxylic dianhydrides, tetracarboxylic dichlorides, and tetracarboxylic activated diesters of these acids and the like.

Examples of alicyclic tetracarboxylic acids and derivatives thereof include: bicyclo[2.2.2]octane-7-ene-2,3,5,6-tetracarboxylic acid, 1,2,4,5-cyclohexanetetracarboxylic acid, 1,2,3,4-cyclobutanetetracarboxylic acid, and 2,3,4,5-tetrahydrofurantetracarboxylic acid; and tetracarboxylic dianhydrides, tetracarboxylic dichlorides, and tetracarboxylic activated diesters of these acids.

Examples of aliphatic tetracarboxylic acids and derivatives thereof include: butane-1,2,3,4-tetracarboxylic acid; and tetracarboxylic dianhydrides, tetracarboxylic dichlorides, and tetracarboxylic activated diesters of the acid.

Dicarboxylic acids and derivatives thereof and tricarboxylic acids and derivatives thereof can preferably be used to obtain the (A1-3) polybenzoxazole and the (A1-4) polybenzoxazole precursor.

Examples of dicarboxylic acids and tricarboxylic acids include aromatic dicarboxylic acids, aromatic tricarboxylic acids, alicyclic dicarboxylic acids, alicyclic tricarboxylic acids, aliphatic dicarboxylic acids, and aliphatic tricarboxylic acids. These dicarboxylic acids and tricarboxylic acids may have a heteroatom other than an oxygen atom, besides the oxygen atoms of the carboxy group.

Examples of aromatic dicarboxylic acids and derivatives thereof include: 4,4′-dicarboxybiphenyl, 2,2′-bis(trifluoromethyl)-4,4′-dicarboxybiphenyl, 4,4′-benzophenonedicarboxylic acid, 2,2-bis(4-carboxyphenyl)hexafluoropropane, 2,2-bis(3-carboxyphenyl)hexafluoropropane, and 4,4′-dicarboxydiphenyl ether; and dicarboxylic anhydrides, dicarboxylic chlorides, dicarboxylic activated esters, and diformyl compounds of these acids and the like.

Examples of aromatic tricarboxylic acids and derivatives thereof include: 1,2,4-benzenetricarboxylic acid, 1,3,5-benzenetricarboxylic acid, 2,4,5-benzophenonetricarboxylic acid, 2,4,4′-biphenyltricarboxylic acid, and 3,3′,4′-tricarboxy diphenyl ether; tricarboxylic anhydrides, tricarboxylic chlorides, and tricarboxylic activated esters of these acids or ethers; and diformyl monocarboxylic acids.

Examples of alicyclic dicarboxylic acids and derivatives thereof include: tetrahydrophthalic acid, 3-methyltetrahydrophthalic acid, 4-methylhexahydrophthalic acid, 1,4-cyclohexanedicarboxylic acid, and 1,2-cyclohexanedicarboxylic acid; and dicarboxylic anhydrides, dicarboxylic chlorides, dicarboxylic activated esters, and diformyl compounds of these acids.

Examples of alicyclic tricarboxylic acids and derivatives thereof include: 1,2,4-cyclohexanetricarboxylic acid, and 1,3,5-cyclohexanetricarboxylic acid; tricarboxylic anhydrides, tricarboxylic chlorides, and tricarboxylic activated esters of these acids; and diformylmonocarboxylic acids.

Examples of aliphatic dicarboxylic acids and derivatives thereof include: itaconic acid, maleic acid, fumaric acid, malonic acid, succinic acid, and hexane-1,6-dicarboxylic acid; and dicarboxylic anhydrides, dicarboxylic chlorides, dicarboxylic activated esters, and diformyl compounds of these acids.

Examples of aliphatic tricarboxylic acids and derivatives thereof include: hexane-1,3,6-tricarboxylic acid and propane-1,2,3-tricarboxylic acid; tricarboxylic anhydrides, tricarboxylic chlorides, and tricarboxylic activated esters of these acids; and diformylmonocarboxylic acids.

<Diamine and Derivative Thereof>

Examples of diamines and derivatives thereof include aromatic diamines, bisaminophenol compounds, alicyclic diamines, alicyclic dihydroxy diamines, aliphatic diamines, and aliphatic dihydroxy diamines. These diamines and derivatives thereof may have a heteroatom besides the nitrogen atom and oxygen atom of the amino group and a derivative thereof.

Examples of aromatic diamines and bisaminophenol compounds and derivatives thereof include: p-phenylenediamine, 1,4-bis(4-aminophenoxy)benzene, 2,2′-dimethyl-4,4′-diaminobiphenyl, 2,2′-bis(trifluoromethyl)-4,4′-diaminobiphenyl, 3,3′-diamino-4,4′-biphenol, 1,5-naphthalenediamine, 9,9-bis(3-amino-4-hydroxyphenyl)fluorene, 2,2-bis(3-amino-4-hydroxyphenyl)propane, 2,2-bis(3-amino-4-hydroxyphenyl)hexafluoropropane, bis(3-amino-4-hydroxyphenyl)sulfone, 4,4′-diaminodiphenyl sulfide, bis(3-amino-4-hydroxyphenyl)ether, 3-sulfonic acid-4,4′-diaminodiphenyl ether, dimercaptophenylenediamine, and N,N′-bis[5,5′-hexafluoropropane-2,2-diyl-bis(2-hydroxyphenyl)]bis(3-aminobenzoic acid amide); and diisocyanate compounds thereof and trimethylsilylated diamines.

Examples of alicyclic diamines and alicyclic dihydroxy diamines and derivatives thereof include: 1,4-cyclohexanediamine, bis(4-aminocyclohexyl)methane, 3,6-dihydroxy-1,2-cyclohexanediamine, and bis(3-hydroxy-4-aminocyclohexyl)methane; and diisocyanate compounds thereof and trimethylsilylated diamines.

Examples of aliphatic diamines and aliphatic dihydroxy diamines and derivatives thereof include: 1,6-hexamethylenediamine and 2,5-dihydroxy-1,6-hexamethylene diamine; diisocyanate compounds thereof and trimethylsilylated diamines.

<End-Capping Agent>

The above-mentioned (A1-1) polyimide, (A1-2) polyimide precursor, (A1-3) polybenzoxazole, and (A1-4) polybenzoxazole precursor may be a resin an end of which is capped with an end-capping agent such as a monoamine, dicarboxylic anhydride, monocarboxylic acid, monocarboxylic chloride, or monocarboxylic activated ester. Allowing an end of the resin to be capped with an end-capping agent makes it possible to enhance the storage stability of a coating liquid of the resin composition containing the end-capped (A1-1) polyimide, (A1-2) polyimide precursor, (A1-3) polybenzoxazole, or (A1-4) polybenzoxazole precursor.

With respect to each of the (A1-1) polyimide, (A1-2) polyimide precursor, (A1-3) polybenzoxazole, and (A1-4) polybenzoxazole precursor, the content ratios of a structural unit derived from each carboxylic acid and a structural unit derived from each amine in the polymer can be determined by any combination of ¹H-NMR, ¹³C-NMR, ¹⁵N-NMR, IR, TOF-MS, elemental analysis, and ash measurement.

<Properties of (A1-1) Polyimide, (A1-2) Polyimide Precursor, (A1-3) Polybenzoxazole and/or (A1-4) Polybenzoxazole Precursor>

The weight-average molecular weight (hereinafter referred to as “Mw”) of each of the (A1-1) polyimide, (A1-2) polyimide precursor, (A1-3) polybenzoxazole, and (A1-4) polybenzoxazole precursor is preferably 1,000 to 500,000 in terms of polystyrene as measured by gel permeation chromatography (hereinafter referred to as “GPC”). The Mw within the above-mentioned range makes it possible to enhance the leveling property for coating and the patterning property for an alkaline developer.

The alkali dissolution rate of the (A) alkali-soluble resin is preferably 50 nm/min. to 12,000 nm/min. The alkali dissolution rate within the above-mentioned range makes it possible to enhance the resolution obtained after development in alkaline development and prevent film loss.

As used herein, an alkali dissolution rate refers to a value of film thickness decrease caused as follows: a solution of a resin dissolved in γ-butyrolactone is applied to a Si wafer and prebaked at 120° C. for four minutes to form a prebaked film having a film thickness of 10 μm 0.5 μm, and the prebaked film is developed with an aqueous solution of 2.38 mass % tetramethylammonium hydroxide at 23±1° C. for 60 seconds and rinsed with water for 30 seconds.

The (A1-1) polyimide and the (A1-2) polyimide precursor can be synthesized by a known method. Examples of such methods include: a method in which a tetracarboxylic dianhydride and a diamine (partially substituted with a monoamine as an end-capping agent) are allowed to react in a polar solvent such as N-methyl-2-pyrrolidone at 80 to 200° C.; a method in which a tetracarboxylic dianhydride (partially substituted with a dicarboxylic anhydride, monocarboxylic acid, monocarboxylic chloride, or monocarboxylic activated ester as an end-capping agent) and a diamine are allowed to react at 80 to 200° C.; and the like.

The (A1-3) polybenzoxazole and the (A1-4) polybenzoxazole precursor can be synthesized by a known method. Examples of such methods include: a method in which a dicarboxylic activated diester and a bisaminophenol compound (partially substituted with a monoamine as an end-capping agent) are allowed to react in a polar solvent such as N-methyl-2-pyrrolidone at 80 to 250° C.; a method in which a dicarboxylic activated diester (partially substituted with a dicarboxylic anhydride, monocarboxylic acid, monocarboxylic chloride, or monocarboxylic activated ester as an end-capping agent) and a bisaminophenol compound are allowed to react at 80 to 250° C.; and the like.

<(A2) Second Resin>

A negative photosensitive resin composition according to the present invention preferably contains (A2) a second resin as the (A) alkali-soluble resin. The (A2) second resin to be contained is preferably (A2-1) a polysiloxane from the viewpoint of enhancing the sensitivity during light exposure and forming a low taper in controlling the pattern shape obtained after development. In the present invention, the (A2-1) polysiloxane may be either a resin obtained by polymerizing a single monomer or a polymer obtained by polymerizing a plurality of monomers.

<(A2-1) Polysiloxane>

Examples of the (A2-1) polysiloxane used in the present invention include a polysiloxane obtained by allowing one or more selected from trifunctional organosilanes, tetrafunctional organosilanes, difunctional organosilanes, and monofunctional organosilanes to be hydrolyzed for dehydration condensation.

The (A2-1) polysiloxane is a thermosetting resin, and is thermoset at high temperature to undergo dehydration condensation, forming a highly heat-resistant siloxane bond (Si—O). Accordingly, allowing a negative photosensitive resin composition to contain the (A2-1) polysiloxane having a highly heat-resistant siloxane bond enables the heat resistance of the resulting cured film to be enhanced. In addition, the (A2-1) polysiloxane is a resin the heat resistance of which is enhanced by the dehydration condensation, and accordingly, the polysiloxane is suitable for use in, for example, applications which need to satisfy both the characteristics of the polysiloxane that is yet to undergo dehydration condensation and the heat resistance of the cured film.

Examples of trifunctional organosilanes include trifunctional organosilanes such as methyltrimethoxysilane, methyltriethoxysilane, n-propyltrimethoxysilane, cyclohexyltrimethoxysilane, 3-glycidoxypropyltrimethoxysilane, 2-(3,4-epoxy cyclohexyl)ethyltrimethoxysilane, 3-[(3-ethyl-3-oxetanyl)methoxy]propyltrimethoxysilane, 3-aminopropyltrimethoxysilane, N-phenyl-3-aminopropyltrimethoxysilane, 3-(4-aminophenyl)propyltrimethoxysilane, 1-(3-trimethoxysilylpropyl)urea, 3-triethoxysilyl-N-(1,3-dimethylbutylidene)propylamine, 3-mercaptopropyltrimethoxysilane, 3-isocyanatepropyltriethoxysilane, 1,3,5-tris(3-trimethoxysilylpropyl)isocyanuric acid, N-t-butyl-2-(3-trimethoxysilylpropyl)succinic acid imide, and N-t-butyl-2-(3-triethoxysilylpropyl)succinic acid imide, and in particular, 2-(3,4-epoxy cyclohexyl)ethyltrimethoxysilane is preferably contained. Containing 2-(3,4-epoxycyclohexyl)ethyltrimethoxysilane makes it possible to enhance the patterning property for alkaline development and enhance the sensitivity during light exposure.

Examples of tetrafunctional organosilanes include: tetrafunctional organosilanes such as tetramethoxysilane, tetraethoxysilane, and tetra-n-propoxysilane; and silicate compounds such as Methyl Silicate 51 (manufactured by Fuso Chemical Co., Ltd.), M Silicate 51 (manufactured by Tama Chemicals Co., Ltd.), and Methyl Silicate 51 (manufactured by Colcoat Co., Ltd.).

Examples of difunctional organosilanes include difunctional organosilanes such as dimethyldimethoxysilane, dimethyldiethoxysilane, diethyldimethoxysilane, diphenyldimethoxysilane, 1,1,3,3-tetramethyl-1,3-dimethoxydisiloxane, and 1,1,3,3-tetraethyl-1,3-dimethoxydisiloxane.

Examples of monofunctional organosilanes include monofunctional organosilanes such as trimethylmethoxysilane, trimethylethoxysilane, tri-n-propylmethoxysilane, (3-glycidoxypropyl)dimethylmethoxysilane, and (3-glycidoxypropyl)dimethylethoxysilane.

<Properties of (A2-1) Polysiloxane>

The Mw of the (A2-1) polysiloxane used in the present invention is preferably 500 or more, more preferably 700 or more, still more preferably 1,000 or more, in terms of polystyrene as measured by GPC. The Mw of 500 or more makes it possible to enhance the resolution obtained after development. On the other hand, the Mw is preferably 100,000 or less, more preferably 50,000 or less, still more preferably 20,000 or less. The Mw of 100,000 or less makes it possible to enhance the leveling property for coating and the patterning property for an alkaline developer.

The (A2-1) polysiloxane can be synthesized by a known method. Examples of such methods include a method in which an organosilane is hydrolyzed in a reaction solvent to undergo dehydration condensation. Examples of methods of hydrolyzing an organosilane for dehydration condensation include a method in which a reaction solvent and water, and further a catalyst, if necessary, are added to a mixture containing an organosilane, and the resulting mixture is stirred under heating at 50 to 150° C., preferably 90 to 130° C., for approximately 0.5 to 100 hours. If necessary, a hydrolysis byproduct (alcohol such as methanol) and a condensation byproduct (water) may be removed by distillation during the stirring under heating.

<(B) Radical Polymerizable Compound>

A negative photosensitive resin composition according to the present invention contains (B) a radical polymerizable compound.

The (B) radical polymerizable compound refers to a compound having a plurality of ethylenic unsaturated double-bond groups in the molecule. During light exposure, radicals generated from the below-mentioned (C) photo initiator causes radical polymerization of the (B) radical polymerizable compound to progress, and thus, the exposed portion of the film of a resin composition is insolubilized against an alkaline developer, enabling a negative pattern to be formed.

The (B) radical polymerizable compound is preferably a compound that has a (meth)acrylic group and is ready to undergo radical polymerization. The (B) radical polymerizable compound is more preferably a compound having two or more (meth)acrylic groups in the molecule from the viewpoint of enhancing the sensitivity during light exposure and enhancing the hardness of the cured film. The double-bond equivalent amount of the (B) radical polymerizable compound is preferably 80 to 800 g/mol from the viewpoint of enhancing the sensitivity during light exposure and forming a low-taper-shaped pattern.

Examples of the (B) radical polymerizable compound include: diethylene glycol di(meth)acrylate, triethylene glycol di(meth)acrylate, tetraethylene glycol di(meth)acrylate, propylene glycol di(meth)acrylate, trimethylolpropane di(meth)acrylate, trimethylolpropane tri(meth)acrylate, ditrimethylolpropane tri(meth)acrylate, ditrimethylolpropane tetra(meth)acrylate, 1,3-butanediol di(meth)acrylate, neopentyl glycol di(meth)acrylate, 1,4-butanediol di(meth)acrylate, 1,6-hexanediol di(meth)acrylate, 1,9-nonanediol di(meth)acrylate, 1,10-decanediol di(meth)acrylate, dimethylol-tricyclodecane di(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, tetrapentaerythritol nona(meth)acrylate, tetrapentaerythritol deca(meth)acrylate, pentapentaerythritol undeca(meth)acrylate, pentapentaerythritol dodeca(meth)acrylate, ethoxylated bisphenol A di(meth)acrylate, 2,2-bis[4-(3-(meth)acryloxy-2-hydroxy propoxy)phenyl]propane, 1,3,5-tris((meth)acryloxyethyl)isocyanuric acid, and 1,3-bis((meth)acryloxyethyl)isocyanuric acid; and acid-modified products thereof. From the viewpoint of enhancing the resolution obtained after development, another compound that is preferably used is one that is obtained by allowing a polybasic acid carboxylic acid or a polybasic carboxylic anhydride to react with a compound obtained by allowing a compound having two or more glycidoxy groups in the molecule and an unsaturated carboxylic acid having an ethylenic unsaturated double-bond group to undergo ring-opening addition reaction.

The amount of the (B) radical polymerizable compound contained in a negative photosensitive resin composition according to the present invention is preferably 15 parts by mass to 65 parts by mass with respect to 100 parts by mass of the total amount of the (A) alkali-soluble resin and the (B) radical polymerizable compound. This range makes it possible to enhance the sensitivity during light exposure and the heat resistance of the cured film and to obtain a low-taper pattern shape.

<(B1) Flexible-chain-containing Aliphatic Radical Polymerizable Compound>

In a negative photosensitive resin composition according to the present invention, the (B) radical polymerizable compound preferably contains (B1) a flexible-chain-containing aliphatic radical polymerizable compound.

The (B1) flexible-chain-containing aliphatic radical polymerizable compound refers to a compound having a plurality of ethylenic unsaturated double-bond groups and a flexible backbone such as an aliphatic chain or an oxyalkylene chain in the molecule, and specific examples of such compounds include a compound having a group represented by the general formula (24) and two or more groups represented by the general formula (25) in the molecule. Such a compound preferably contains three or more groups represented by the general formula (25).

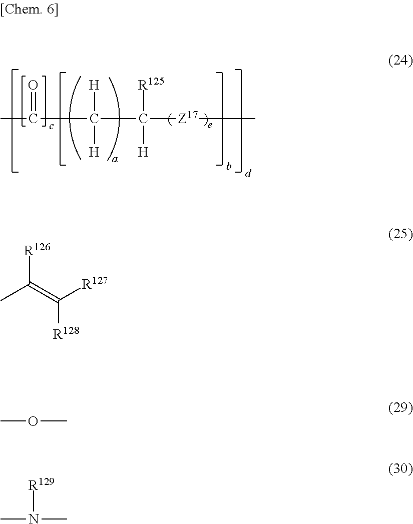

In the general formula (24), R¹²⁵ represents hydrogen or a C₁-C₁₀ alkyl group. Z¹⁷ represents a group represented by the general formula (29) or a group represented by the general formula (30). a represents an integer of 1 to 10, b represents an integer of 1 to 4, c represents 0 or 1, d represents an integer of 1 to 4, and e represents 0 or 1. When c is 0, d is 1. In the general formula (25), R¹²⁶ to R¹²⁸ independently represent hydrogen, a C₁-C₁₀ alkyl group, or C₆-C₁₅ aryl group. In the general formula (30), R¹²⁹ represents hydrogen or a C₁-C₁₀ alkyl group. In the general formula (24), c is preferably 1, and e is preferably 1. In the general formula (25), R¹²⁶ is preferably hydrogen or a C₁-C₄ alkyl group, more preferably hydrogen or a methyl group. R¹²⁷ and R¹²⁸ are each preferably independently hydrogen or a C₁-C₄ alkyl group, more preferably hydrogen. In the general formula (30), R¹²⁹ is preferably hydrogen or a C₁-C₄ alkyl group, more preferably hydrogen or a methyl group. Allowing c to be 1 in the general formula (24) makes it possible to prevent generation of a residue left after development.

Containing the (B1) flexible-chain-containing aliphatic radical polymerizable compound enables curing during light exposure to progress efficiently and enables the sensitivity during light exposure to be enhanced. In addition, containing the (Da) black pigment allows the (Da) black pigment to be fixed to the cured portion of the (B1) flexible-chain-containing aliphatic radical polymerizable compound by cross-linking during the curing, thus making it possible to prevent a residue derived from the (Da) black pigment from being left after development. In addition, a low-taper-shaped pattern can be formed after the thermosetting.

Further, containing particularly (Da-1a) a benzofuranone black pigment as the below-mentioned (Da) black pigment causes a development residue derived from the pigment to be generated owing to the insufficient alkali resistance of the pigment in some cases, as above-mentioned. Even in such a case, containing the (B1) flexible-chain-containing aliphatic radical polymerizable compound makes it possible to prevent the development residue derived from the pigment from being generated.

The (B1) flexible-chain-containing aliphatic radical polymerizable compound is preferably a compound represented by the general formula (27) or the general formula (28).

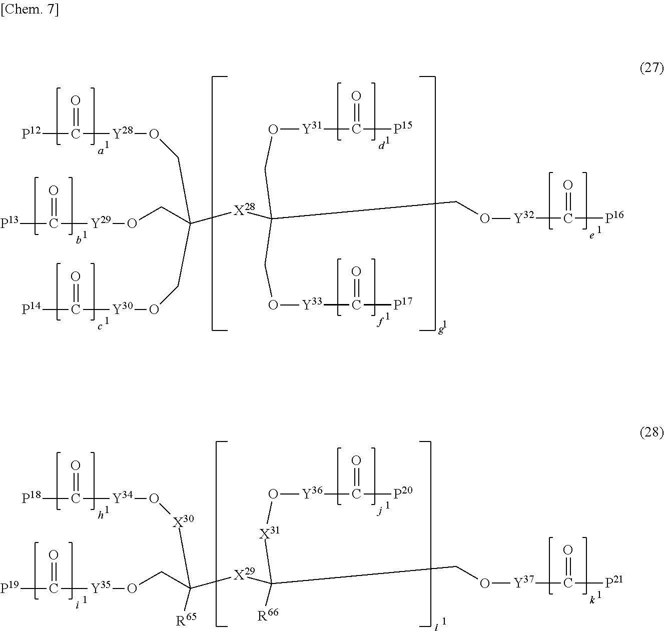

In the general formula (27), X²⁸ represents a divalent organic group. Y²⁸ to Y³³ independently represent a direct bond or a group represented by the general formula (24), and at least one of Y²⁸ to Y³³ is a group represented by the general formula (24). P¹² to P¹⁷ independently represent hydrogen or a group represented by the general formula (25), and at least three of P¹² to P¹⁷ are groups represented by the general formula (25). a¹, b¹, c¹, d¹, e¹, and f¹ independently represent 0 or 1, and g¹ represents an integer of 0 to 10. However, any of P¹² to P¹⁷ which is adjacent to a carbonyl group the number of which is 1 as a¹, b¹, c¹, d¹, e¹, or f¹ is represented by the general formula (25).

In the general formula (27), X²⁸ is preferably a divalent organic group having one or more selected from C₁-C₁₀ aliphatic structures, C₄-C₂₀ alicyclic structures, and C₆-C₃₀ aromatic structures. a¹, b¹, c¹, d¹, e¹, and f¹ are all preferably 1, and g¹ is preferably 0 to 5. The above-mentioned aliphatic structures, alicyclic structures, and aromatic structures may each have a heteroatom, or may be either an unsubstituted structure or a substituted structure. In the general formula (27), preferably two or more, more preferably three or more, still more preferably four or more groups of Y²⁸ to Y³³ are represented by the general formula (24). Allowing two or more of Y²⁸ to Y³³ to be groups represented by the general formula (24) makes it possible to enhance the sensitivity during light exposure and prevent generation of a residue left after development.

In the general formula (28), X²⁹ represents a divalent organic group. X³⁰ and X³¹ independently represent a direct bond or a C₁-C₁₀ alkylene chain. Y³⁴ to Y³⁷ independently represent a direct bond or a group represented by the general formula (24), and at least one of Y³⁴ to Y³⁷ is a group represented by the general formula (24). R⁶⁵ and R⁶⁶ independently represent hydrogen or a C₁-C₁₀ alkyl group. P¹⁸ to P²¹ independently represent hydrogen or a group represented by the general formula (25), and at least three of P¹⁸ to P²¹ are groups represented by the general formula (25). h¹, i¹, j¹, and k¹ independently represent 0 or 1, and l¹ represents an integer of 0 to 10. However, any of P¹⁸ to P²¹ which is adjacent to a carbonyl group the number of which is 1 as h¹, i¹, j¹, or k¹ is represented by the general formula (25).

In the general formula (28), X²⁹ is preferably a divalent organic group having one or more selected from C₁-C₁₀ aliphatic structures, C₄-C₂₀ alicyclic structures, and C₆-C₃₀ aromatic structures. h¹, i¹, j¹, and k¹ are all preferably 1, and l¹ is preferably 0 to 5. The above-mentioned alkyl groups, alkylene chains, aliphatic structures, alicyclic structures, and aromatic structures may each have a heteroatom, or may be either an unsubstituted structure or a substituted structure. In the general formula (28), preferably two or more, more preferably three or more, still more preferably four or more groups of Y³⁴ to Y³⁷ are represented by the general formula (24). Allowing two or more of Y³⁴ to Y³⁷ to be groups represented by the general formula (24) makes it possible to enhance the sensitivity during light exposure and prevent generation of a residue left after development.

The (B1) flexible-chain-containing aliphatic radical polymerizable compound preferably has at least one modified chain selected from the group consisting of lactone modified chains and lactam modified chains. The (B1) flexible-chain-containing aliphatic radical polymerizable compound having a lactone modified chain or a lactam modified chain makes it possible to enhance the sensitivity during light exposure and to prevent generation of a residue left after development, and also enables a low-taper-shaped pattern to be formed after the thermosetting.

As used herein, a lactone modified chain refers to a structural unit represented by the structure of the following general formula (31). The structure of the general formula (31) can be obtained by ring-opening addition of a lactone, or may be introduced by another method. A lactam modified chain refers to a structural unit represented by the structure of the following general formula (32). The structure of the general formula (32) can be obtained by ring-opening addition of a lactam, or may be introduced by another method.

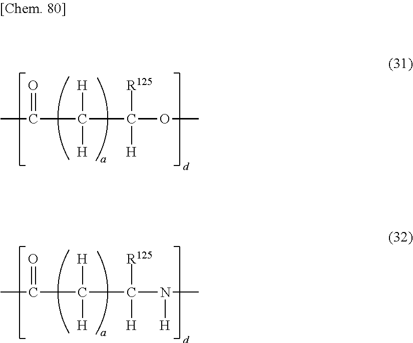

In the general formulae (31) and (32), R¹²⁵, which may be the same or different, represents hydrogen or a C₁-C₁₀ alkyl group. a, which may be the same or different, represents an integer of 1 to 10, and d, which may be the same or different, represents an integer of 1 to 4.

In cases where the (B1) flexible-chain-containing aliphatic radical polymerizable compound is a compound represented by the general formula (27) or a compound represented by the general formula (28) and in cases where, in the general formula (24), c is 1, and e is 1, the (B1) flexible-chain-containing aliphatic radical polymerizable compound has at least one lactone modified chain and/or at least one lactam modified chain.

The number of ethylenic unsaturated double-bond groups contained in the molecule of the (B1) flexible-chain-containing aliphatic radical polymerizable compound is preferably two or more, more preferably three or more, still more preferably four or more. Two or more as the number of ethylenic unsaturated double-bond groups makes it possible to enhance the sensitivity during light exposure. On the other hand, the number of ethylenic unsaturated double-bond groups contained in the molecule of the (B1) flexible-chain-containing aliphatic radical polymerizable compound is preferably twelve or less, more preferably ten or less, still more preferably eight or less, particularly preferably six or less. Twelve or less as the number of ethylenic unsaturated double-bond groups enables a low-taper-shaped pattern to be formed after the thermosetting.

The double-bond equivalent amount of the (B1) flexible-chain-containing aliphatic radical polymerizable compound is preferably 100 g/mol to 800 g/mol. The double-bond equivalent amount in this range makes it possible to enhance the sensitivity during light exposure and prevent generation of a residue left after development. In addition, the amount makes it possible to prevent a change in width in the pattern opening dimensions between before and after the thermosetting.

Examples of the (B1) flexible-chain-containing aliphatic radical polymerizable compound include: ethoxylated dipentaerythritolhexa(meth)acrylate, propoxylated dipentaerythritolhexa(meth)acrylate, ε-caprolactone modified dipentaerythritolhexa(meth)acrylate, δ-valerolactone modified dipentaerythritolhexa(meth)acrylate, γ-butyrolactone modified dipentaerythritolhexa(meth)acrylate, β-propiolactone modified dipentaerythritolhexa(meth)acrylate, ε-caprolactam modified dipentaerythritolhexa(meth)acrylate, ε-caprolactone modified dipentaerythritolpenta(meth)acrylate, ε-caprolactone modified trimethylolpropanetri(meth)acrylate, ε-caprolactone modified ditrimethylolpropanetetra(meth)acrylate, ε-caprolactone modified glycerintri(meth)acrylate, ε-caprolactone modified pentaerythritoltri(meth)acrylate, ε-caprolactone modified pentaerythritoltetra(meth)acrylate, and ε-caprolactone modified 1,3,5-tris((meth)acryloxyethyl)isocyanuric acid; “KAYARAD” (registered trademark) DPEA-12, ditto DPCA-20, ditto DPCA-30, ditto DPCA-60, and ditto DPCA-120 (which are all manufactured by Nippon Kayaku Co., Ltd.); and “NK ESTER” (registered trademark) A-DPH-6E, ditto A-DPH-6P, ditto M-DPH-6E, ditto A-9300-1CL, and ditto A-9300-3CL (which are all manufactured by Shin-Nakamura Chemical Co., Ltd.).

The (B1) flexible-chain-containing aliphatic radical polymerizable compound can be synthesized by a known method.

The amount of the (B1) flexible-chain-containing aliphatic radical polymerizable compound contained in a negative photosensitive resin composition according to the present invention is preferably 5 parts by mass to 45 parts by mass with respect to 100 parts by mass of the total amount of the (A) alkali-soluble resin and the (B) radical polymerizable compound. The amount in this range makes it possible to enhance the sensitivity during light exposure, prevent generation of a residue left after development, and also obtain a cured film having a low-taper-shaped pattern.

<(C) Photo Initiator>

The (C) photo initiator refers to a compound that is caused by light exposure to undergo bond cleavage or reaction, generating a radical.

In a negative photosensitive resin composition according to the present invention, the (C) photo initiator contains (C1) an oxime ester photo initiator and (C2) an α-hydroxyketone photo initiator, wherein the content ratio of the (C1) oxime ester photo initiator is 51 to 95 mass % in the (C) photo initiator.

The (C1) oxime ester photo initiator affords good sensitivity even in cases where the composition contains a light shielding agent particularly as a negative photosensitive resin composition for black matrix formation does. This is considered to be because: the (C1) oxime ester photo initiator has absorption up to a relatively longer wavelength, and thus, generated radicals increase during light exposure and, in addition, the reactivity of the generated activated radicals is high. In addition, the (C2) α-hydroxyketone photo initiator facilitates curing of the surface of a film, and thus, contributes to prevention of deformation of the pattern shape and prevention of generation of a development residue.

Even if a negative photosensitive resin composition according to the present invention contains the below-mentioned (Da) black pigment, allowing the composition to contain the (C1) oxime ester photo initiator and the (C2) α-hydroxyketone photo initiator and allowing the content ratio of the (C1) oxime ester photo initiator to be 51 to 95 mass % makes it possible to impart good sensitivity to the negative photosensitive resin composition and prevent a residue arising from the pigment from being left after development. In addition, even a cured film having an optical density of 1.0 to 3.0 per 1 μm of film thickness and thus having high light-blocking ability makes it possible to impart good sensitivity.

<(C1) Oxime Ester Photo Initiator>

The (C1) oxime ester photo initiator contained in a negative photosensitive resin composition according to the present invention preferably contains one or more selected from the compounds represented by the following general formulae (11) to (13). Containing a compound represented by any one of the following general formulae (11) to (13) and the (A) alkali-soluble resin containing one or more selected from the (A1-1) polyimide, (A1-2) polyimide precursor, (A1-3) polybenzoxazole, and (A1-4) polybenzoxazole precursor makes it possible to enhance the sensitivity during light exposure and also enables a low-taper-shaped pattern to be formed after development. From the viewpoint of enhancing the sensitivity during light exposure, it is more preferable to contain a compound represented by the general formula (11) or a compound represented by the general formula (12).

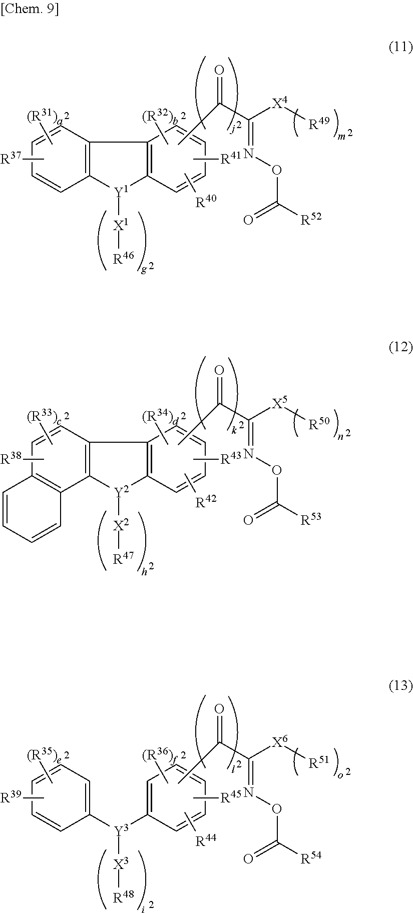

In the general formulae (11) to (13). X¹ to X⁶ independently represent a direct bond, C₁-C₁₀ alkylene group, C₄-C₁₀ cycloalkylene group, or C₆-C₁₅ arylene group. Y¹ to Y³ independently represent carbon, nitrogen, oxygen, or sulfur. R³¹ to R³⁶ independently represent a C₁-C₁₀ alkyl group, C₄-C₁₀ cycloalkyl group, C₆-C₁₅ aryl group, C₁-C₁₀ alkoxy group, or C₁-C₁₀ hydroxyalkyl group. R³⁷ to R³⁹ independently represent a group represented by the general formula (14), a group represented by the general formula (15), a group represented by the general formula (16), a group represented by the general formula (17), or a nitro group. R³⁷ is preferably a nitro group from the viewpoint of enhancing the sensitivity during light exposure. R⁴⁰ to R⁴⁵ independently represent hydrogen, a C₁-C₁₀ alkyl group, C₄-C₁₀ cycloalkyl group, or C₆-C₁₅ aryl group. In addition, R⁴⁰ with R⁴¹, R⁴² with R⁴³, and R⁴⁴ with R⁴⁵ may each form a condensed ring, and in each of these cases, the total number of carbon atoms is 4 to 10. R⁴⁶ to R⁴⁸ independently represent hydrogen, a C₁-C₁₀ alkyl group, C₄-C₁₀ cycloalkyl group, C₆-C₁₅ aryl group, C₁-C₁₀ alkenyl group, C₁-C₁₀ alkoxy group, C₁-C₁₀ haloalkyl group, C₁-C₁₀ haloalkoxy group, or C₂-C₁₀ acyl group. R⁴⁹ to R⁵¹ independently represent hydrogen, a C₁-C₁₀ alkyl group, C₄-C₁₀ cycloalkyl group, C₆-C₁₅ aryl group, C₁-C₁₀ alkoxy group, C₁-C₁₀ haloalkyl group, C₁-C₁₀ haloalkoxy group, C₄-C₁₀ heterocyclic group, C₄-C₁₀ heterocyclic oxy group, C₂-C₁₀ acyl group, or nitro group. R⁵² to R⁵⁴ independently represent hydrogen, a C₁-C₁₀ alkyl group, C₄-C₁₀ cycloalkyl group, or C₆-C₁₅ aryl group. a² represents an integer of 0 to 3; b², d², j², k², and l² independently represent 0 or 1; c² represents an integer of 0 to 5; e² represents an integer of 0 to 4; F represents an integer of 0 to 2; g², h², and i² independently represent 2 when Y¹ to Y³ are each carbon, 1 when Y¹ to Y³ are each nitrogen, and 0 when Y¹ to Y³ are each oxygen or sulfur; and m², n², and o² independently represent an integer of 1 to 10. When Y¹ is nitrogen, when R³⁷ is a nitro group, and when X⁴ is a C₆-C₁₅ arylene group, however, R⁴⁹ represents hydrogen, a C₁-C₁₀ alkyl group, C₄-C₁₀ cycloalkyl group, C₆-C₁₅ aryl group, C₁-C₁₀ haloalkyl group, C₁-C₁₀ haloalkoxy group, C₄-C₁₀ heterocyclic group, C₄-C₁₀ heterocyclic oxy group, C₂-C₁₀ acyl group, or nitro group.

In the general formulae (11) to (13), X¹ to X⁶ is preferably independently a C₁-C₁₀ alkylene group from the viewpoint of enhancing solubility in a solvent, and preferably a C₆-C₁₅ arylene group from the viewpoint of enhancing the sensitivity during light exposure. Examples of C₄-C₁₀ rings formed in R⁴⁰ to R⁴⁵ include benzene rings and cyclohexane rings. From the viewpoint of enhancing solubility in a solvent, R⁴⁶ to R⁴⁸ are preferably independently a C₁-C₁₀ alkyl group, C₄-C₁₀ cycloalkyl group, C₁-C₁₀ haloalkyl group, or C₁-C₁₀ haloalkoxy group, more preferably a C₁-C₁₀ fluoroalkyl group or C₁-C₁₀ fluoroalkoxy group. From the viewpoint of enhancing the sensitivity during light exposure and forming a low-taper-shaped pattern after development, R⁴⁶ to R⁴⁸ are preferably independently a C₁-C₁₀ haloalkyl group, C₁-C₁₀ haloalkoxy group, or C₂-C₁₀ acyl group, more preferably a C₁-C₁₀ fluoroalkyl group or C₁-C₁₀ fluoroalkoxy group. From the viewpoint of enhancing solubility in a solvent, R⁴⁹ to R⁵¹ are preferably independently a C₄-C₁₀ cycloalkyl group, C₁-C₁₀ haloalkyl group, or C₁-C₁₀ haloalkoxy group, more preferably a C₁-C₁₀ fluoroalkyl group or C₁-C₁₀ fluoroalkoxy group. From the viewpoint of enhancing the sensitivity during light exposure and forming a low-taper-shaped pattern after development, R⁴⁹ to R⁵¹ are preferably independently a C₁-C₁₀ haloalkyl group, C₁-C₁₀ haloalkoxy group, C₄-C₁₀ heterocyclic group, C₄-C₁₀ heterocyclic oxy group, C₂-C₁₀ acyl group, or nitro group, more preferably a C₁-C₁₀ fluoroalkyl group or C₁-C₁₀ fluoroalkoxy group. From the viewpoint of enhancing the sensitivity during light exposure, R⁵² to R⁵⁴ are preferably independently hydrogen or a C₁-C₁₀ alkyl group, more preferably hydrogen or a C₁-C₄ alkyl group, still more preferably methyl. j², k², and l² are each preferably 0 from the viewpoint of enhancing the sensitivity during light exposure.

From the viewpoint of enhancing the sensitivity during light exposure, controlling the shape of a pattern into a low taper after development, preventing a change in width in the pattern opening dimensions before and after the thermosetting, and enhancing the half-tone characteristics, the (C₁) oxime ester photo initiator to be preferably used is a compound represented by the general formula (11) or a compound represented by the general formula (12). In this case, Y¹ and Y² in the general formula (11) and general formula (12) are each preferably carbon or nitrogen. In addition, R⁴⁶ or R⁴⁷ are each preferably a C₁-C₁₀ alkenyl group, more preferably a C₁-C₆ alkenyl group. R⁴⁹ or R⁵⁰ are each preferably a C₁-C₁₀ alkenyl group, more preferably a C₁-C₆ alkenyl group. This is considered to be because containing an alkenyl group makes it possible to further enhance compatibility between the resin and the initiator, allowing UV curing to efficiently progress also in the deep portion of a film during light exposure.

Examples of alkenyl groups include a vinyl group, 1-methylethenyl group, allyl group, 1-methyl-2-propenyl group, 2-methyl-2-propenyl group, 1-propenyl group, 2-methyl-1-propenyl group, 1-butenyl group, 2-butenyl group, 2-methyl-2-butenyl group, 3-methyl-2-butenyl group, 2,3-dimethyl-2-butenyl group, 3-butenyl group, and cinnamyl group.

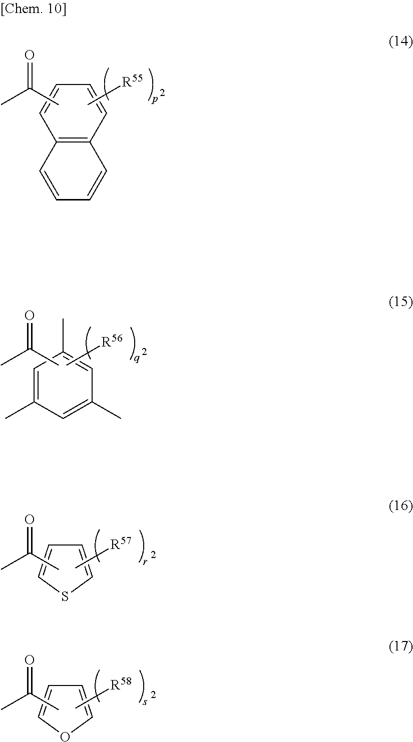

In the general formulae (14) to (17), R⁵⁵ to R⁵⁸ independently represent a C₁-C₁₀ alkyl group, C₄-C₁₀ cycloalkyl group, C₆-C₁₅ aryl group, C₁-C₁₀ alkoxy group, or C₁-C₁₀ hydroxyalkyl group. p² represents an integer of 0 to 7, q² represents an integer of 0 to 2, and r² and s² independently represent an integer of 0 to 3.

Examples of the (C1) oxime ester photo initiator include 1-phenylpropane-1,2-dione-2-(O-ethoxycarbonyl)oxime, 1-phenylbutane-1,2-dione-2-(O-methoxycarbonyl)oxime, 1,3-diphenylpropane-1,2,3-trione-2-(O-ethoxycarbonyl)oxime, 1-[4-(phenylthio)phenyl]octane-1,2-dione-2-(O-benzoyl)oxime, 1-[4-[4-carboxyphenylthio]phenyl]propane-1,2-dione-2-(O-acetyl)oxime, 1-[4-[4-(2-hydroxyethoxy)phenylthio]phenyl]propane-1,2-dione-2-(O-acetyl)oxime, 1-[4-(phenylthio)phenyl]-3-cyclopentylpropane-1,2-dione-2-(O-benzoyl)oxime, 1-[4-(phenylthio)phenyl]-2-cyclopentylethane-1,2-dione-2-(O-acetyl)oxime, 1-[9,9-diethylfluorene-2-yl]propane-1,2-dione-2-(O-acetyl)oxime, 1-[9,9-di-n-propyl-7-(2-methylbenzoyl)-fluorene-2-yl]ethanone-1-(O-acetyl)oxime, 1-[9-ethyl-6-(2-methylbenzoyl)-9H-carbazole-3-yl]ethanone-1-(0-acetyl)oxime, 1-[9-ethyl-6-[2-methyl-4-[1-(2,2-dimethyl-1,3-dioxolane-4-yl)methyloxy]benzoyl]-9H-carbazole-3-yl]ethanone-1-(O-acetyl)oxime, 1-[9-ethyl-6-(2-methylbenzoyl)-9H-carbazole-3-yl]-3-cyclopentylpropane-1-one-1-(O-acetyl)oxime, and 1-(9-ethyl-6-nitro-9H-carbazole-3-yl)-1-[2-methyl-4-(1-methoxypropane-2-yloxy)phenyl]methanone-1-(O-acetyl)oxime. Preferable examples include compounds (O-1 and O-2) having a structure shown below.

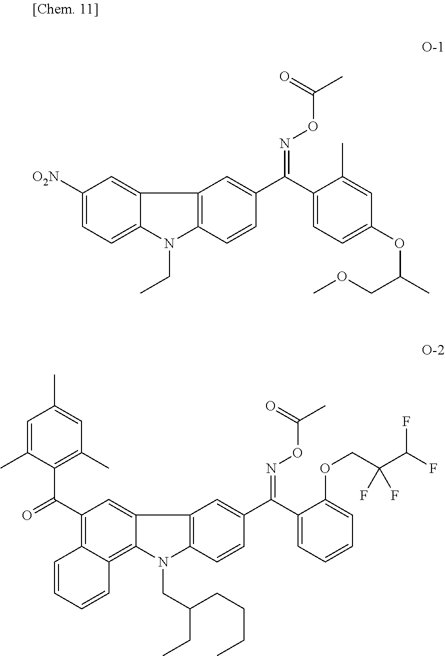

The content ratio of the (C1) oxime ester photo initiator to the (C) photo initiator in a negative photosensitive resin composition according to the present invention is 51 to 95 mass %, preferably 60 mass % or more, more preferably 70 mass % or more. The content ratio of 51 mass % or more makes it possible to enhance the sensitivity during light exposure. On the other hand, the content ratio of the (C1) oxime ester photo initiator to the (C) photo initiator is preferably 90 mass % or less, more preferably 85 mass % or less. The content ratio of 95 mass % or less makes it possible to obtain a low-taper-shaped pattern and enhance the resolution obtained after development.

<(C2) α-Hydroxyketone Photo Initiator>

In a negative photosensitive resin composition according to the present invention, the (C) photo initiator contains (C2) an α-hydroxyketone photo initiator. The (C2) α-hydroxyketone photo initiator is preferably a compound having a structure represented by the following general formula (18). Having a structure of the following general formula (18) enables the heat resistance of the aromatic group to enhance the heat resistance of the cured film.

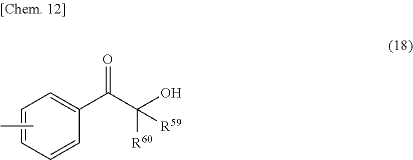

In the general formula (18), R⁵⁹ and R⁶⁰ independently represent hydrogen, a C₁-C₁₀ alkyl group optionally having a substituent, C₂-C₆ acyl group optionally having a substituent, or C₆-C₁₅ aryl group optionally having a substituent. In addition, R⁵⁹ and R⁶⁰ may form a ring therebetween, and in this case, represent a C₃-C₂₀ cycloalkyl group optionally having a substituent.

In addition, the (C2) α-hydroxyketone photo initiator is preferably a compound one molecule of which has two or more α-hydroxyketone structures from the viewpoint of enhancing the sensitivity and preventing a development residue. The compound one molecule of which has two or more α-hydroxyketone structures preferably contains one or more selected from the compounds represented by one of the following general formulae (19) and (20). Having a structure of the following general formula (19) or (20) increases the molecular weight and increases the number of functional groups contained in one molecule, making it possible to prevent generation of a residue left after development and obtain a low-taper-shaped pattern.

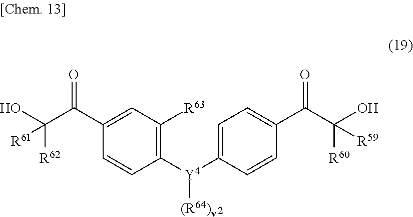

In the general formula (19), R⁵⁹ to R⁶² independently represent hydrogen, a C₁-C₁₀ alkyl group optionally having a substituent, C₂-C₆ acyl group optionally having a substituent, or C₆-C₁₅ aryl group optionally having a substituent. In addition, R⁵⁹ with R⁶⁰ and R⁶¹ with R⁶² may each form a ring, and in this case, represent a C₃-C₂₀ cycloalkyl group optionally having a substituent. Y⁴ represents a carbon atom or oxygen atom, and v² represents 0 or 2. When Y⁴ is an oxygen atom, v² is 0, and when Y⁴ is a carbon atom, v² is 2. R⁶³ and R⁶⁴ independently represent hydrogen, a C₁-C₁₀ alkyl group optionally having a substituent, C₂-C₆ acyl group optionally having a substituent, or C₆-C₁₅ aryl group optionally having a substituent. When Y⁴ is a carbon atom, R⁶³ and R⁶⁴ may form a ring, and in this case, represent a C₃-C₂₀ cycloalkyl group optionally having a substituent. When v² is 2, R⁶⁴ may be the same or different.

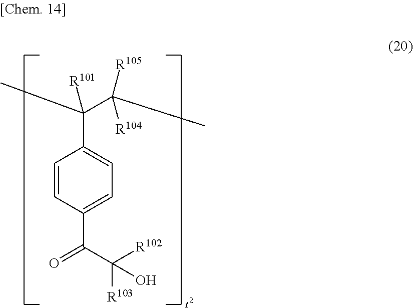

In the general formula (20), R¹⁰¹ to R¹⁰⁵ independently represent hydrogen, a C₁-C₁₀ alkyl group optionally having a substituent, C₂-C₆ acyl group optionally having a substituent, or C₆-C₁₅ aryl group optionally having a substituent. t² represents an integer of 2 to 10000.

Examples of α-hydroxyketone photo initiators include 1-(4-isopropylphenyl)-2-hydroxy-2-methylpropane-1-one, 2-hydroxy-2-methyl-1-phenylpropane-1-one, 1-hydroxycyclohexylphenylketone, 1-[4-(2-hydroxyethoxy)phenyl]-2-hydroxy-2-methylpropane-1-one, 2-hydroxy-1-[4-[4-(2-hydroxy-2-methylpropionyl)benzyl]phenyl]-2-methylpropane-1-one, 2-hydroxy-1-[4-[4-(2-hydroxy-2-methylpropionyl)phenoxy]phenyl]-2-methylpropane-1-one (for example, “Esacure” (registered trademark) KIP 160 (manufactured by IGM Resins B.V.)), 2-hydroxy-1-[4-[5-(2-hydroxy-2-methylpropionyl)-1,3,3-trimethyl 2,3-dihydro-1H-indene-1-yl]phenyl]-2-methylpropane-1-one (for example, “Esacure” (registered trademark) ONE (manufactured by IGM Resins B.V.)), oligo[2-hydroxy-2-methyl-1[4-(1-methylvinyl)phenyl]propanone] (for example, “Esacure” (registered trademark) KIP 150 (manufactured by IGM Resins B.V.), and TR-PPI-101 (manufactured by Changzhou Tronly New Electronic Materials Co., Ltd.)). From the viewpoint of preventing generation of a residue, photo initiators preferable among these are 2-hydroxy-1-[4-[4-(2-hydroxy-2-methylpropionyl)benzyl]phenyl]-2-methylpropane-1-one, 2-hydroxy-1-[4-[4-(2-hydroxy-2-methylpropionyl)phenoxy]phenyl]-2-methylpropane-1-one (for example, “Esacure” (registered trademark) KIP 160 (manufactured by IGM Resins B.V.)), 2-hydroxy-1-[4-[5-(2-hydroxy-2-methylpropionyl)-1,3,3-trimethyl 2,3-dihydro-1H-indene-1-yl]phenyl]-2-methylpropane-1-one (for example, “Esacure” (registered trademark) ONE (manufactured by IGM Resins B.V.)), oligo[2-hydroxy-2-methyl-1[4-(1-methylvinyl)phenyl]propanone] (for example, “Esacure” (registered trademark) KIP 150 (manufactured by IGM Resins B.V.), and TR-PPI-101 (manufactured by Changzhou Tronly New Electronic Materials Co., Ltd.)).

The content ratio of the (C2) α-hydroxyketone photo initiator to the (C) photo initiator in a negative photosensitive resin composition according to the present invention is preferably 5 mass % or more, more preferably 10 mass % or more, still more preferably 15 mass % or more. The content ratio of 5 mass % or more makes it possible to prevent generation of a residue left after development. On the other hand, the content ratio of the (C2) α-hydroxyketone photo initiator to the (C) photo initiator is preferably 49 mass % or less, more preferably 40 mass % or less, still more preferably 30 mass % or less. The content ratio of 49 mass % or less makes it possible to maintain the sensitivity of the negative photosensitive resin composition well.

With respect to the (C) photo initiator in a negative photosensitive resin composition according to the present invention, it is preferable that the content ratio of the (C1) oxime ester photo initiator is 60 mass % or more and that the content ratio of the (C2) α-hydroxyketone photo initiator is 40 mass % or less, it is more preferable that the content ratio of the (C1) oxime ester photo initiator is 70 mass % or more and that the content ratio of the (C2) α-hydroxyketone photo initiator is 30 mass % or less. Allowing the content ratio of the (C1) oxime ester photo initiator to be 60 mass % or more and allowing the content ratio of the (C2) α-hydroxyketone photo initiator to be 40 mass % or less makes it possible to maintain the sensitivity of the negative photosensitive resin composition better. It is preferable that the content ratio of the (C1) oxime ester photo initiator is 85 mass % or less and that the content ratio of the (C2) α-hydroxyketone photo initiator is 15 mass % or more, it is more preferable that the content ratio of the (C1) oxime ester photo initiator is 75 mass % or less and that the content ratio of the (C2) α-hydroxyketone photo initiator is 25 mass % or more. Allowing the content ratio of the (C1) oxime ester photo initiator to be 85 mass % or less and allowing the content ratio of the (C2) α-hydroxyketone photo initiator to be 15 mass % or more makes it possible to further prevent generation of a residue left after development and obtain a low-taper-shaped pattern.

In addition, the (C) photo initiator to be contained may be a photo initiator other than the (C1) oxime ester photo initiator and the (C2) α-hydroxyketone photo initiator.

Preferable examples of the (C) photo initiator other than the (C1) oxime ester photo initiator and the (C2) α-hydroxyketone photo initiator include benzylketal photo initiators, α-aminoketone photo initiators, acylphosphine oxide photo initiators, biimidazole photo initiators, acridine photo initiators, titanocene photo initiators, benzophenone photo initiators, acetophenone photo initiators, aromatic ketoester photo initiators, and benzoate photo initiators; α-aminoketone photo initiators, acylphosphine oxide photo initiators, biimidazole photo initiators, acridine photo initiators, and benzophenone photo initiators are more preferable from the viewpoint of enhancing the sensitivity during light exposure; and α-aminoketone photo initiators, acylphosphine oxide photo initiators, and biimidazole photo initiators are still more preferable.

Examples of benzylketal photo initiators include 2,2-dimethoxy-1,2-diphenylethane-1-one.

Examples of α-aminoketone photo initiators include 2-methyl-1-[4-(methylthio)phenyl]-2-morpholinopropane-1-one, 2-benzyl-2-dimethylamino-1-(4-morpholinophenyl)-butane-1-one, 2-dimethylamino-2-(4-methylbenzyl)-1-(4-morpholinophenyl)-butane-1-one, and 3,6-bis(2-methyl-2-morpholinopropionyl)-9-octyl-9H-carbazole.

Examples of acylphosphine oxide photo initiators include 2,4,6-trimethylbenzoyl-diphenylphosphine oxide, bis(2,4,6-trimethylbenzoyl)-phenylphosphine oxide, and bis(2,6-dimethoxybenzoyl)-(2,4,4-trimethylpentyl)phosphine oxide.

Examples of acridine photo initiators include 1,7-bis(acridine-9-yl)-n-heptane.

Examples of titanocene photo initiators include bis(η⁵-2,4-cyclopentadiene-1-yl)-bis[2,6-difluoro-3-(1H-pyrrole-1-yl)phenyl]titanium (IV), and bis(η⁵-3-methyl-2,4-cyclopentadiene-1-yl)-bis(2,6-difluorophenyl)titanium (IV).

Examples of benzophenone photo initiators include benzophenone, 4,4′-bis(dimethylamino)benzophenone, 4,4′-bis(diethylamino)benzophenone, 4-phenylbenzophenone, 4,4-dichlorobenzophenone, 4-hydroxybenzophenone, alkylated benzophenone, 3,3′,4,4′-tetrakis(t-butylperoxycarbonyl)benzophenone, 4-methylbenzophenone, dibenzylketone, and fluorenone.

Examples of biimidazole photo initiators include 2,2′-bis(2-chlorophenyl)-4,4′,5,5′-tetraphenyl-1,2′-biimidazole, 2,2′,5-tris(2-chlorophenyl)-4-(3,4-dimethoxyphenyl)-4′,5′-diphenyl-1,2′-biimidazole,2,2′,5-tris(2-fluorophenyl)-4-(3,4-dimethoxyphenyl)-4′,5′-diphenyl-1,2′-biimidazole,2,2′-bis(2,4-dichlorophenyl)-4,4′,5,5′-tetraphenyl-1,2′-biimidazole, and 2,2′-bis(2-methoxyphenyl)-4,4′,5,5′-tetraphenyl-1,2′-biimidazole.

Examples of acetophenone photo initiators include 2,2-diethoxyacetophenone, 2,3-diethoxyacetophenone, 4-t-butyldichloroacetophenone, benzalacetophenone, and 4-azidobenzalacetophenone.

Examples of aromatic ketoester photo initiators include methyl 2-phenyl-2-oxyacetate.

Examples of benzoate photo initiators include ethyl 4-dimethylaminobenzoate, (2-ethyl)hexyl 4-dimethylaminobenzoate, ethyl 4-diethylaminobenzoate, and methyl 2-benzoylbenzoate.

In addition, containing the (C) photo initiator in not less than a specific amount makes it possible to prevent a change in width of the pattern opening dimensions between before and after the thermosetting. This is considered to be due to an increase in the amount of generation of radicals derived from the (C) photo initiator during light exposure. On the other hand, the inference is that increasing the amount of generation of radicals during light exposure increases the probability of collision between the generated radicals and the ethylenic unsaturated double-bond groups in the (B) radical polymerizable compound, facilitates the curing, enhances the cross-linking density, and thus, prevents the reflow at the taper portion of the pattern and the edge of the pattern during the thermosetting, thus making it possible to prevent a change in width of the pattern opening dimensions between before and after the thermosetting.

The amount of the (C) photo initiator contained in a negative photosensitive resin composition according to the present invention is preferably 1 part by mass or more, more preferably 2 parts by mass or more, still more preferably 3 parts by mass or more, particularly preferably 5 parts by mass or more, with respect to 100 parts by mass of the total amount of the (A) alkali-soluble resin and the (B) radical polymerizable compound. The amount of 1 part by mass or more makes it possible to enhance the sensitivity during light exposure. In addition, the amount of the (C1) photo initiator is preferably 10 parts by mass or more, more preferably 12 parts by mass or more, still more preferably 14 parts by mass or more, particularly preferably 15 parts by mass or more, from the viewpoint of controlling the width of the pattern opening dimensions. The amount of 10 parts by mass or more makes it possible to prevent a change in width in the pattern opening dimensions between before and after the thermosetting. On the other hand, the amount of the (C) photo initiator is preferably 30 parts by mass or less, more preferably 25 parts by mass or less, still more preferably 22 parts by mass or less, particularly preferably 20 parts by mass or less. The amount of 30 parts by mass or less makes it possible to enhance the resolution obtained after development and obtain a cured film having a low-taper-shaped pattern.

<(Da) Black Pigment>

A negative photosensitive resin composition according to the present invention contains (Da) a black pigment.

The (Da) black pigment refers to a pigment that absorbs light having a wavelength of visible light and is thereby colored black. The black pigment may be a mixture of a plurality of pigments that assumes a black color. Containing the (Da) black pigment allows a film of a resin composition to be colored black and have excellent hiding power, and thus, can enhance the light-blocking ability of the film of the resin composition. The content ratio of the (Da) black pigment is 5 to 50 mass % in all the solid contents of a negative photosensitive resin composition according to the present invention except a solvent.

The black color for the (Da) black pigment refers to any Color Index Generic Number (hereinafter refers to as “C. I. number”) that contains “BLACK”. A pigment which is a mixture or has no C. I. number is regarded as black in cases where the resulting cured film is black. Regarding the expression “regarded as black in cases where the resulting cured film is black”, a cured film of the resin composition containing the (Da) black pigment is examined to obtain a transmission spectrum and the transmittance per 1.0 μm of film thickness at a wavelength of 550 nm is assigned to the Lambert-Beer's equation to give a film thickness in the range of from 0.1 to 1.5 μm where the transmittance at a wavelength of 550 nm is 10%. The expression applies when the transmittance in the wavelength range of from 450 to 650 nm is 25% or less in the converted transmission spectrum.

The transmittance spectrum of a cured film can be determined by the following method. A resin composition containing at least arbitrary binder resin and the (Da) black pigment is prepared in such a manner that the content ratio of the (Da) black pigment is 35 mass % in all the solid contents of the resin composition. A film of the resin composition is applied to a TEMPAX glass substrate (manufactured by AGC Techno Glass Co., Ltd.), prebaked at 110° C. for two minutes, and formed into a film to obtain a prebaked film. Next, a high-temperature inert gas oven (INH-9CD-S; manufactured by Koyo Thermo Systems Co., Ltd.) is used to thermoset the prebaked film under a nitrogen atmosphere at 250° C. for 60 minutes to produce a cured film having a film thickness of 1.0 μm and composed of the resin composition containing the (Da) black pigment (hereinafter referred to as a “black-pigment-containing cured film”). In addition, a resin composition containing the binder resin and containing no (Da) black pigment is prepared, applied to a TEMPAX glass substrate, prebaked, and thermoset in the same manner as above-mentioned to produce a cured film having a film thickness of 1.0 μm and composed of the resin composition containing no (Da) black pigment (hereinafter referred to as a “blank cured film”). An ultraviolet and visible spectrophotometer (MultiSpec-1500; manufactured by Shimadzu Corporation) is used to first make a measurement on a TEMPAX glass substrate on which the blank cured film is formed to have a film thickness of 1.0 μm, and the ultraviolet visible absorption spectrum is used as a blank. Next, the produced TEMPAX glass substrate having a black-pigment-containing cured film formed thereon is subjected to measurement with a single beam to determine a transmittance per 1.0 μm of film thickness at a wavelength of 450 to 650 nm and then calculate the transmittance of the black-pigment-containing cured film from the difference from the blank.

For a negative photosensitive resin composition according to the present invention, the (Da) black pigment preferably contains one or both of (Da-1) a black organic pigment and (Da-3) a mixture of two or more pigments of different colors mixed to assume a black color.

The (Da) black pigment preferably has a number-average particle size of 1 to 1,000 nm. The (Da) black pigment having a number-average particle size of 1 to 1,000 nm makes it possible to enhance the light-blocking ability of the film of the resin composition and the dispersion stability of the (Da) black pigment.

Here, the number-average particle size of the (Da) black pigment can be determined using a submicron particle size distribution analyzer (N4-PLUS; manufactured by Beckman Coulter, Inc.) or a zeta-potential particle size and molecular weight analyzer (Zetasizer Nano-ZS; manufactured by Sysmex Corporation) to measure laser scattering caused by the Brownian motion of the (Da) black pigment in a solution (a dynamic light scattering method).

In addition, the content ratio of the (Da) black pigment in all the solid contents of a negative photosensitive resin composition according to the present invention except a solvent is preferably 8 mass % or more, more preferably 10 mass % or more, still more preferably 15 mass % or more, particularly preferably 20 mass % or more. The content ratio of 8 mass % or more makes it possible to enhance light-blocking ability, colorability, or toning ability. In addition, the content ratio of the (Da) black pigment is preferably 65 mass % or less, more preferably 60 mass % or less, still more preferably 55 mass % or less, particularly preferably 50 mass % or less. The content ratio of 65 mass % or less makes it possible to enhance the sensitivity during light exposure.

<(Da-1) Black Organic Pigment and (Da-3) Mixture of Two or More Pigments of Different Colors>

For a negative photosensitive resin composition according to the present invention, the (Da) black pigment preferably contains one or both of (Da-1) a black organic pigment and (Da-3) a mixture of two or more coloring pigments of different colors mixed to assume a black color.

The (Da-1) black organic pigment refers to an organic pigment that absorbs light having a wavelength of visible light and is thereby colored black. Containing the (Da-1) black organic pigment allows a film of a resin composition to be colored black and have excellent hiding power, and thus, can enhance the light-blocking ability of the film of the resin composition. Furthermore, being an organic material causes chemical structure change or functional conversion to adjust the transmittance spectrum or absorption spectrum of the film of the resin composition, for example, to transmit or block desired light having a specific wavelength, making it possible to enhance the toning ability. In addition, the (Da-1) black organic pigment has excellent insulation properties and low dielectricity compared with general inorganic pigments, and thus, containing the (Da-1) black organic pigment makes it possible to enhance the resistance value of the film. In particular, using such a film as an insulation layer or the like, for example, a pixel division layer of an organic EL display makes it possible to prevent light-emitting failure and the like and enhance reliability.

Examples of the (Da-1) black organic pigment include anthraquinone black pigments, benzofuranone black pigments, perylene black pigments, aniline black pigments, azo black pigments, azomethine black pigments, and carbon black. Examples of carbon blacks include channel black, furnace black, thermal black, acetylene black, and lamp black. Channel black is preferable from the viewpoint of light-blockingability.

The (Da-3) mixture of two or more pigments of different colors mixed to assume a black color refers to a pigment mixture obtained by combining two or more pigments of different colors selected from pigments of red, orange, yellow, green, blue, and purple to create a black color in a pseudo manner. Containing a mixture of two or more pigments of different colors allows a film of a resin composition to be blackened and have excellent hiding power, and thus, can enhance the light-blocking ability of the film of the resin composition. Furthermore, mixing two or more pigments of different colors makes it possible to adjust the transmittance spectrum or absorption spectrum of the film of the resin composition, for example, to transmit or block desired light having a specific wavelength, making it possible to enhance the toning ability.

A known pigment can be used as a black organic pigment, red pigment, orange pigment, yellow pigment, green pigment, blue pigment, purple pigment, or the like.

<(Da-1a) Benzofuranone Black Pigment, (Da-1b) Perylene Black Pigment, and (Da-1c) Azo Black Pigment>

For a negative photosensitive resin composition according to the present invention, the (Da-1) black organic pigment is preferably one or more selected from the group consisting of (Da-1a) benzofuranone black pigments, (Da-1b) perylene black pigments, and (Da-1c) azo black pigments, more preferably (Da-1a) a benzofuranone black pigment, from the viewpoint of light-blocking ability and insulation properties per unit content ratio.

Containing one or more selected from the group consisting of (Da-1a) benzofuranone black pigments, (Da-1b) perylene black pigments, and (Da-1c) azo black pigments allows a film of a resin composition to be blackened and have excellent hiding power, and thus, can enhance the light-blocking ability of the film of the resin composition. Such a pigment in the resin composition has excellent light-blocking ability per unit content ratio, particularly compared with general organic pigments, and thus, makes it possible to afford the same level of light-blocking ability at a low content ratio. This makes it possible to enhance the light-blocking ability of the film and enhance the sensitivity during light exposure. Furthermore, being an organic material causes chemical structure change or functional conversion to adjust the transmittance spectrum or absorption spectrum of the film of the resin composition, for example, to transmit or block desired light having a specific wavelength, making it possible to enhance the toning ability. In particular, such a pigment can enhance the transmittance at a wavelength in the near-infrared area (for example, 700 nm or more), thus has light-blocking ability, and is suitable in applications in which light having a wavelength in the near-infrared area is utilized. In addition, such a pigment has excellent insulation properties and low dielectricity compared with general organic pigments and inorganic pigments, and thus, makes it possible to enhance the resistance value of the film. In particular, using such a film as an insulation layer or the like, for example, a pixel division layer of an organic EL display makes it possible to prevent light-emitting failure and the like and enhance reliability. The (Da-1a) benzofuranone black pigment is preferable from the viewpoint of light-blocking ability per unit content ratio.

In addition, the (Da-1a) benzofuranone black pigment absorbs light having a wavelength of visible light, and has high transmittance at a wavelength in the ultraviolet area (for example, 400 nm or less), and thus, containing the (Da-1a) benzofuranone black pigment makes it possible to enhance the sensitivity during light exposure.

The (Da-1a) benzofuranone black pigment refers to a compound that has a benzofuran-2(3H)-one structure or a benzofuran-3(2H)-one structure in the molecule and absorbs light having a wavelength of visible light to be colored black.

On the other hand, containing the (Da-1a) benzofuranone black pigment causes a development residue derived from the pigment to be generated owing to the insufficient alkali resistance of the pigment in some cases, as above-mentioned. That is, the surface of the (Da-1a) benzofuranone black pigment is exposed to an alkaline developer during development, and thus, part of the surface is decomposed or dissolved, and in some cases, remains on the substrate as a development residue derived from the pigment. In such a case, containing the (B1) flexible-chain-containing aliphatic radical polymerizable compound makes it possible, as above-mentioned, to prevent a development residue derived from the pigment from being generated.

The (Da-1a) benzofuranone black pigment is preferably a benzofuranone compound represented by any one of the general formulae (63) to (68), a geometric isomer of the compound, salt of the compound, or salt of the geometric isomer.

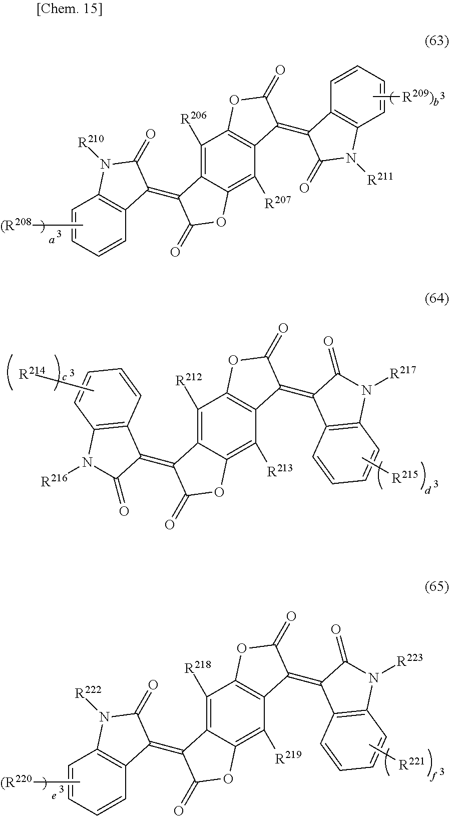

In the general formulae (63) to (65), R²⁰⁶, R²⁰⁷, R²¹², R²¹³, R²¹⁸, and R²¹⁹ independently represent hydrogen, a halogen atom, C₁-C₁₀ alkyl group, or C₁-C₁₀ alkyl group having 1 to 20 fluorine atoms. R²⁰⁸, R²⁰⁹, R²¹⁴, R²¹⁵, R²²⁰, and R²²¹ independently represent hydrogen, a halogen atom, R²⁵¹, COOH, COOR²⁵¹, COO, CONH₂, CONHR²⁵¹, CONR²⁵¹R²⁵², CN, OH, OR²⁵¹, OCOR²⁵¹, OCONH₂, OCONHR²⁵¹, OCONR²⁵¹R²⁵², NO₂, NH₂, NHR²⁵¹, NR²⁵¹R²⁵², NHCOR²⁵¹, NR²⁵¹COR²⁵², N═CH₂, N═CHR²⁵¹, N═CR²⁵¹R²⁵², SH, SR²⁵¹, SOR²⁵¹, SO₂R²⁵¹, SO₃R², SO₃H, SO₃⁻, SO₂NH₂, SO₂NHR²⁵¹, or SO₂NR²⁵¹R²⁵², and R²⁵¹ and R²⁵² independently represent a C₁-C₁₀ alkyl group, C₄-C₁₀ cycloalkyl group, C₂-C₁₀ alkenyl group, C₄-C₁₀ cycloalkenyl group, or C₂-C₁₀ alkynyl group. Two or more of R²⁰⁸, R²⁰⁹, R²¹⁴, R²¹⁵, R²²⁰, and R²²¹ may form a ring with a direct bond or an oxygen atom bridge, sulfur atom bridge, NH bridge, or NR²⁵¹ bridge. R²¹⁰, R²¹¹, R²¹⁶, R²¹⁷, R²²², and R²²³ independently represent hydrogen, a C₁-C₁₀ alkyl group, or C₆-C₁₅ aryl group. a³, b³, c³, d³, e³, and f³ independently represent an integer of 0 to 4. The above-mentioned alkyl groups, cycloalkyl groups, alkenyl groups, cycloalkenyl groups, alkynyl groups, and aryl groups may each have a heteroatom, and may be either an unsubstituted structure or a substituted structure.

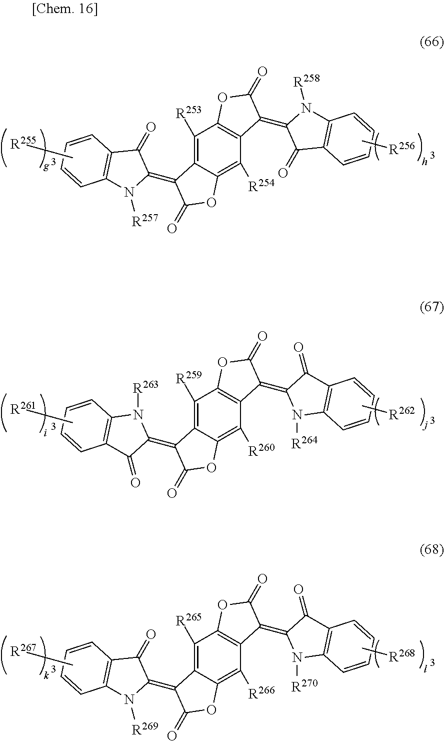

In the general formulae (66) to (68), R²⁵³, R²⁵⁴, R²⁵⁹, R²⁶⁰, R²⁶⁵, and R²⁶⁶ independently represent hydrogen, a halogen atom, C₁-C₁₀ alkyl group, or C₁-C₁₀ alkyl group having 1 to 20 fluorine atoms. R²⁵⁵, R²⁵⁶, R²⁶¹, R²⁶², R²⁶⁷, and R²⁶⁸ independently represent hydrogen, a halogen atom, R²⁷¹, COOH, COOR²⁷¹, COO⁻, CONH₂, CONHR²⁷¹, CONR²⁷¹R²⁷², CN, OH, OR²⁷¹, OCOR²⁷¹, OCONH₂, OCONHR²⁷¹, OCONR²⁷¹R²⁷², NO₂, NH₂, NHR²⁷¹, NR²⁷¹R²⁷², NHCOR²⁷¹, NR²⁷¹COR²⁷², N═CH₂, N═CHR²⁷¹, N═CR²⁷¹R²⁷², SH, SR²⁷¹, SOR²⁷¹, SO₂R²⁷¹, SO₃R²⁷¹, SO₃H, SO₃⁻, SO₂NH₂, SO₂NHR²⁷¹, or SO₂NR²⁷¹R²⁷², and R²⁷¹ and R²⁷² independently represent a C₁-C₁₀ alkyl group, C₄-C₁₀ cycloalkyl group, C₂-C₁₀ alkenyl group, C₄-C₁₀ cycloalkenyl group, or C₂-C₁₀ alkynyl group. Two or more of R²⁵⁵, R²⁵⁶, R²⁶¹, R²⁶², R²⁶⁷, and R²⁶⁸ may form a ring with a direct bond or an oxygen atom bridge, sulfur atom bridge, NH bridge, or NR²⁷¹ bridge. R²⁵⁷, R²⁵⁸, R²⁶³, R²⁶⁴, R²⁶⁹, and R²⁷⁰ independently represent hydrogen, a C₁-C₁₀ alkyl group, or C₆-C₁₅ aryl group. g³, h³, i³, j³, k³, and l³ independently represent an integer of 0 to 4. The above-mentioned alkyl groups, cycloalkyl groups, alkenyl groups, cycloalkenyl groups, alkynyl groups, and aryl groups may each have a heteroatom, and may be either an unsubstituted structure or a substituted structure.

Examples of the (Da-1a) benzofuranone black pigment include “IRGAPHOR” (registered trademark) BLACK S0100CF (manufactured by BASF SE), a black pigment described in WO 2010-081624, and a black pigment described in WO2010-081756.

The (Da-1b) perylene black pigment refers to a compound that has a perylene structure in the molecule and absorbs light having a wavelength of visible light to be colored black.

The (Da-1b) perylene black pigment is preferably a perylene compound represented by any one of the general formulae (69) to (71), a geometric isomer of the compound, salt of the compound, or salt of the geometric isomer.

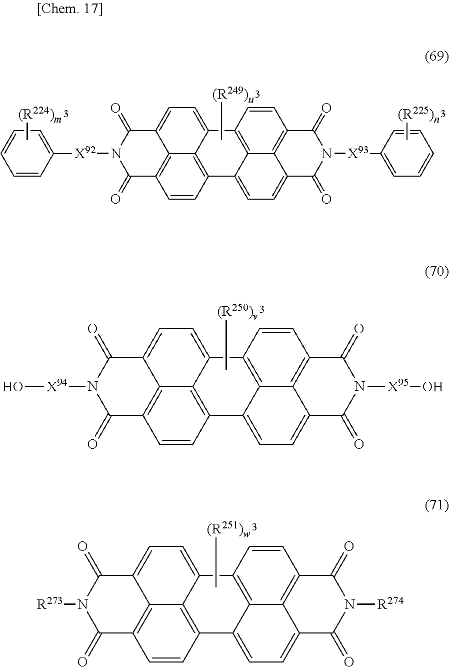

In the general formulae (69) to (71), X⁹², X⁹³, X⁹⁴, and X⁹⁵ independently represent a C₁-C₁₀ alkylene chain. R²²⁴ and R²²⁵ independently represent hydrogen, a hydroxy group, C₁-C₆ alkoxy group, or C₂-C₆ acyl group. R²⁴⁹, R²⁵⁰, and R²⁵¹ independently represent hydrogen, a halogen atom, C₁-C₁₀ alkyl group, or C₁-C₁₀ alkyl group having 1 to 20 fluorine atoms. R²⁷³ and R²⁷⁴ independently represent hydrogen or a C₁-C₁₀ alkyl group. m³ and n³ independently represent an integer of 0 to 5. u³, v³, and w³ independently represent an integer of 0 to 8. The above-mentioned alkylene chains, alkoxy groups, acyl groups, and alkyl groups may each have a heteroatom, and may be either an unsubstituted structure or a substituted structure.

Examples of the (Da-1b) perylene black pigment include Pigment Black 31 or 32 (the values are each a C. I. number).

Examples of such pigments other than above-mentioned include “PALIOGEN” (registered trademark) BLACK S0084, ditto K0084, ditto L0086, ditto K0086, ditto EH0788, and ditto FK4281 (which are all manufactured by BASF SE).

The (Da-1c) azo black pigment refers to a compound that has an azo structure in the molecule and absorbs light having a wavelength of visible light to be colored black.

The (Da-1c) azo black pigment is preferably an azo compound represented by the general formula (72).

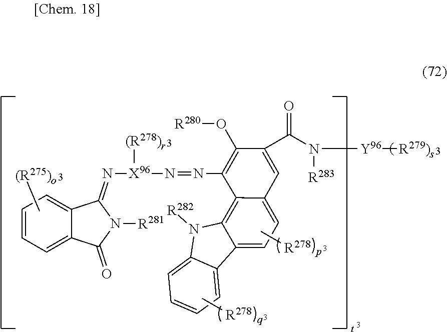

In the general formula (72), X⁹⁶ represents a C₆-C₁₅ arylene chain. Y⁹⁶ represents a C₆-C₁₅ arylene chain. R²⁷⁵, R²⁷⁶, and R²⁷⁷ independently represent halogen or a C₁-C₁₀ alkyl group. R²⁷⁸ represents halogen, a C₁-C₁₀ alkyl group, a C₁-C₆ alkoxy group, or nitro group. R²⁷⁹ represents halogen, a C₁-C₁₀ alkyl group, a C₁-C₆ alkoxy group, C₂-C₁₀ acylamino group, or nitro group. R²⁸⁰, R²⁸¹, R²⁸², and R²⁸³ independently represent hydrogen or a C₁-C₁₀ alkyl group. o³ represents an integer of 0 to 4, p³ represents an integer of 0 to 2, q³ represents an integer of 0 to 4, r³ and s³ independently represent an integer of 0 to 8, and t³ represents an integer of 1 to 4. The above-mentioned arylene chains, alkyl groups, alkoxy groups, and acylamino groups may each have a heteroatom, and may be either an unsubstituted structure or a substituted structure.

Examples of the (Da-1c) azo black pigment include “CHROMOFINE” (registered trademark) BLACK A1103 (manufactured by Dainichiseika Color & Chemicals Mfg. Co., Ltd.), a black pigment described in JPH01-170601A, and a black pigment described in JPH02-034664A.

The content ratio of one or more selected from the group consisting of the (Da-1a) benzofuranone black pigment, the (Da-1b) perylene black pigment, and the (Da-1c) azo black pigment in all the solid contents of a negative photosensitive resin composition according to the present invention except a solvent is preferably 8 mass % or more, more preferably 10 mass % or more, still more preferably 15 mass % or more, particularly preferably 20 mass % or more. The content ratio of 8 mass % or more makes it possible to enhance light-blocking ability and toning ability. On the other hand, the content ratio of one or more selected from the group consisting of the (Da-1a) benzofuranone black pigment, the (Da-1b) perylene black pigment, and the (Da-1c) azo black pigment is preferably 65 mass % or less, more preferably 60 mass % or less, still more preferably 55 mass % or less, particularly preferably 50 mass % or less. The content ratio of 65 mass % or less makes it possible to enhance the sensitivity during light exposure.

<(Db) Pigment Other than Black>

A negative photosensitive resin composition according to the present invention may contain (Db) a pigment other than black in cases where the above-mentioned (Da) black pigment is the (Da-1) black organic pigment.

The (Db) pigment other than black refers to a pigment that absorbs light having a wavelength of visible light and is thereby colored purple, blue, green, yellow, orange, or red, but not black. Containing the (Db) pigment other than black enables the film of the resin composition to be colored and have colorability or toning ability. Combining the different colors of two or more different (Db) pigments other than black makes it possible to tone a film of a resin composition to desired xy color coordinates and enhance the toning ability. Examples of the (Db) pigment other than black include (Db-1) an organic pigment other than black. Examples of the (Db-1) organic pigment other than black include phthalocyanine pigments, anthraquinone pigments, quinacridone pigments, dioxazine pigments, thioindigo pigments, diketo-pyrrolo-pyrrole pigments, threne pigments, indoline pigments, perylene pigments, and aniline pigments.

<(E) Dispersant>

A negative photosensitive resin composition according to the present invention preferably further contains (E) a dispersant.

The (E) dispersant refers to a compound having a surface affinity group that interacts with the surface of the above-mentioned (Da) black pigment and having a dispersion-stabilization structure that enhances the dispersion stability of the (Da) black pigment. Examples of the dispersion-stabilization structure of the (E) dispersant include a polymer chain, a substituent having electrostatic charge, and/or the like.

In cases where the negative photosensitive resin composition contains the (Da) black pigment, containing the (E) dispersant makes it possible to enhance the dispersion stability of the pigment and enhance the resolution obtained after development. For example, particularly in cases where the (Da) black pigment is particles disintegrated into a number-average particle size of 1 μm or less, the surface area of the particles of the (Da) black pigment increases, and thus, aggregation of the particles of the (Da) black pigment is more likely to occur. On the other hand, containing the (E) dispersant allows the surface of the disintegrated (Da) black pigment to interact with the surface affinity group of the (E) dispersant and allows the steric effect and/or electrostatic repulsion due to the dispersion-stabilization structure of the (E) dispersant to inhibit the aggregation of the particles of the (Da) black pigment, thus making it possible to enhance the dispersion stability.

Examples of the (E) dispersant having a surface affinity group include (E) dispersants having a basic group alone, (E) dispersants having a basic group and an acidic group, and (E) dispersants having an acidic group alone. From the viewpoint of enhancing the dispersion stability of the particles of the (Da) black pigment, the (E) dispersant having a basic group alone or the (E) dispersant having a basic group and an acidic group are preferably used. In addition, the (E) dispersant preferably has a structure in which the basic group and/or acidic group as a surface affinity group are/is salified with an acid and/or base.

Examples of the basic group of the (E) dispersant or examples of the structure in which the basic group is salified include: tertiary amino groups and quaternary ammonium salt structures; and nitrogen-containing ring backbones such as pyrrolidine backbones, pyrrole backbones, imidazole backbones, pyrazole backbones, triazole backbones, tetrazole backbones, imidazoline backbones, oxazole backbones, isoxazole backbones, oxazoline backbones, isooxazoline backbones, thiazole backbones, isothiazole backbones, thiazoline backbones, isothiazoline backbones, thiazine backbones, piperidine backbones, piperazine backbones, morpholine backbones, pyridine backbones, pyridazine backbones, pyrimidine backbones, pyrazine backbones, triazine backbones, isocyanuric acid backbones, imidazolidinone backbones, propylene urea backbones, butylene urea backbones, hydantoin backbones, barbituric acid backbones, alloxan backbones, and glycoluril backbones.

From the viewpoint of enhancing the dispersion stability and enhancing the resolution obtained after development, preferable examples of the basic group and preferable examples of the structure in which the basic group is salified include: tertiary amino groups and quaternary ammonium salt structures; and nitrogen-containing ring backbones such as pyrrole backbones, imidazole backbones, pyrazole backbones, pyridine backbones, pyridazine backbones, pyrimidine backbones, pyrazine backbones, triazine backbones, isocyanuric acid backbones, imidazolidinone backbones, propylene urea backbones, butylene urea backbones, hydantoin backbones, barbituric acid backbones, alloxan backbones, and glycoluril backbones.

Examples of the (E) dispersant having a basic group alone include: “DISPERBYK” (registered trademark)-108, ditto-160, ditto-167, ditto-182, ditto-2000, ditto-2164, “BYK” (registered trademark)-9075, ditto-LP-N6919, and ditto-LP-N21116 (which are all manufactured by BYK Japan KK); “EFKA” (registered trademark) 4015, ditto 4050, ditto 4080, ditto 4300, ditto 4400, and ditto 4800 (which are all manufactured by BASF SE); “AJISPER” (registered trademark) PB711 (manufactured by Ajinomoto Fine-Techno Co., Inc.); and “SOLSPERSE” (registered trademark) 13240, ditto 20000, and ditto 71000 (which are all manufactured by The Lubrizol Corporation).

Examples of the (E) dispersant having a basic group and an acidic group include: “ANTI-TERRA” (registered trademark)-U100 and ditto-204; “DISPERBYK” (registered trademark)-106, ditto-140, ditto-145, ditto-180, ditto-191, ditto-2001, ditto-2020, and “BYK” (registered trademark)-9076 (manufactured by BYK Japan KK); “AJISPER” (registered trademark) PB821 and ditto PB881 (which are all manufactured by Ajinomoto Fine-Techno Co., Inc.); and “SOLSPERSE” (registered trademark) 9000, ditto 13650, ditto 24000, ditto 33000, ditto 37500, ditto 39000, ditto 56000, and ditto 76500 (which are all manufactured by The Lubrizol Corporation).

Examples of the (E) dispersant having an acidic group include “DISPERBYK” (registered trademark)-102, ditto-118, ditto-170, ditto-2096, “BYK” (registered trademark)-P104, and ditto-220S (which are all manufactured by BYK Japan KK); and “SOLSPERSE” (registered trademark) 3000, ditto 16000, ditto 21000, ditto 36000, and ditto 55000 (which are all manufactured by The Lubrizol Corporation).

Examples of the (E) dispersant having no basic group and no acidic group include: “DISPERBYK” (registered trademark)-103, ditto-192, ditto-2152, and ditto-2200 (which are all manufactured by BYK Japan KK); and “SOLSPERSE” (registered trademark) 27000, ditto 54000, and ditto X300 (which are all manufactured by The Lubrizol Corporation).

The (E) dispersant preferably has an amine value of 5 mgKOH/g to 150 mgKOH/g. The amine value in this range makes it possible to enhance the storage stability of the resin composition.

The (E) dispersant preferably has an acid value of 5 mgKOH/g to 200 mgKOH/g. The acid value in this range makes it possible to enhance the storage stability of the resin composition.

Examples of the (E) dispersant having a polymer chain include acrylic resin dispersants, polyoxyalkylene ether dispersants, polyester dispersants, polyurethane dispersants, polyol dispersants, polyethyleneimine dispersants, and polyallylamine dispersants. From the viewpoint of the patterning property with an alkaline developer, acrylic resin dispersants, polyoxyalkylene ether dispersants, polyester dispersants, polyurethane dispersants, or polyol dispersants are preferable.

The content ratio of the (E) dispersant in a negative photosensitive resin composition according to the present invention is preferably 1 mass % to 60 mass % with respect to 100 mass % of the total amount of the (Da) black pigment and the (E) dispersant. The content ratio in this range both enables the (Da) black pigment to have dispersion stability and resolution obtained after development and enables the cured film to have heat resistance.

<Solvent>

A negative photosensitive resin composition according to the present invention preferably contains a solvent.

The solvent refers to a compound that can dissolve all or part of each of various resins or additives each contained in a resin composition. Containing a solvent makes it possible to uniformly dissolve each of various resins and additives each contained in the resin composition and enhance the transmittance of the cured film. In addition, it is made possible to adjust the resin composition to arbitrary viscosity and to form a film of the resin composition having a desired film thickness on a substrate. In addition, it is made possible to arbitrary adjust the surface tension of the resin composition, the drying speed during coating, or the like, and to enhance the leveling property during coating and the film thickness uniformity of the coating film.

From the viewpoint of the solubility of various resins and various additives, the solvent is preferably a compound having an alcoholic hydroxyl group, a compound having a carbonyl group, or a compound having three or more ether bonds. On the other hand, a compound having a boiling point of 110 to 250° C. under atmospheric pressure is more preferable. Having a boiling point of 110° C. or more allows the solvent to be volatilized to a suitable degree during coating to dry the coating film, thus making it possible to prevent coating nonuniformity and enhance film thickness uniformity. In addition, having a boiling point of 250° C. or less makes it possible to decrease the amount of solvent remaining in the coating film. Accordingly, it is made possible to decrease the amount of film shrinkage during thermosetting and to enhance the flatness of the cured film and enhance film thickness uniformity.

Examples of compounds having an alcoholic hydroxyl group and having a boiling point of 110 to 250° C. under atmospheric pressure include diacetone alcohol, ethyl lactate, ethylene glycol monomethyl ether, propylene glycol monomethyl ether, diethylene glycol monomethyl ether, dipropylene glycol monomethyl ether, 3-methoxy-1-butanol, 3-methoxy-3-methyl-1-butanol, and tetrahydrofurfuryl alcohol.

Examples of compounds having a carbonyl group and having a boiling point of 110 to 250° C. under atmospheric pressure include 3-methoxy-n-butyl acetate, 3-methyl-3-n-butyl acetate, propylene glycol monomethyl ether acetate, dipropylene glycol monomethyl ether acetate, and γ-butyrolactone.

Examples of compounds having three or more ether bonds and having a boiling point of 110 to 250° C. under atmospheric pressure include diethylene glycol dimethyl ether, diethylene glycol ethyl methyl ether, and dipropylene glycol dimethyl ether.

The content ratio of the solvent in a negative photosensitive resin composition according to the present invention can be adjusted suitably in accordance with the coating method. For example, the content ratio is generally 50 to 95 mass % of the whole negative photosensitive resin composition in cases where the coating film is formed by spin coating.

In cases where the resin composition contains the (Da) black pigment, the solvent is preferably a solvent having a carbonyl group or ester bond. Containing a solvent having a carbonyl group or ester bond enables the dispersion stability of the (Da) black pigment to be enhanced. In addition, the solvent is more preferably a solvent having an acetate bond from the viewpoint of the dispersion stability. Containing a solvent having an acetate bond enables the dispersion stability of the (Da) black pigment to be enhanced.

Examples of solvents having an acetate bond include 3-methoxy-n-butyl acetate, 3-methyl-3-methoxy-n-butyl acetate, ethylene glycol monomethyl ether acetate, propylene glycol monomethyl ether acetate, diethylene glycol monomethyl ether acetate, diethylene glycol monoethyl ether acetate, diethylene glycol mono-n-butyl ether acetate, dipropylene glycol monomethyl ether acetate, cyclohexanol acetate, propylene glycol diacetate, and 1,4-butanediol diacetate.

In the solvents in a negative photosensitive resin composition according to the present invention, the content ratio of a solvent having a carbonyl group or ester bond is preferably 30 to 100 mass %. The content ratio of 30 to 100 mass % makes it possible to enhance the dispersion stability of the (Da) black pigment.

<Other Additives>

A negative photosensitive resin composition according to the present invention may contain, as another additive, a known one such as a cross-linking agent, sensitizing agent, photo acid generator, chain transfer agent, polymerization terminator, silane coupling agent, or surfactant to the extent that the effects of the present invention are achieved. Furthermore, the resin composition may contain another resin or precursor thereof. Examples of other resins or precursors thereof include polyamides, polyamideimides, acrylic resins, cardo resins, epoxy resins, novolac resins, urea resins, and polyurethane, or precursors thereof.

<Method of Producing Negative Photosensitive Resin Composition>

A typical method of producing a negative photosensitive resin composition according to the present invention will be described with reference to an example. (E) a dispersant is added to a solution of (A) an alkali-soluble resin, and in this solution mixture, (Da) a black pigment is dispersed using a disperser to prepare a pigment dispersion liquid. Next, (B) a radical polymerizable compound, (C) a photo initiator, another additive(s), and arbitrary solvent(s) are added to the pigment dispersion liquid, and the resulting mixture is stirred for 20 minutes to three hours to afford a uniform solution. After the stirring, the resulting solution is filtrated to obtain a negative photosensitive resin composition according to the present invention.

Examples of dispersers include ball mills, bead mills, sand grinders, triple roll mills, and high-speed impact mills. Bead mills are preferable in terms of higher dispersion efficiency and microdispersion. Examples of bead mills include CoBall mills, basket mills, pin mills, and DYNO mills. Examples of beads for bead mills include titania beads, zirconia beads, and zircon beads. Beads for such bead mills preferably have a bead diameter of 0.01 to 6 mm, more preferably 0.015 to 5 mm, still more preferably 0.03 to 3 mm. Fine beads having a diameter of 0.015 to 0.1 mm are preferable in cases where the particle size of the primary particles of the (Da) black pigment and the particle size of the secondary particles formed by aggregation of the primary particles are several hundred nanometers or less. In this case, bead mills that have a separator based on a centrifugation method and that can separate fine beads from a pigment dispersion liquid are preferable. On the other hand, beads having a diameter of 0.1 to 6 mm are preferable from the viewpoint of higher dispersion efficiency in cases where the (Da) black pigment contains coarse particles having a diameter of several hundred nanometers or more.

<Low-Taper-Shaped Cured Pattern>

A negative photosensitive resin composition according to the present invention makes it possible to obtain a cured film containing a low-taper-shaped cured pattern. The inclined sides of the cross-section of the cured pattern contained in a cured film obtained from a negative photosensitive resin composition according to the present invention preferably make a cone angle of 1° to 60°. The cone angle in this range makes it possible to integrate and arrange light-emitting elements densely and thus to enhance the resolution of a display device, and, in addition, makes it possible to prevent disconnection in forming electrodes such as transparent electrodes and reflecting electrode. In addition, electric field concentration at the edge of the electrode can be prevented, thus making it possible to prevent the degradation of the light-emitting element.

In this regard, a cured film according to the present invention can be obtained by curing a negative photosensitive resin composition according to the present invention, and for the cured film according to the present invention, curing means a state in which the film has no more fluidity after being heated.

A cured film obtained by curing a negative photosensitive resin composition according to the present invention preferably has an optical density of 0.3 or more, more preferably 0.5 or more, still more preferably 0.7 or more, particularly preferably 1.0 or more, per 1 μm of film thickness. The optical density of 0.3 or more per 1 μm of film thickness enables such a cured film to enhance the light-blocking ability, and thus makes it possible to prevent visualization of electrode wiring or decrease external light reflection on a display device such as an organic EL display or liquid crystal display, enabling the contrast on the image display to be enhanced. Such a cured film is suitable in applications which need higher contrast achieved by prevention of external light reflection, examples of such applications including a black matrix of a color filter, a light-blocking film such as a black column spacer of a liquid crystal display, a pixel division layer of an organic EL display, and a TFT planarization layer. On the other hand, the optical density is preferably 3.0 or less, more preferably 2.8 or less, still more preferably 2.5 or less, per 1 μm of film thickness. The optical density of 3.0 or less per 1 μm of film thickness makes it possible to enhance the sensitivity during light exposure and also obtain a cured film having a low-taper-shaped pattern. The optical density of the cured film per 1 μm of film thickness can be regulated by changing the composition and content ratio of the above-mentioned (D) coloring agent.

<Production Process of Organic EL Display Device>

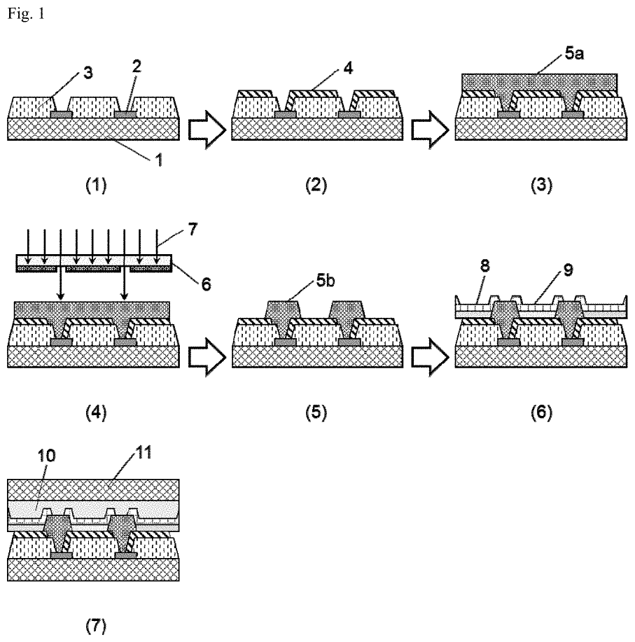

A process in which a negative photosensitive resin composition according to the present invention is used will be described with reference to the schematic cross-sectional view in FIG. 1, taking, for example, a process in which a cured film of the composition is used as a light-blocking pixel division layer of an organic EL display device. First, (1) on a glass substrate 1, a thin-film-transistor (hereinafter referred to as a “TFT”) 2 is formed, and a photosensitive material for a TFT planarization film is formed into a film and patterned by photolithography, followed by being thermoset to form a cured film 3 for TFT planarization. Next, (2) a silver-palladium-copper alloy (hereinafter referred to as an “APC”) is formed into a film using a sputter and patterned by etching using a photoresist to form an APC layer, and furthermore, indium tin oxide (hereinafter referred to as “ITO”) is formed into a film on the APC layer by sputtering and patterned by etching using a photoresist to form a reflecting electrode 4 as a first electrode. Then, (3) a negative photosensitive resin composition according to the present invention is applied and prebaked to form a prebaked film 5a. Then, (4) the prebaked film is irradiated with activated actinic rays 7 via a mask 6 having a desired pattern. Next, (5) the prebaked film is developed, patterned, and, if necessary, followed by undergoing bleaching exposure and middle-baking, and the resulting pattern is thermoset to form a cured pattern 5b having a desired pattern as a light-blocking pixel division layer. Then, (6) an organic EL light-emitting material is formed into a film by vapor deposition via a mask, resulting in an organic EL light-emitting layer 8; a magnesium-silver alloy (hereinafter referred to as a “MgAg”) is formed into a film by vapor deposition; and the film is patterned by etching using a photoresist to form a transparent electrode 9 as a second electrode. Next, (7) a photosensitive material for a planarization film is formed into a film, patterned by photolithography, and then thermoset to form a cured film 10 for planarization, followed by being joined to a cover glass 11, to obtain an organic EL display having a negative photosensitive resin composition according to the present invention as a light-blocking pixel division layer.

<Production Process of Liquid Crystal Display (Liquid Crystal Display)>

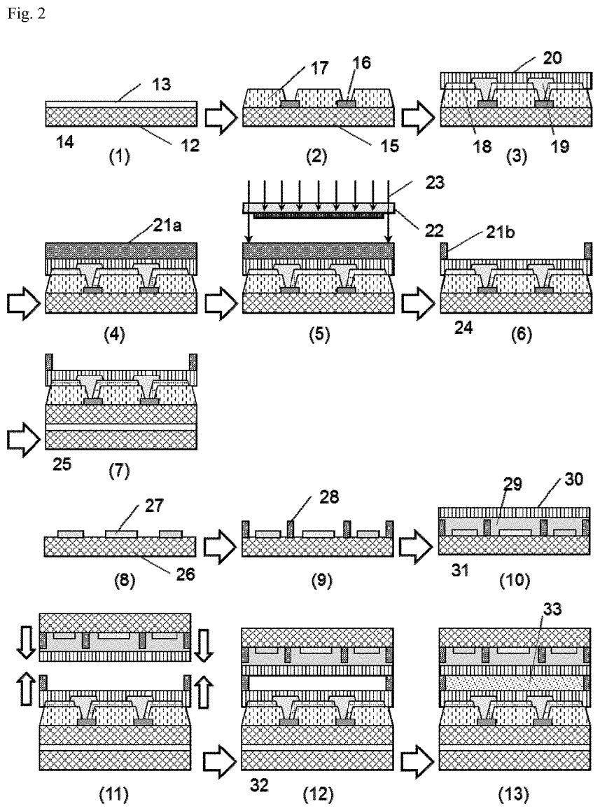

Another process in which a negative photosensitive resin composition according to the present invention is used will be described with reference to the schematic cross-sectional view in FIG. 2, taking, for example, a process in which a cured film of the composition is used as a black column spacer (hereinafter referred to as a “BCS”) of a liquid crystal display and a black matrix (hereinafter referred to as a “BM”) of a color filter. First, (1) a backlight unit (hereinafter referred to as a “BLU”) 13 is formed on a glass substrate 12 to obtain a glass substrate 14 having a BLU.

In addition, (2) on another glass substrate 15, a TFT 16 is formed, and a photosensitive material for a TFT planarization film is formed into a film and patterned by photolithography, followed by being thermoset to form a cured film 17 for TFT planarization. Next, (3) an ITO is formed into a film using a sputter, and the film is patterned by etching using a photoresist to form a transparent electrode 18, followed by forming a planarization film 19 and an alignment film 20. Then, (4) a negative photosensitive resin composition according to the present invention is applied and prebaked to forma prebaked film 21a. Then, (5) the prebaked film is irradiated with activated actinic rays 23 via a mask 22 having a desired pattern. Next, (6) the prebaked film is developed, patterned, and, if necessary, followed by undergoing bleaching exposure and middle-baking, and the resulting pattern is thermoset to form a cured pattern 21b having a desired pattern as a BCS, allowing a glass substrate 24 having a BCS to be obtained. Then, (7) joining the above-mentioned glass substrate 14 and the glass substrate 24 together results in obtaining a glass substrate 25 having a BLU and a BCS.

Furthermore, (8) a color filter 27 of three colors: red, green, and blue, is formed on another glass substrate 26. Next, (9) a cured pattern 28 having a desired pattern is formed as a light-blocking BM from a negative photosensitive resin composition according to the present invention in the same manner as above-mentioned. Then, (10) a photosensitive material for planarization is formed into a film and patterned by photolithography, followed by being thermoset to form a cured film 29 for planarization, and an alignment film 30 is formed on the cured film to obtain a color filter substrate 31. Then, (11) the above-mentioned glass substrate 25 having a BLU and a BCS and the color filter substrate 31 are joined together, and thus, (12) a glass substrate 32 having a BLU, a BCS, and a BM is obtained. Next, (13) injecting liquid crystal to form a liquid crystal layer 33 results in obtaining a liquid crystal display having a negative photosensitive resin composition according to the present invention as a BCS and a BM.

As above-mentioned, the method of producing an organic EL display device and a liquid crystal display using a negative photosensitive resin composition according to the present invention makes it possible to obtain a highly heat-resistant and light-blocking patterned cured film containing a polyimide and/or a polybenzoxazole, thus leading to enhancing a yield, enhancing performance, and enhancing reliability in production of organic EL display devices and liquid crystal displays.

A process carried out using a negative photosensitive resin composition according to the present invention makes it possible to carry out direct patterning by photolithography because the resin composition is photosensitive. Consequently, it becomes possible to reduce the number of steps, compared with a process carried out using a photoresist, thus making it possible to enhance the productivity of organic EL display devices and liquid crystal displays, shorten process time, and shorten tact time.

<Display Device Produced Using Cured Film Obtained from Negative Photosensitive Resin Composition according to the Present Invention>

A cured film obtained from a negative photosensitive resin composition according to the present invention can be a suitable constituent of an organic EL display device or liquid crystal display.

In addition, a negative photosensitive resin composition according to the present invention makes it possible to obtain a low-taper-shaped pattern and obtain a cured film having excellent high heat resistance. Thus, such a resin composition is suitable in applications which need high heat resistance and a low-taper-shaped pattern, for example, an insulation layer such as a pixel division layer of an organic EL display. In particular, problems depending on the heat resistance and pattern shape are considered to occur in some applications, examples of such problems including: failure or characteristic degradation caused to an element by degassing due to thermal decomposition; and disconnection caused to electrode wiring by a high-taper-shaped pattern, and in such applications, using a cured film of a negative photosensitive resin composition according to the present invention makes it possible to produce an element having high reliability and causing no such problem as above-mentioned. Furthermore, such a cured film has excellent light-blocking ability, and thus, makes it possible to prevent visualization of electrode wiring or decrease external light reflection, enabling the contrast on the image display to be enhanced. Thus, using, as a pixel division layer of an organic EL display, a cured film obtained from a negative photosensitive resin composition according to the present invention makes it possible to enhance the contrast without forming a polarizing plate or a ¼ wavelength plate on the light extraction side of a light-emitting element.

In addition, a display device according to the present invention preferably has a display unit having a curved face. The curvature radius of this curved face is preferably 0.1 mm or more, more preferably 0.3 mm or more, from the viewpoint of preventing display failure due to disconnection or the like on a display unit having a curved face. The curvature radius of the curved face is preferably 10 mm or less, more preferably 7 mm or less, still more preferably 5 mm or less, from the viewpoint of producing a display device having a smaller size and higher resolution.

<Flexible Organic EL Display Device Produced Using Cured Film Obtained from Negative Photosensitive Resin Composition According to the Present Invention>

A negative photosensitive resin composition according to the present invention allows the resulting cured film to have excellent flexibility and have an excellent adhesion property to an adjacent constituent such as a base material, and thus can be preferably used for a flexible organic EL display device that is an organic EL display device in which a flexible material is used as a substrate.

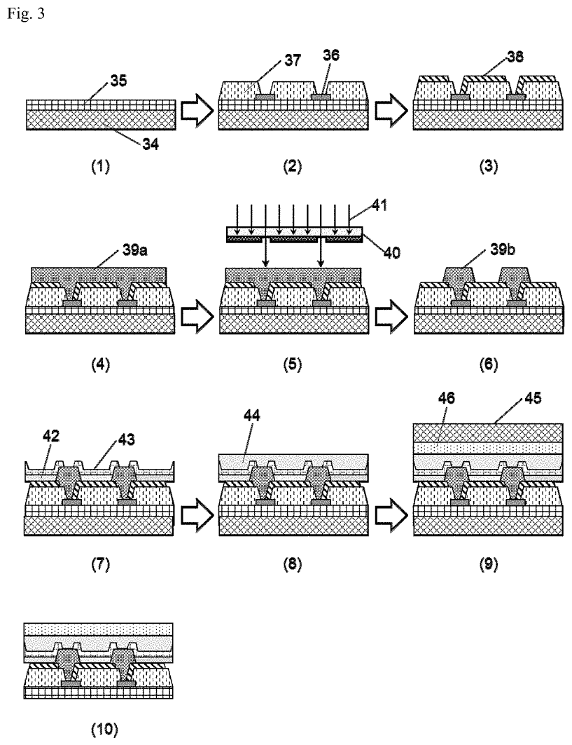

A process in which a negative photosensitive resin composition according to the present invention is used will be described with reference to FIG. 3, taking, for example, a process in which a cured film of the composition is used as a light-blocking pixel division layer of a flexible organic EL display. First, (1) a polyimide (hereinafter referred to as a “PI”) film substrate 35 that is a flexible base material is tentatively fixed on a glass substrate 34. Next, (2) on the PI film substrate, an oxide TFT 36 is formed, and a photosensitive material for a TFT planarization film is formed into a film and patterned by photolithography, followed by being thermoset to form a cured film 37 for TFT planarization. Then, (3) an APC is formed into a film as an APC layer using a sputter, and an ITO is formed into a film further on the APC layer using a sputter, patterned by etching using a photoresist, and patterned by etching using a photoresist to form a reflecting electrode 38 as a first electrode. Next, (4) a negative photosensitive resin composition according to the present invention is applied and prebaked to form a prebaked film 39a. Then, (5) the prebaked film is irradiated with activated actinic rays 41 via a mask 40 having a desired pattern. Then, (6) the prebaked film is developed, patterned, and, if necessary, followed by undergoing bleaching exposure and middle-baking, and the resulting pattern is thermoset to form a cured pattern 39b having a desired pattern as a flexible and light-blocking pixel division layer. Next, (7) an EL light-emitting material is formed into a film by vapor deposition via a mask, resulting in an EL light-emitting layer 42; an MgAg is formed into a film by vapor deposition; and the film is patterned by etching using a photoresist to form a transparent electrode 43 as a second electrode. Then, (8) a photosensitive material for a TFT planarization film is formed into a film and patterned by photolithography, followed by being thermoset to form a cured film 44 for planarization. Next, (9) to the cured film, a polyethylene terephthalate (hereinafter referred to as “PET”) film substrate 46 tentatively fixed on another glass substrate 45 is joined together. Then, (10) the glass substrate 34 is peeled away from the PI film substrate 35, and the glass substrate 45 is peeled away from the PET film substrate 46 to obtain a top emission type flexible organic EL display having a negative photosensitive resin composition according to the present invention as a flexible and light-blocking pixel division layer.

As above-mentioned, the method of producing a flexible organic EL display using a negative photosensitive resin composition according to the present invention makes it possible to obtain a highly heat-resistant and light-blocking patterned cured film, thus leading to enhancing a yield, enhancing performance, and enhancing reliability in production of flexible organic EL displays.

In addition, a negative photosensitive resin composition according to the present invention makes it possible to obtain a pattern having a low-taper shape and high resolution and obtain a cured film having flexibility. Thus, it is possible to have the cured film as a structure laminated on a flexible substrate, and such a resin composition is suitable in applications which need flexibility and a low-taper-shaped pattern, for example, an insulation layer such as a pixel division layer of a flexible organic EL display. Furthermore, such a cured film has high heat resistance, and thus, in cases where problems depending on the heat resistance and pattern shape are considered to occur in some applications, examples of such problems including: failure or characteristic degradation caused to an element by degassing due to thermal decomposition; and disconnection caused to electrode wiring by a high-taper-shaped pattern, using a cured film of a negative photosensitive resin composition according to the present invention makes it possible to produce an element having high reliability and causing no such problem as above-mentioned.

The flexible substrate is preferably a substrate containing a carbon atom as a main component, such as a film or sheet-like substrate that is composed of a polymer. Containing a carbon atom as a main component enables the substrate to have flexibility. The flexible substrate more preferably contains a polyimide from the viewpoint of enhancing the mechanical properties of the substrate and thus enhancing the flexibility. As used herein, having flexibility refers to having resistance to being folded carried out a minimum of 100 times in an MIT test described in JIS P 8115:2001. In addition, a cured film obtained from a negative photosensitive resin composition according to the present invention also contains a resin component, and thus, makes it possible to enhance the interaction of the cured film with the flexible substrate that is an underlying substrate and to enhance the adhesion property to the substrate. Furthermore, it is made possible to enhance the flexibility which allows the cured film to conform to the underlying substrate.

The content ratio of carbon atoms in the flexible substrate is preferably 20 mass % or more, more preferably 25 mass % or more, still more preferably 30 mass % or more, with respect to the mass of the substrate. The content ration in this range makes it possible to enhance the adhesion property to the underlying substrate and the flexibility of the cured film. In addition, the content ratio is preferably 95 mass % or less, more preferably 90 mass % or less. The content ratio in this range makes it possible to enhance the adhesion property to the underlying substrate and the flexibility of the cured film.

A negative photosensitive resin composition according to the present invention contains (C1) an oxime ester photo initiator and (C2) an α-hydroxyketone photo initiator, and thus, makes it possible to maintain the sensitivity well in forming a cured film on a flexible substrate containing a polyimide and at the same time, prevent generation of a residue derived from a black pigment after development. Accordingly, a cured film obtained from a negative photosensitive resin composition according to the present invention essentially needs to contain a black pigment to prevent external light reflection, and is suitable in applications for an insulation layer such as a pixel division layer of an organic EL display including a flexible substrate containing a polyimide, wherein such applications need achievement of light-blocking ability and higher sensitivity as well as prevention of generation of a development residue. In particular, problems due to a residue left after development are considered to occur in some applications, examples of such problems including generation of dark spots due to a residue at the opening, and in such applications, using a cured film of a negative photosensitive resin composition according to the present invention enables an element having high reliability and causing no such problem as above-mentioned to be produced with high production efficiency owing to the good sensitivity.

A method of producing a display device using a negative photosensitive resin composition according to the present invention has the following steps (1) to (4):

(1) forming a coating film of a negative photosensitive resin composition according to the present invention on a substrate;

(2) irradiating the coating film of the negative photosensitive resin composition with activated actinic rays via a photomask;

(3) carrying out development using an alkaline solution to form a pattern of the negative photosensitive resin composition; and

(4) heating the pattern to obtain a cured pattern of the negative photosensitive resin composition.

<Step of Forming Coating Film>

The method of producing a display device using a negative photosensitive resin composition according to the present invention has the step (1) of forming a coating film of a negative photosensitive resin composition on a substrate. Examples of methods of forming a film of a negative photosensitive resin composition according to the present invention include a method in which a substrate is coated with the resin composition and a method in which a substrate is coated with the resin composition in pattern shape.

Examples of substrates to be used include a substrate in which an oxide, metal (molybdenum, silver, copper, aluminium, chromium, or titanium), or CNT (Carbon Nano Tube) is formed as wiring or electrodes on a sheet of glass, wherein the oxide has one or more selected from indium, tin, zinc, aluminium, and gallium.

Examples of oxides having one or more selected from indium, tin, zinc, aluminium, and gallium include indium tin oxide (ITO), indium zinc oxide (IZO), aluminium zinc oxide (AZO), indium gallium zinc oxide (IGZO), and zinc oxide (ZnO).

<Method of Coating Substrate with Negative Photosensitive Resin Composition According to the Present Invention>

Examples of methods of coating a substrate with a negative photosensitive resin composition according to the present invention include micro gravure coating, spin coating, dip coating, curtain flow coating, roll coating, spray coating, and slit coating. The coating film thickness varies depending on the coating method, the solid content of the resin composition, and the viscosity, and the coating is usually formed in such a manner that the film thickness obtained after coating and prebaking is 0.1 to 30 μm.

After the substrate is coated with the negative photosensitive resin composition according to the present invention, the composition is preferably formed into a film by prebaking. The prebaking can be carried out using an oven, hot plate, infrared light, flash annealing device, or laser annealing device. The prebaking temperature is preferably 50 to 150° C. The prebaking time is preferably 30 seconds to several hours. The prebaking may be carried out through two or more stages, for example, prebaking at 80° C. for two minutes followed by prebaking at 120° C. for two minutes.

<Method of Coating Substrate with Negative Photosensitive Resin Composition According to the Present Invention in Pattern Shape>

Examples of methods of coating a substrate with a negative photosensitive resin composition according to the present invention in pattern shape include letterpress printing, intaglio printing, stencil printing, planographic printing, screen printing, ink-jet printing, off-set printing, and laser printing. The coating film thickness varies depending on the coating method, the solid content of the negative photosensitive resin composition according to the present invention, and the viscosity, and the coating is usually formed in such a manner that the film thickness obtained after coating and prebaking is 0.1 to 30 μm.

After the substrate is coated with the negative photosensitive resin composition according to the present invention in patter shape, the composition is preferably formed into a film by prebaking. The prebaking can be carried out using an oven, hot plate, infrared light, flash annealing device, or laser annealing device. The prebaking temperature is preferably 50 to 150° C. The prebaking time is preferably 30 seconds to several hours. The prebaking may be carried out through two or more stages, for example, prebaking at 80° C. for two minutes followed by prebaking at 120° C. for two minutes.

<Method of Patterning Coating Film Formed on Substrate>

Examples of methods of patterning a coating film of a negative photosensitive resin composition according to the present invention formed on a substrate include a method in which the coating film is patterned directly by photolithography and a method in which the coating film is patterned by etching. A method in which the coating film is patterned directly by photolithography is preferable from the viewpoint of reducing the number of steps to thereby enhance productivity and shorten process time.

<Step of Radiating Activated Actinic Rays Via Photomask>

The method of producing a display device using a negative photosensitive resin composition according to the present invention has the step (2) of irradiating the coating film of the negative photosensitive resin composition with activated actinic rays via a photomask.

After the substrate is coated with the negative photosensitive resin composition according to the present invention followed by prebaking the composition in film form, the film is exposed to light using an aligner such as a stepper, mirror projection mask aligner (MPA), or parallel light mask aligner (PLA). Examples of activated actinic rays radiated during light exposure include ultraviolet light, visible light, electron beam, X-ray, KrF laser (having a wavelength of 248 nm), and ArF laser (having a wavelength of 193 nm). The j-line (having a wavelength of 313 nm), i-line (having a wavelength of 365 nm), h-line (having a wavelength of 405 nm), or g-line (having a wavelength of 436 nm) of a mercury lamp is preferably used. The exposure energy is usually approximately 100 to 40,000 J/m² (10 to 4,000 mJ/cm²) (values on an i-line light meter), and, if necessary, light exposure can be carried out via a photomask having a desired pattern.

After light exposure, post-exposure baking may be carried out. Post-exposure baking makes it possible to expect effects such as enhancing the resolution obtained after development and expanding the tolerable range of the development conditions. The post-exposure baking can be carried out using an oven, hot plate, infrared light, flash annealing device, or laser annealing device. The post-exposure baking temperature is preferably 50 to 180° C. The post-exposure baking time is preferably 10 seconds to several hours. The post-exposure baking time of 10 seconds to several hours allows the reaction to progress well and can shorten the development time in some cases.

<Step of Carrying Out Development with Alkaline Solution to Form Pattern>

A method of producing a display device using a negative photosensitive resin composition according to the present invention has the step (3) of carrying out development with an alkaline solution to form a pattern of the negative photosensitive resin composition. After the light exposure, development is carried out using an automatic developing device or the like. The negative photosensitive resin composition according to the present invention is photosensitive, and thus the exposed portions or unexposed portions are removed with a developer by development, making it possible to obtain a relief pattern.

A commonly used developer is an alkaline developer. Preferable examples of alkaline developers include organic alkaline solutions and aqueous solutions of a compound exhibiting alkalinity, and aqueous solutions of a compound exhibiting alkalinity, that is, alkali aqueous solutions are more preferable from an environmental viewpoint.

Examples of organic alkaline solutions or compounds exhibiting alkalinity include 2-aminoethanol, 2-(dimethylamino)ethanol, 2-(diethylamino)ethanol, diethanolamine, methylamine, ethylamine, dimethylamine, diethylamine, triethylamine, (2-dimethylamino)ethyl acetate, (2-dimethylamino)ethyl (meth)acrylate, cyclohexylamine, ethylenediamine, hexamethylenediamine, ammonia, tetramethylammonium hydroxide, tetraethylammonium hydroxide, sodium hydroxide, potassium hydroxide, magnesium hydroxide, calcium hydroxide, barium hydroxide, sodium carbonate, and potassium carbonate; and tetramethylammonium hydroxide or tetraethylammonium hydroxide is preferable from the viewpoint of decreasing metallic impurities in a cured film and preventing display failure of a display device.

An organic solvent may be used as a developer. A solution mixture containing both an organic solvent and a poor solvent for a negative photosensitive resin composition according to the present invention may be used as a developer.

Examples of developing methods include puddle development, spray development, and dip development. Examples of puddle development include a method in which the above-mentioned developer is directly applied to the exposed film and then left to stand for arbitrary period of time, and a method in which the above-mentioned developer in mist form is radiated and applied to the exposed film for arbitrary period of time and then left to stand for arbitrary period of time. Examples of spray development include a method in which the above-mentioned developer in mist form is continuously radiated to the exposed film for arbitrary period of time. Examples of dip development include a method in which the exposed film is dipped in the above-mentioned developer for arbitrary period of time, and a method in which the exposed film is dipped in the above-mentioned developer followed by being continuously irradiated with ultrasonic waves for any period of time. A preferable developing method is puddle development from the viewpoint of preventing contamination of a device during development and reducing the usage amount of a developer to reduce process costs. Preventing contamination of a device during development makes it possible to prevent contamination of a substrate during development, thus making it possible to prevent display failure of a display device. On the other hand, a preferable developing method is spray development from the viewpoint of preventing generation of a residue left after development. In addition, a preferable developing method is dip development in terms of reusing a developer to reduce the usage amount of a developer and reduce process costs.

The development time is preferably 5 seconds to 30 minutes.

After the development, the obtained relief pattern is preferably cleaned with a rinse solution. A preferable rinse solution is water in cases where an alkali aqueous solution is used as a developer. Examples of rinse solutions that may be used include: aqueous solutions of alcohols such as ethanol and isopropyl alcohol; aqueous solutions of esters such as propylene glycol monomethyl ether acetate; aqueous solutions of compounds exhibiting acidity, such as carbon dioxide gas, hydrochloric acid, and acetic acid. An organic solvent may be used as a rinse solution.

After the pattern of the negative photosensitive resin composition according to the present invention is obtained by photolithography, the pattern may be subjected to bleaching exposure. Bleaching exposure makes it possible to arbitrarily control the shape of the pattern obtained after thermosetting. In addition, it is made possible to enhance the transparency of the cured film.

Bleaching exposure can be carried out using an aligner such as a stepper, mirror projection mask aligner (MPA), or parallel light mask aligner (PLA). Examples of activated actinic rays radiated during bleaching exposure include ultraviolet light, visible light, electron beam, X-ray, KrF laser (having a wavelength of 248 nm), and ArF laser (having a wavelength of 193 nm). The j-line (having a wavelength of 313 nm), i-line (having a wavelength of 365 nm), h-line (having a wavelength of 405 nm), or g-line (having a wavelength of 436 nm) of a mercury lamp is preferably used. The exposure energy is usually approximately 500 to 500,000 J/m² (50 to 50,000 mJ/cm²) (values on an i-line light meter), and, if necessary, light exposure can be carried out via a mask having a desired pattern.

After the pattern of the negative photosensitive resin composition according to the present invention is obtained, the pattern may be subjected to middle-baking. Middle-baking makes it possible to enhance the resolution obtained after thermosetting and arbitrarily control the shape of the pattern obtained after thermosetting. The middle-baking can be carried out using an oven, hot plate, infrared light, flash annealing device, or laser annealing device. The middle-baking temperature is preferably 50° C. to 250° C. The middle-baking time is preferably 10 seconds to several hours. The middle-baking may be carried out through two or more stages, for example, middle-baking at 100° C. for five minutes followed by middle-baking at 150° C. for five minutes.

<Step of Heating Pattern to Obtain Cured Pattern>

The method of producing a display device using a negative photosensitive resin composition according to the present invention has the step (4) of heating a pattern of the negative photosensitive resin composition to obtain a cured pattern of the negative photosensitive resin composition.

The pattern of the negative photosensitive resin composition according to the present invention formed as a film on a substrate can be heated using an oven, hot plate, infrared light, flash annealing device, or laser annealing device. Heating the pattern of the negative photosensitive resin composition according to the present invention for thermosetting makes it possible to enhance the heat resistance of the cured film and to obtain a low-taper-shaped pattern.

The thermosetting temperature is preferably 150° C. to 500° C.

The thermosetting time is preferably one minute to 300 minutes. The thermosetting may be carried out through two or more stages, for example, thermosetting at 150° C. for 30 minutes followed by thermosetting at 250° C. for 30 minutes.

In addition, a negative photosensitive resin composition according to the present invention makes it possible to obtain a cured film that is suitably used in applications such as a pixel division layer of an organic EL display, a color filter, a black matrix of a color filter, a black column spacer of a liquid crystal display, a gate insulation film of a semiconductor, an interlayer insulation film of a semiconductor, a protection film for metal wiring, an insulation film for metal wiring, and a planarization film for a TFT. In particular, such a resin composition has excellent light-blocking ability, and thus, is suitable for a light-blocking pixel division layer of an organic EL display, a black matrix of a color filter, or a black column spacer of a liquid crystal display. In addition, it is made possible to obtain an element and a display device that include the cured film for the above-mentioned applications.

In a display device according to the present invention, the opening of the pixel division layer in the display area preferably has an opening ratio of 20% or less. The opening ratio of 20% or less enables a display device to have higher resolution and higher fineness, and increases the area of the pixel division layer that decreases external light reflection, thus making it possible to enhance the contrast of the display device. On the other hand, a smaller opening ratio of the opening of the pixel division layer increases the contribution to generation of display failure such as generation of dark spots due to a development residue, or a decrease in brightness. Accordingly, forming the pixel division layer using a negative photosensitive resin composition according to the present invention makes it possible to prevent generation of a development residue, thus enabling the display device to be prevented from generating display failure and have higher reliability.

Furthermore, the method of producing a display device using a negative photosensitive resin composition according to the present invention makes it possible to obtain a highly heat-resistant and light-blocking patterned cured film containing a polyimide and/or a polybenzoxazole, thus leading to enhancing a yield, enhancing performance, and enhancing reliability in production of organic EL displays and liquid crystal displays. In addition, a negative photosensitive resin composition according to the present invention can be directly patterned by photolithography, and thus, makes it possible to reduce the number of steps, compared with a process carried out using a photoresist, thus making it possible to enhance the productivity, shorten process time, and shorten tact time.

### EXAMPLES

Below, the present invention will be more specifically described with reference to Examples and Comparative Examples, and the present invention is not to be construed as limited thereby. Among the compounds used, those which are abbreviated are below-mentioned with the names.

6FDA: 2,2-(3,4-dicarboxyphenyl)hexafluoropropane dianhydride 4,4′-hexafluoropropane-2,2-diyl-bis(1,2-phthalic anhydride)
APC: Argentum-Palladium-Cupper (silver-palladium-copper alloy)
BAHF: 2,2-bis(3-amino-4-hydroxyphenyl)hexafluoropropane
BFE: 1,2-bis(4-formylphenyl)ethane
Bk-A1103: “CHROMOFINE” (registered trademark) BLACK A1103 (an azo black pigment having a primary particle size of 50 to 100 nm; manufactured by Dainichiseika Color & Chemicals Mfg. Co., Ltd.)
Bk-S0084: “PALIOGEN” (registered trademark) BLACK S0084 (a perylene black pigment having a primary particle size of 50 to 100 nm; manufactured by BASF SE)
Bk-S0100CF: “IRGAPHOR” (registered trademark) BLACK S0100CF (a benzofuranone black pigment having a primary particle size of 40 to 80 nm; manufactured by BASF SE)
cyEpoTMS: 2-(3,4-epoxycyclohexyl)ethyltrimethoxysilane
D. BYK-167: “DISPERBYK” (registered trademark)-167 (a dispersant having a basic group alone; manufactured by BYK Japan KK)
DMF-DFA: N,N-dimethylformamide dimethylacetal
DPCA-60: “KAYARAD” (registered trademark) DPCA-60 (ε-caprolactone modified dipentaerythritol hexaacrylate having six oxypentylenecarbonyl structures in the molecule; manufactured by Nippon Kayaku Co., Ltd.)
DPHA: “KAYARAD” (registered trademark) DPHA (dipentaerythritol hexaacrylate; manufactured by Nippon Kayaku Co., Ltd.)
GMA: glycidyl methacrylate
HA: N,N′-bis[5,5′-hexafluoropropane-2,2-diyl-bis(2-hydroxyphenyl)]bis(3-aminobenzoic amide)
IGZO: indium gallium zinc oxide
ITO: indium tin oxide
MAA: methacrylic acid
MAP: 3-aminophenol; meta-aminophenol
MBA: 3-methoxy-n-butyl acetate
MeTMS: methyltrimethoxy silane
MgAg: Magnesium-Argentum (magnesium-silver alloy)
NA: 5-norbornene-2,3-dicarboxylic anhydride; nadic anhydride
NMP: N-methyl-2-pyrrolidone
ODPA: bis(3,4-dicarboxyphenyl)ether dianhydride; oxydiphthalic dianhydride
P. B. 15:6: C. I. pigment blue 15:6
P. R. 254: C. I. pigment red 254
P. V. 23: C. I. pigment violet 23
P. Y. 139: C. I. pigment yellow 139
PGMEA: propylene glycol monomethyl ether acetate
PhTMS: phenyltrimethoxy silane
S-20000: “SOLSPERSE” (registered trademark) 20000 (a polyether dispersant; manufactured by The Lubrizol Corporation)
SiDA: 1,3-bis(3-aminopropyl)tetramethyl disiloxane
STR: styrene
TCDM: tricyclo[5.2.1.0^{2,6}]decane-8-yl methacrylate; dimethylol-tricyclodecane dimetaacrylate
TMAH: tetramethylammonium hydroxide
TMOS: tetramethoxy silane
TPK-1227: carbon black surface-treated to introduce a sulfonic group (manufactured by Cabot Corporation)

### Synthesis Example (A)

Into a three-neck flask, 18.31 g (0.05 mol) of BAHF, 17.42 g (0.3 mol) of propylene oxide, and 100 mL of acetone were weighed out and dissolved. To the resulting mixture, a solution of 20.41 g (0.11 mol) of 3-nitrobenzoyl chloride dissolved in 10 mL of acetone was added dropwise. Upon completion of the dropwise addition, the resulting mixture was allowed to react at −15° C. for four hours and then returned to room temperature. The precipitated white solid was collected by filtration and vacuum-dried at 50° C. Into a 300-mL stainless steel autoclave, 30 g of the obtained solid was added and dispersed in 250 mL of 2-methoxy ethanol, and to the resulting mixture, 2 g of 5% palladium-carbon was added. To the resulting mixture, hydrogen was introduced from a balloon and allowed to react at room temperature for two hours. After two hours, no more deflation of the balloon was verified. Upon completion of the reaction, the palladium compound, which was a catalyst, was removed by filtration, and the residue was concentrated by evaporation under reduced pressure to obtain a hydroxy-group-containing diamine compound (HA) having the following structure.

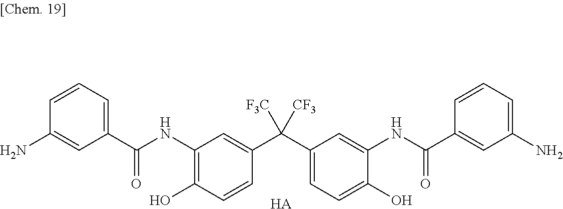

### Synthesis Example 1: Synthesis of Polyimide (PI-1)

Into a three-neck flask, 31.13 g of BAHF (0.085 mol; 77.3 mol % with respect to the structural units derived from all amines and derivatives thereof), 1.24 g of SiDA (0.0050 mol; 4.5 mol % with respect to the structural units derived from all amines and derivatives thereof), 2.18 g of MAP as an end-capping agent (0.020 mol; 18.2 mol % with respect to the structural units derived from all amines and derivatives thereof), and 150.00 g of NMP were weighed out and dissolved under a dry nitrogen gas stream. To the resulting mixture, a solution of 31.02 g of ODPA (0.10 mol; 100 mol % with respect to the structural units derived from all carboxylic acids and derivatives thereof) dissolved in 50.00 g of NMP was added, and the resulting mixture was stirred at 20° C. for one hour and then stirred at 50° C. for four hours. To the resulting mixture, 15 g of xylene was then added, and the resulting mixture was stirred at 150° C. for five hours while water was allowed to undergo azeotropy with the xylene. Upon completion of the reaction, the reaction solution was added to 3 L of water, and a precipitated solid was obtained by filtration. The obtained solid was washed with water three times, and then dried with a vacuum dryer at 80° C. for 24 hours to obtain a polyimide (PI-1). The obtained polyimide had an Mw of 27,000.

### Synthesis Example 2: Synthesis of Polyimide Precursor (PIP-1)

Into a three-neck flask, 44.42 g of 6FDA (0.10 mol; 100 mol % with respect to the structural units derived from all carboxylic acids and derivatives thereof) and 150 g of NMP were weighed out and dissolved under a dry nitrogen gas stream. A solution of 14.65 g of BAHF (0.040 mol; 32.0 mol % with respect to the structural units derived from all amines and derivatives thereof), 18.14 g of HA (0.030 mol; 24.0 mol % with respect to the structural units derived from all amines and derivatives thereof), and 1.24 g of SiDA (0.0050 mol; 4.0 mol % with respect to the structural units derived from all amines and derivatives thereof) dissolved in 50 g of NMP was added, and the resulting mixture was stirred at 20° C. for one hour and then stirred at 50° C. for two hours. Next, a solution of 5.46 g of MAP as an end-capping agent (0.050 mol; 40.0 mol % with respect to the structural units derived from all amines and derivatives thereof) dissolved in 15 g of NMP was added, and the resulting mixture was stirred at 50° C. for two hours. To the mixture, a solution of 23.83 g (0.20 mol) of DMF-DFA dissolved in 15 g of NMP was then added dropwise over ten minutes. Upon completion of the dropwise addition, the resulting mixture was stirred at 50° C. for three hours. Upon completion of the reaction, the reaction solution was cooled to room temperature, the reaction solution was added to 3 L of water, and a precipitated solid was obtained by filtration. The obtained solid was washed with water three times, and then dried with a vacuum dryer at 80° C. for 24 hours to obtain a polyimide precursor (PIP-1). The obtained polyimide precursor had an Mw of 20,000.

### Synthesis Example 3: Synthesis of Polybenzoxazole (PBO-1)

Into a 500-mL round bottom flask having a Dean and Stark water separator filled with toluene and having a cooling tube, 34.79 g of BAHF (0.095 mol; 95.0 mol % with respect to the structural units derived from all amines and derivatives thereof), 1.24 g of SiDA (0.0050 mol; 5.0 mol % with respect to the structural units derived from all amines and derivatives thereof), and 75.00 g of NMP were weighed out and dissolved. To the resulting mixture, a solution of 19.06 g of BFE (0.080 mol; 66.7 mol % with respect to the structural units derived from all carboxylic acids and derivatives thereof) and 6.57 g of NA as an end-capping agent (0.040 mol; 33.3 mol % with respect to the structural units derived from all carboxylic acids and derivatives thereof) dissolved in 25.00 g of NMP was added, and the resulting mixture was stirred at 20° C. for one hour and then stirred at 50° C. for one hour. Then, the mixture was heated with stirring under a nitrogen atmosphere at 200° C. or more for ten hours to undergo dehydration reaction. Upon completion of the reaction, the reaction solution was added to 3 L of water, and a precipitated solid was obtained by filtration. The obtained solid was washed with water three times, and then dried with a vacuum dryer at 80° C. for 24 hours to obtain a polybenzoxazole (PBO-1). The obtained polybenzoxazole had an Mw of 25,000.

### Synthesis Example 4: Synthesis of Polybenzoxazole Precursor (PBOP-1)

Into a 500-mL round bottom flask having a Dean and Stark water separator filled with toluene and having a cooling tube, 34.79 g of BAHF (0.095 mol; 95.0 mol % with respect to the structural units derived from all amines and derivatives thereof), 1.24 g of SiDA (0.0050 mol; 5.0 mol % with respect to the structural units derived from all amines and derivatives thereof), and 70.00 g of NMP were weighed out and dissolved. To the resulting mixture, a solution of 19.06 g of BFE (0.080 mol; 66.7 mol % with respect to the structural units derived from all carboxylic acids and derivatives thereof) dissolved in 20.00 g of NMP was added, and the resulting mixture was stirred at 20° C. for one hour and then stirred at 50° C. for two hours. Next, a solution of 6.57 g of NA as an end-capping agent (0.040 mol; 33.3 mol % with respect to the structural units derived from all carboxylic acids and derivatives thereof) dissolved in 10 g of NMP was added, and the resulting mixture was stirred at 50° C. for two hours. Then, the resulting mixture was stirred under a nitrogen atmosphere at 100° C. for two hours. Upon completion of the reaction, the reaction solution was added to 3 L of water, and a precipitated solid was obtained by filtration. The obtained solid was washed with water three times, and then dried with a vacuum dryer at 80° C. for 24 hours to obtain a polybenzoxazole precursor (PBOP-1). The obtained polybenzoxazole precursor had an Mw of 20,000.

### Synthesis Example 5: Synthesis of Polysiloxane Solution (PS-1)

In a three-neck flask, 20.43 g (30 mol %) of MeTMS, 49.57 g (50 mol %) of PhTMS, 12.32 g (10 mol %) of cyEpoTMS, 7.61 g (10 mol %) of TMOS, and 83.39 g of PGMEA were well mixed. Air was run into the flask at 0.05 L/min., and the solution mixture was heated to 40° C. with stirring in an oil bath. To the solution mixture, which was being stirred further, a phosphoric acid aqueous solution of 0.27 g of phosphoric acid dissolved in 28.83 g of water was added dropwise over ten minutes. Upon completion of the dropwise addition, the resulting mixture was stirred at 40° C. for 30 minutes to hydrolyze the silane compound. Upon completion of the hydrolysis, the resulting solution was stirred for one hour with the bath temperature set to 70° C., and subsequently, the bath temperature was raised to 115° C. Approximately one hour after starting to raise the temperature, the internal temperature of the solution reached 100° C., and for two hours thereafter, the solution was heated with stirring (the internal temperature was 100 to 110° C.). The solution was heated with stirring for two hours, and the resulting resin solution was cooled in an ice bath to obtain a polysiloxane solution (PS-1). The obtained polysiloxane had an Mw of 4,500.

### Synthesis Example 6: Synthesis of Acrylic Resin Solution (AC-1)

In a three-neck flask, 0.821 g (1 mol %) of 2,2′-azobis(isobutyronitrile) and 29.29 g of PGMEA were well mixed. Next, 21.52 g (50 mol %) of MAA, 22.03 g (20 mol %) of TCDM, and 15.62 g (30 mol %) of STR were well mixed, and the resulting mixture was stirred at room temperature, sparged sufficiently with nitrogen in the flask, and then, stirred at 70° C. for five hours. To the resulting solution, a solution of 14.22 g (20 mol %) of GMA, 0.676 g (1 mol %) of dibenzylamine, and 0.186 g (0.3 mol %) of 4-methoxyphenol dissolved in 59.47 g of PGMEA was then added, and the resulting mixture was stirred at 90° C. for four hours to obtain an acrylic resin solution (AC-1). The obtained acrylic resin had an Mw of 15,000.

The formulations for Synthesis Examples 1 to 6 are listed in Table 1-1 to Table 1-3.

TABLE 1-1

| | | Monomer [molar ratio] | | | | | |
|---|---|---|---|---|---|---|---|
| | | Tetracarboxylic acid | | Diamine | | | End-capping |
| | Polymer | and derivative thereof | | and derivative thereof | | | agent |
| Synthesis | Polyimide | ODPA | — | BAHF | — | SiDA | MAP |
| Example 1 | (PI-1) | (100) | | (85) | | (5) | (20) |
| Synthesis | Polyimide precursor | — | 6FDA | BAHF | HA | SiDA | MAP |
| Example 2 | (PIP-1) | | (100) | (40) | (30) | (5) | (50) |

TABLE 1-2

| | | Monomer [molar ratio] | | | |
|---|---|---|---|---|---|
| | | Dicarboxylic | | | |
| | | acid and | Bisaminophenol | | |
| | | derivative thereof | compound and | | |
| | | Diformyl | derivative thereof | | |
| | | compound and | Dihydroxydiamine and | | End-capping |
| | Polymer | derivative thereof | derivative thereof | | agent |
| Synthesis | Polybenzoxazole | BFE | BAHF | SiDA | NA |
| Example 3 | (PBO-1) | (80) | (95) | (5) | (40) |
| Synthesis | Polybenzoxazole | BFE | BAHF | SiDA | NA |
| Example 4 | precursor | (80) | (95) | (5) | (40) |
| | (PBOP-1) | | | | |

| | | Monomer [mol %] | | | |
|---|---|---|---|---|---|
| | | | | | Tetrafunctional |
| | | | | | organosilane |
| | | | | | Tetrafunctional |
| | | | | | organosilane |
| | Polymer | Trifunctional organosilane | | | oligomer |
| Synthesis | Polysiloxane | MeTMS | PhTMS | cyEpoTMS | TMOS |
| Example 5 | solution | (30) | (50) | (10) | (10) |
| | (PS-1) | | | | |

TABLE 1-3

| | | Monomer [molar ratio] | | | |
|---|---|---|---|---|---|
| | | | | | Unsaturated compound |
| | | Copolymerized | Copolymerized | Copolymerized | having ethylenic |
| | | component | component | component | unsaturated double- |
| | | having | having | having | bond group |
| | Polymer | acidic group | aromatic group | alicyclic group | and epoxy group |
| Synthesis | Acrylic resin | MAA | STR | TCDM | GMA |
| Example 6 | solution (AC-1) | (50) | (30) | (20) | (20) |

### Preparation Example 1: Preparation of Pigment Dispersion Liquid (Bk-1)

With 782.0 g of MBA as a solvent, 34.5 g of S-20000 as a dispersant was mixed; the resulting mixture was stirred for ten minutes; and to the mixture, 103.5 g of Bk-S0100CF as a pigment was added; the resulting mixture was stirred for 30 minutes; and a horizontal type of bead mill containing zirconia beads having a diameter of 0.40 mm was used to carry out a wet type of media dispersion treatment in such a manner that the number-average particle size became 150 nm.

### Preparation Example 2: Preparation of Pigment Dispersion Liquid (Bk-2)

With 717.6 g of MBA as a solvent, 92.0 g of MBA solution of 30 mass % polyimide (PI-1) obtained in Synthesis Example 1, as a resin, and 27.6 g of S-20000 as a dispersant were mixed and diffused for ten minutes; and to the resulting mixture, 82.8 g of Bk-S0100CF as a pigment was added; the resulting mixture was stirred for 30 minutes; and a horizontal type of bead mill containing zirconia beads having a diameter of 0.40 mm was used to carry out a wet type of media dispersion treatment in such a manner that the number-average particle size became 150 nm.

### Preparation Examples 3 to 8: Preparation of Pigment Dispersion Liquid (Bk-3) to Pigment Dispersion Liquid (Bk-8)

The pigment, (A) alkali-soluble resin, and (E) dispersant, the kinds and ratios of which are described in Table 2-1, were dispersed in the same manner as in Preparation Example 2 to obtain a pigment dispersion liquid (Bk-3) to a pigment dispersion liquid (Bk-8).

The formulations for Preparation Examples 1 to 8 are listed in Table 2-1.

TABLE 2-1

| | | Composition [mass %] | | | | |
|---|---|---|---|---|---|---|
| | Dispersion liquid | Black pigment | | | (A) Alkali-soluble resin | (E) Dispersant |
| Preparation Example 1 | Pigment dispersion liquid | Bk-S0100CF | — | — | — | S-20000 |
| | (Bk-1) | (75) | | | | (25) |
| Preparation Example 2 | Pigment dispersion liquid | Bk-S0100CF | — | — | Polyimide | S-20000 |
| | (Bk-2) | (60) | | | (PI-1) | (20) |
| | | | | | (20) | |
| Preparation Example 3 | Pigment dispersion liquid | Bk-S0100CF | — | — | Polyimide | S-20000 |
| | (Bk-3) | (65) | | | (PI-1) | (10) |
| | | | | | (25) | |
| Preparation Example 4 | Pigment dispersion liquid | Bk-S0084 | — | — | Polyimide | D.BYK-167 |
| | (Bk-4) | (60) | | | (PI-1) | (20) |
| | | | | | (20) | |
| Preparation Example 5 | Pigment dispersion liquid | Bk-A1103 | — | — | Polyimide | D.BYK-167 |
| | (Bk-5) | (60) | | | (PI-1) | (20) |
| | | | | | (20) | |
| Preparation Example 6 | Pigment dispersion liquid | TPK-1227 | — | — | Polyimide | D.BYK-167 |
| | (Bk-6) | (60) | | | (PI-1) | (20) |
| | | | | | (20) | |
| Preparation Example 7 | Pigment dispersion liquid | P.R. 254 | P.Y. 139 | P.B. 15:6 | Polyimide | D.BYK-167 |
| | (Bk-7) | (21) | (9) | (30) | (PI-1) | (20) |
| | | | | | (20) | |
| Preparation Example 8 | Pigment dispersion liquid | P.V. 23 | P.Y. 139 | — | Polyimide | D.BYK-167 |
| | (Bk-8) | (30) | (30) | | (PI-1) | (20) |
| | | | | | (20) | |

The structural formulae of the (C1) oxime ester photo initiator (O-1) corresponding to the general formula (11), the (C1) oxime ester photo initiator (O-2) corresponding to the general formula (12), the (C1) oxime ester photo initiator (O-3) not corresponding to the general formulae (11) to (13), the (C₂) α-hydroxyketone photo initiators (H-1 to H-7), and the benzylketal photo initiator (B-1), which were used in Examples and Comparative Examples, are shown below.

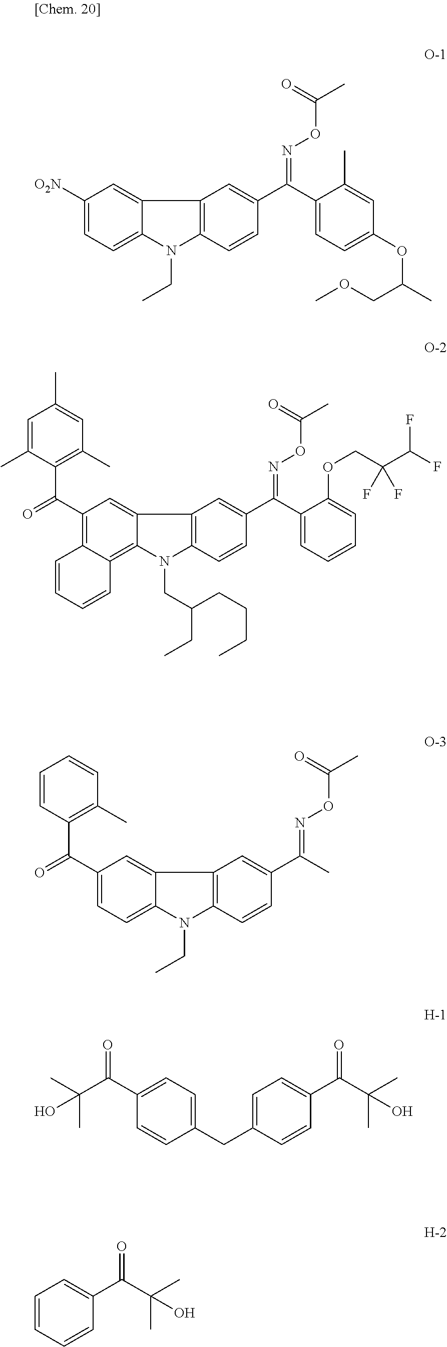

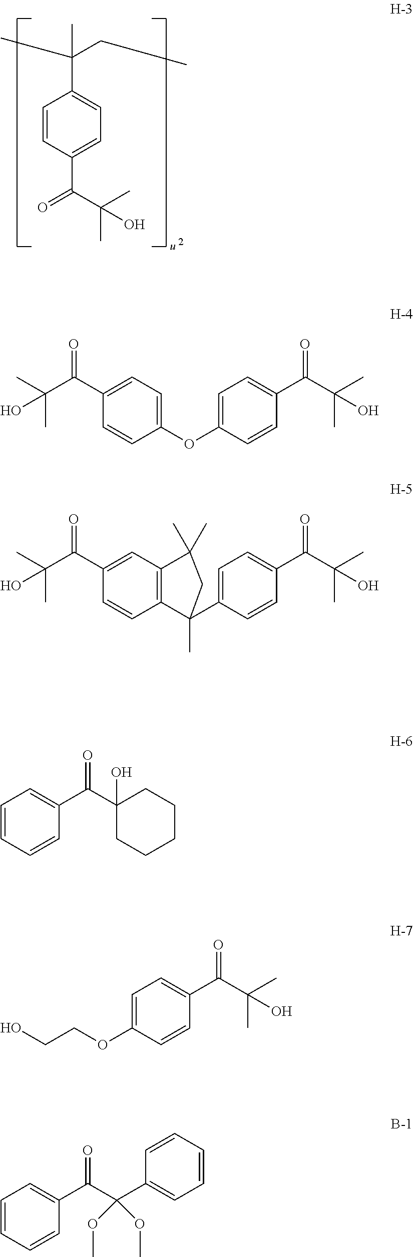

u² represents an integer of 2 to 5.

The evaluation methods in Examples and Comparative Examples are below-Mentioned.

(1) Weight-average molecular weight of resin

The weight-average molecular weight in terms of polystyrene was determined by measurement based on a method carried out near ordinary temperature in accordance with “JIS K7252-3(2008)” using a GPC analyzer (HLC-8220; manufactured by Tosoh Corporation) and using tetrahydrofuran or NMP as a fluid phase.

(2) Pretreatment of Substrate

A glass substrate (manufactured by Geomatec Co., Ltd.; hereinafter referred to as an “ITO substrate”), in which ITO was formed into a 100 nm film on a glass sheet using a sputter, was cleaned under UV-03 for 100 seconds using a tabletop type photo surface processor (PL16-110; manufactured by Sen Lights Corporation).

(3) Sensitivity

A prebaked film was produced by the method described in the below-mentioned Example 1 and underwent patterning exposure to the i-line (having a wavelength of 365 nm), h-line (having a wavelength of 405 nm), and g-line (having a wavelength of 436 nm) of an ultra-high-pressure mercury lamp using a double-side alignment one-side aligner (a mask aligner, PEM-6M; manufactured by Union Optical Co., Ltd.) via a grayscale mask for sensitivity measurement (MDRM MODEL 4000-5-FS; manufactured by Opto-Line International, Inc.), and then, the resulting film was developed using a small type developing device for photolithography (AD-2000; manufactured by Takizawa Sangyo K.K.) to produce a developed film of the negative photosensitive resin composition. Here, the details about the light exposure and development conditions are the same as described in Example 1.

An FPD/LSI inspection microscope (OPTIPHOT-300; manufactured by Nikon Corporation) was used to observe the resolution pattern of the produced developed film, and the exposure energy (a value on an i-line light meter) for forming a 20 μm line-and-space pattern with a one-to-one width was regarded as the sensitivity. The sensitivity value was rounded to whole numbers and rated as below-mentioned; a sensitivity value of 90 mJ/cm² or less was rated as acceptable, falling under A+, A, B, and C; a sensitivity value of 60 mJ/cm² or less was rated as good in sensitivity, falling under A+, A, and B; and a sensitivity value of 45 mJ/cm² or less was rated as excellent in sensitivity, falling under A+ and A.

A+: 1 to 30 mJ/cm² in sensitivity
A: 31 to 45 mJ/cm² in sensitivity
B: 46 to 60 mJ/cm² in sensitivity
C: 61 to 90 mJ/cm² in sensitivity
D: 91 to 150 mJ/cm² in sensitivity
E: 151 to 500 mJ/cm² in sensitivity

(4) Development Residue

A prebaked film was produced by the method described in the below-mentioned Example 1 and underwent patterning exposure to the i-line (having a wavelength of 365 nm), h-line (having a wavelength of 405 nm), and g-line (having a wavelength of 436 nm) of an ultra-high-pressure mercury lamp using a double-side alignment one-side aligner (a mask aligner, PEM-6M; manufactured by Union Optical Co., Ltd.) via a grayscale mask for sensitivity measurement (MDRM MODEL 4000-5-FS; manufactured by Opto-Line International, Inc.), and then, the resulting film was developed using a small type developing device for photolithography (AD-2000; manufactured by Takizawa Sangyo K.K.), followed by using a high-temperature inert gas oven (INH-9CD-S; manufactured by Koyo Thermo Systems Co., Ltd.) to produce a cured film of the negative photosensitive resin composition. Here, the details about the light exposure, development, and curing conditions are the same as described in Example 1.

The FPD/LSI inspection microscope (OPTIPHOT-300; manufactured by Nikon Corporation) was used to observe the resolution pattern of the produced cured film. The presence area of a residue in the opening can be determined in accordance with Sc/St×100(%) from the area (St) of the opening in the observed resolution pattern and the area (Sc) occupied by the residue derived from the pigment and present in the opening in the 20 μm line-and-space pattern. This determination was carried out for ten randomly selected line-and-space patterns, and the number average of the ten values was used. The presence area was rounded to whole numbers and rated as below-mentioned; a presence area of 10% or less occupied by the residue in the opening was rated as acceptable, falling under A+, A, and B; a presence area of 5% or less occupied by the residue in the opening was rated as good against a development residue, falling under A+ and A; and no presence area occupied by the residue in the opening was rated as excellent against a development residue, falling under A+.

A+: no residue in the opening
A: a presence area of 1 to 5% occupied by the residue in the opening
B: a presence area of 6 to 10% occupied by the residue in the opening
C: a presence area of 11 to 30% occupied by the residue in the opening
D: a presence area of 31 to 50% occupied by the residue in the opening
E: a presence area of 51 to 100% occupied by the residue in the opening

(5) Cross-Sectional Shape of Pattern

A prebaked film was produced by the method described in the below-mentioned Example 1 and underwent patterning exposure to the i-line (having a wavelength of 365 nm), h-line (having a wavelength of 405 nm), and g-line (having a wavelength of 436 nm) of an ultra-high-pressure mercury lamp using a double-side alignment one-side aligner (a mask aligner, PEM-6M; manufactured by Union Optical Co., Ltd.) via a grayscale mask for sensitivity measurement (MDRM MODEL 4000-5-FS; manufactured by Opto-Line International, Inc.), and then, the resulting film was developed using a small type developing device for photolithography (AD-2000; manufactured by Takizawa Sangyo K.K.), followed by using a high-temperature inert gas oven (INH-9CD-S; manufactured by Koyo Thermo Systems Co., Ltd.) to produce a cured film of the negative photosensitive resin composition. Here, the details about the light exposure, development, and curing conditions are the same as described in Example 1.

Using a field emission type scanning electron microscope (S-4800; manufactured by Hitachi High-Technologies Corporation), the cross-section of a line-and-space pattern which was among the resolution patterns of the produced cured film and had a space dimension width of 20 μm was observed to measure the cone angle of the cross-section. The cone angle value was rounded to whole numbers and rated as below-mentioned; a cone angle of 600 or less in the cross-section was rated as acceptable, falling under A+, A, and B; a cone angle of 45 or less in the cross-section was rated as good in pattern shape, falling under A+ and A; and a cone angle of 30° or less in the cross-section was rated as excellent in pattern shape, falling under A+.

A+: a cone angle of 1 to 30° in the cross-section
A: a cone angle of 31 to 45 in the cross-section
B: a cone angle of 46 to 60° in the cross-section
C: a cone angle of 61 to 70° in the cross-section
D: a cone angle of 71 to 80 in the cross-section
E: a cone angle of 81 to 179 in the cross-section

(6) Heat Resistance (High-Temperature Weight Residual Ratio Difference)

A prebaked film was produced by the method described in the below-mentioned Example 1 and underwent patterning exposure to the i-line (having a wavelength of 365 nm), h-line (having a wavelength of 405 nm), and g-line (having a wavelength of 436 nm) of an ultra-high-pressure mercury lamp using a double-side alignment one-side aligner (a mask aligner, PEM-6M; manufactured by Union Optical Co., Ltd.) via a grayscale mask for sensitivity measurement (MDRM MODEL 4000-5-FS; manufactured by Opto-Line International, Inc.), and then, the resulting film was developed using a small type developing device for photolithography (AD-2000; manufactured by Takizawa Sangyo K.K.), followed by using a high-temperature inert gas oven (INH-9CD-S; manufactured by Koyo Thermo Systems Co., Ltd.) to produce a cured film of the negative photosensitive resin composition. Here, the details about the light exposure, development, and curing conditions are the same as described in Example 1.

After the thermosetting, the produced cured film was shaved from the substrate, and approximately 10 mg of the shaved film was placed in an aluminium cell. This aluminium cell was retained in a nitrogen atmosphere at 30° C. for ten minutes using a thermogravimetric analyzer (TGA-50; manufactured by Shimadzu Corporation), then heated to 150° C. at a heating speed of 10° C./min., then retained at 150° C. for 30 minutes, and further heated to 500° C. at a heating speed of 10° C./min., carrying out thermogravimetric analysis. With respect to 100 mass % of the weight obtained after heating at 150° C. for 30 minutes, the weight residual ratio at 350° C. obtained by further heating was defined as (Mₐ) mass %, the weight residual ratio at 400° C. obtained likewise was defined as (M_{b}) mass %, and the high-temperature weight residual ratio difference ((Mₐ)−(M_{b})) was calculated as an index of heat resistance.

The high-temperature weight residual ratio difference value was rounded to the first decimal place and rated as below-mentioned; a high-temperature weight residual ratio difference of 25.0 mass % or less was rated as acceptable, falling under A+, A, and B; a high-temperature weight residual ratio difference of 15.0% or less was rated as good in heat resistance, falling under A+ and A; and a high-temperature weight residual ratio difference of 5.0% or less was rated as excellent in heat resistance, falling under A+.

A+: a high-temperature weight residual ratio difference of 0 to 5.0%
A: a high-temperature weight residual ratio difference of 5.1 to 15.0%
B: a high-temperature weight residual ratio difference of 15.1 to 25.0%
C: a high-temperature weight residual ratio difference of 25.1 to 35.0%
D: a high-temperature weight residual ratio difference of 35.1 to 45.0%
E: a high-temperature weight residual ratio difference of 45.1 to 100%

(7) Light-Blocking Ability (Optical Density (Hereinafter Referred to as “OD”) value)

A prebaked film was produced by the method described in the below-mentioned Example 1 and underwent patterning exposure to the i-line (having a wavelength of 365 nm), h-line (having a wavelength of 405 nm), and g-line (having a wavelength of 436 nm) of an ultra-high-pressure mercury lamp using a double-side alignment one-side aligner (a mask aligner, PEM-6M; manufactured by Union Optical Co., Ltd.) via a grayscale mask for sensitivity measurement (MDRM MODEL 4000-5-FS; manufactured by Opto-Line International, Inc.), and then, the resulting film was developed using a small type developing device for photolithography (AD-2000; manufactured by Takizawa Sangyo K.K.), followed by using a high-temperature inert gas oven (INH-9CD-S; manufactured by Koyo Thermo Systems Co., Ltd.) to produce a cured film of the negative photosensitive resin composition. Here, the details about the light exposure, development, and curing conditions are the same as described in Example 1.

A transmission densitometer (X-Rite 361T(V); manufactured by X-Rite Inc.) was used to measure the incident light intensity (I₀) and transmitted light intensity (I) of the produce cured film. The OD value was calculated as an index of light-blocking ability in accordance with the following equation.

OD value=log₁₀(I₀/I)

(8) Insulation Properties (Surface Resistivity)

A prebaked film was produced by the method described in the below-mentioned Example 1 and underwent patterning exposure to the i-line (having a wavelength of 365 nm), h-line (having a wavelength of 405 nm), and g-line (having a wavelength of 436 nm) of an ultra-high-pressure mercury lamp using a double-side alignment one-side aligner (a mask aligner, PEM-6M; manufactured by Union Optical Co., Ltd.) via a grayscale mask for sensitivity measurement (MDRM MODEL 4000-5-FS; manufactured by Opto-Line International, Inc.), and then, the resulting film was developed using a small type developing device for photolithography (AD-2000; manufactured by Takizawa Sangyo K.K.), followed by using a high-temperature inert gas oven (INH-9CD-S; manufactured by Koyo Thermo Systems Co., Ltd.) to produce a cured film of the negative photosensitive resin composition. Here, the details about the light exposure, development, and curing conditions are the same as described in Example 1.

A high-resistance resistivity meter (“High Rester” UP; manufactured by Mitsubishi Chemical Corporation) was used to measure the surface resistivity (Q/Q) of the produced cured film.

(9) Light-Emitting Characteristics of Organic EL Display Device

(Method of Producing Organic EL Display Device)

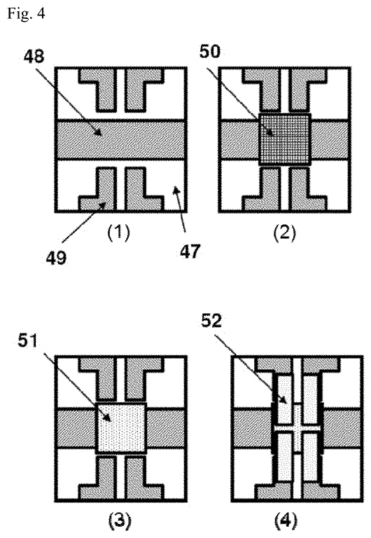

FIGS. 4 (1) to 4 (4) depict the schematic views of a substrate used. First, a 10 nm ITO transparent conductive coating was formed on the whole surface of a 38×46 mm non-alkali glass substrate 47 by sputtering, and etched as a first electrode 48 to form a transparent electrode. In addition, an auxiliary electrode 49 was simultaneously formed to create a second electrode (FIG. 3 (1)). The obtained substrate was subjected to ultrasonic cleaning with “SEMICOCLEAN” (registered trademark) 56 (manufactured by Furuuchi Chemical Corporation) for ten minutes, and cleaned with ultrapure water. Next, the negative photosensitive resin composition was applied and prebaked on this substrate using the method described in Example 1, subjected to patterning exposure via a photomask having a predetermined pattern, developed, rinsed, and then thermoset by heating. In the above-mentioned manner, an insulation layer 50 was formed so as to be limited to the effective area on the substrate, wherein the insulation layer was shaped in such a manner that the openings having a width of 70 μm and a length of 260 μm were arranged at intervals of 155 μm in the width direction and intervals of 465 μm in the length direction, and each opening allowed the first electrode to be exposed (FIG. 3 (2)). In this regard, this opening finally resulted in a light-emitting pixel of an organic EL display device. In addition, the effective area on the substrate was 16 mm square, and the insulation layer 50 was formed to have a thickness of approximately 1.0 μm.

Next, an organic EL display device was produced using the substrate having the first electrode 48, auxiliary electrode 49, and insulation layer 50 formed thereon. After undergoing nitrogen plasma treatment as a pretreatment, an organic EL layer 51 containing a light-emitting layer was formed by vacuum deposition (FIG. 3 (3)). Here, the degree of vacuum was 1×10⁻³ Pa or less during vapor deposition, and the substrate was rotated relative to the vapor deposition source during vapor deposition. First, the compound (HT-1), 10 nm, as a positive hole injection layer and the compound (HT-2), 50 nm, as a hole transporting layer were vapor-deposited. Next, the compound (GH-1) as a host material and the compound (GD-1) as a dopant material were vapor-deposited on the light-emitting layer to have a thickness of 40 nm in such a manner that the dope concentration was 10%. Then, the compound (ET-1) and compound (LiQ) as electron transporting materials were laminated at a volume ratio of 1:1 to have a thickness of 40 nm. The structures of the compounds used for the organic EL layer are shown below.

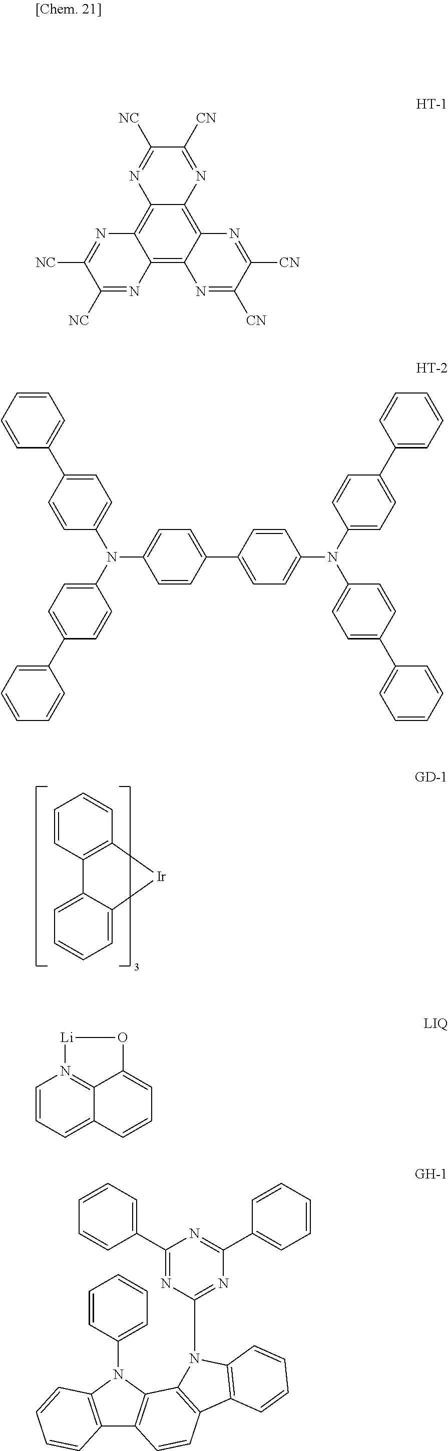

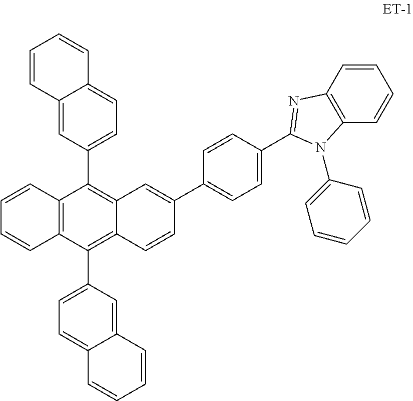 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

Next, the compound (LiQ), 2 nm, was vapor-deposited, and then, MgAg, 100 nm, was vapor-deposited at a volume ratio of 10:1 to form a reflecting electrode as a second electrode 52 (FIG. 3 (4)). Then, an epoxy resin adhesive was used under a low-humidity nitrogen atmosphere to adhere a cap-shaped glass plate for sealing, thus producing four 5 mm square bottom emission type organic EL display devices on one substrate. The film thickness mentioned here refers to a value displayed on a crystal oscillation type film thickness monitor.

(Light-Emitting Characteristics Evaluation)

The organic EL display device produced in the above-mentioned manner was allowed to emit light by DC drive at 10 mA/cm² and observed for any light-emitting failure such as a non-light-emitting region or brightness nonuniformity. The produced organic EL display device was retained at 80° C. for 500 hours in a durability test. After the durability test, the organic EL display device was allowed to emit light by DC drive at 10 mA/cm² and observed for any change in light-emitting characteristics such as a light-emitting region and brightness nonuniformity. After the durability test, the characteristics were determined as the retention ratio between the light-emitting region areas retained before and after the durability test, in other words, determined in accordance with Nc/Nt×100(%) from the area (Nc) of the pixels having no light-emitting failure after the durability test with respect to the area (Nt) of the pixels having no light-emitting failure before the durability test. This determination was carried out for 20 randomly selected pixels, and the number average of the 20 values was used. In this determination, any light-emitting region the brightness of which was changed between before and after the durability test was regarded as causing brightness nonuniformity, and the region that caused brightness nonuniformity was regarded as not light-emitting. The light-emitting region area value was rounded to whole numbers and rated as below-mentioned; and, assuming that the light-emitting region area was 100% before the durability test, the light-emitting region area of 80% or more after the durability test was rated as acceptable, falling under A+, A, and B; the light-emitting region area of 90% or more was rated as good in light-emitting characteristics, falling under A+ and A; and the light-emitting region area of 95% or more was rated as excellent in light-emitting characteristics, falling under A+.

A+: a retention ratio of 95 to 100% for the light-emitting region area
A: a retention ratio of 90 to 94% for the light-emitting region area
B: a retention ratio of 80 to 89% for the light-emitting region area
C: a retention ratio of 70 to 79% for the light-emitting region area
D: a retention ratio of 50 to 69% for the light-emitting region area
E: a retention ratio of 0 to 49% for the light-emitting region area

### Example 1

Under yellow light, 0.324 g of 0-1 and 0.017 g of H-1 were weighed out, and into these, 6.533 g of MBA and 5.100 g of PGMEA were added and dissolved by stirring. Next, to the resulting mixture, 5.059 g of MBA solution of 30 mass % polyimide (PI-1) obtained in Synthesis Example 1 and 1.989 g of MBA solution of 50 mass % DPHA were added and stirred to obtain a preparation solution in the form of a uniform solution. Next, 9.149 g of the pigment dispersion liquid (Bk-2) obtained in Preparation Example 2 was weighed out, and to this, 15.851 g of the preparation solution obtained above was added followed by stirring the resultant mixture to obtain a uniform solution. Then, the resulting solution was filtrated through a 0.45 μm φ filter to prepare a composition 1.

The prepared composition 1 was applied to an ITO substrate by spin coating using a spin coater (MS-A100; manufactured by Mikasa Co., Ltd.) at any rotational speed and prebaked at 110° C. for 120 seconds using a buzzer hot plate (HPD-3000BZN; manufactured by As One Corporation) to produce a prebaked film having a film thickness of approximately 1.8 μm.

The produced prebaked film was subjected to spray development with an aqueous solution of 2.38 mass % TMAH using a small type developing device for photolithography (AD-2000; manufactured by Takizawa Sangyo K.K.), and the time (Breaking Point; hereinafter referred to as “B. P.”) taken until the prebaked film (unexposed portion) was completely dissolved was measured.

In the same manner as above, a prebaked film was produced, and the produced prebaked film underwent patterning exposure to the i-line (having a wavelength of 365 nm), h-line (having a wavelength of 405 nm), and g-line (having a wavelength of 436 nm) of an ultra-high-pressure mercury lamp using a double-side alignment one-side aligner (a mask aligner, PEM-6M; manufactured by Union Optical Co., Ltd.) via a grayscale mask for sensitivity measurement (MDRM MODEL 4000-5-FS; manufactured by Opto-Line International, Inc.). After the light exposure, a small type developing device for photolithography (AD-2000; manufactured by Takizawa Sangyo K.K.) was used to apply an aqueous solution of 2.38 mass % TMAH for ten seconds, followed by puddle development and rinsing with water for 30 seconds. The development time was set to 1.5 times longer than B. P. Here, the development time is the total of ten seconds for applying the aqueous solution of 2.38 mass % TMAH and the time for puddle development.

After the development, a high-temperature inert gas oven (INH-9CD-S; manufactured by Koyo Thermo Systems Co., Ltd.) was used to thermoset the film at 250° C. to produce a cured film having a film thickness of 1.2 μm. The thermosetting conditions included thermosetting at 250° C. for 60 minutes under a nitrogen atmosphere.

### Examples 2 to 28 and Comparative Examples 1 to 9

In the same manner as in Example 1, compositions 2 to 37 were prepared in accordance with the formulations described in Table 3-1, Table 4-1, and Table 5-1. Each of the obtained compositions was used to form a film of the composition on a substrate in the same manner as in Example 1, and the photosensitive characteristics and the characteristics of the cured film were evaluated. The evaluation results are listed in Table 3-2, Table 4-2, and Table 5-2.

TABLE 3-1

| | | | | | | | | | Content ratio | Content ratio | |
|---|---|---|---|---|---|---|---|---|---|---|---|
| | | | Composition [parts by mass] | | | | | | of (C1) | of (C2) α- | Content ratio |
| | | Pig- | | (B) | (C1) | (C2) α- | | | oxime ester | hydroxy- | of (Da) black |
| | | ment | (A) | Radical | Oxime | hydroxy- | | | initiator in | ketone | pigment in |
| | | disper- | Alkali- | polymer- | ester | ketone | | | (C) photo | initiator in (C) | all solid |
| | Compo- | sion | soluble | izable | photo | photo | (Da) Black | (E) | initiator | photo initiator | contents |
| | sition | liquid | resin | compound | initiator | initiator | pigment | Dispersant | (%) | (%) | [mass %] |
| Example 1 | 1 | Bk-2 | PI-1 | DPHA (35) | O-1 | H-1 | Bk-S0100CF | S-20000 | 95 | 5 | 22.0 |
| | | | (65) | | (11.4) | (0.6) | (34.8) | (11.6) | | | |
| Example 2 | 2 | Bk-2 | PI-1 | DPHA (35) | O-1 | H-1 | Bk-S0100CF | S-20000 | 90 | 10 | 22.0 |
| | | | (65) | | (10.8) | (1.2) | (34.8) | (11.6) | | | |
| Example 3 | 3 | Bk-2 | PI-1 | DPHA (35) | O-1 | H-1 | Bk-S0100CF | S-20000 | 85 | 15 | 22.0 |
| | | | (65) | | (10.2) | (1.8) | (34.8) | (11.6) | | | |
| Example 4 | 4 | Bk-2 | PI-1 | DPHA (35) | O-1 | H-1 | Bk-S0100CF | S-20000 | 75 | 25 | 22.0 |
| | | | (65) | | (9.0) | (3.0) | (34.8) | (11.6) | | | |
| Example 5 | 5 | Bk-2 | PI-1 | DPHA (35) | O-1 | H-1 | Bk-S0100CF | S-20000 | 70 | 30 | 22.0 |
| | | | (65) | | (8.4) | (3.6) | (34.8) | (11.6) | | | |
| Example 6 | 6 | Bk-2 | PI-1 | DPHA (35) | O-1 | H-1 | Bk-S0100CF | S-20000 | 60 | 40 | 22.0 |
| | | | (65) | | (7.2) | (4.8) | (34.8) | (11.6) | | | |
| Example 7 | 7 | Bk-2 | PI-1 | DPHA (35) | O-1 | H-1 | Bk-S0100CF | S-20000 | 55 | 45 | 22.0 |
| | | | (65) | | (6.6) | (5.4) | (34.8) | (11.6) | | | |
| Example 8 | 8 | Bk-2 | PI-1 | DPHA (35) | O-1 | H-1 | Bk-S0100CF | S-20000 | 51 | 49 | 22.0 |
| | | | (65) | | (6.1) | (5.9) | (34.8) | (11.6) | | | |
| Example 9 | 9 | Bk-2 | PI-1 | DPHA (35) | O-1 | H-1 | Bk-S0100CF | S-20000 | 75 | 25 | 22.0 |
| | | | (12) | | (9.0) | (3.0) | (34.8) | (11.6) | | | |
| | | | PIP-1 | | | | | | | | |
| | | | (53) | | | | | | | | |
| Example 10 | 10 | Bk-2 | PI-1 | DPHA (35) | O-1 | H-1 | Bk-S0100CF | S-20000 | 75 | 25 | 22.0 |
| | | | (12) | | (9.0) | (3.0) | (34.8) | (11.6) | | | |
| | | | PBO-1 | | | | | | | | |
| | | | (53) | | | | | | | | |
| Example 11 | 11 | Bk-2 | PI-1 | DPHA (35) | O-1 | H-1 | Bk-S0100CF | S-20000 | 75 | 25 | 22.0 |
| | | | (12) | | (9.0) | (3.0) | (34.8) | (11.6) | | | |
| | | | PBOP-1 | | | | | | | | |
| | | | (53) | | | | | | | | |
| Example 12 | 12 | Bk-2 | PI-1 | DPHA (35) | O-1 | H-1 | Bk-S0100CF | S-20000 | 75 | 25 | 22.0 |
| | | | (50) | | (9.0) | (3.0) | (34.8) | (11.6) | | | |
| | | | PS-1 | | | | | | | | |
| | | | (15) | | | | | | | | |

TABLE 3-2

| | | Photosensitive characteristics/Cured film characteristics | | | | | | Light-emitting characteristics | |
|---|---|---|---|---|---|---|---|---|---|
| | | | | | Heat resistance | | Insulation | of organic EL display device | |
| | | | | | High-temperature | Light- | properties | | Characteristics |
| | | | Development | Cross-sectional | weight residual | blocking | Surface | | after durability |
| | Compo- | Sensitivity | residue | shape of pattern | ratio difference | OD | resistivity | Initial | test |
| | sition | [mJ/cm²] | [%] | [°] | [mass %] | value | [Ω/□] | characteristics | [%] |
| Example 1 | 1 | 30 | 10 | 57 | 10.3 | 1.0 | >1.0 × 10\hat{ }15 | good | 100 |
| | | A+ | B | B | A | | | | A+ |
| Example 2 | 2 | 32 | 6 | 51 | 9.0 | 1.0 | >1.0 × 10\hat{ }15 | good | 100 |
| | | A | B | B | A | | | | A+ |
| Example 3 | 3 | 35 | 3 | 45 | 7.5 | 1.0 | >1.0 × 10\hat{ }15 | good | 100 |
| | | A | A | A | A | | | | A+ |
| Example 4 | 4 | 40 | 3 | 40 | 7.7 | 1.0 | >1.0 × 10\hat{ }15 | good | 100 |
| | | A | A | A | A | | | | A+ |
| Example 5 | 5 | 42 | 5 | 38 | 8.8 | 1.0 | >1.0 × 10\hat{ }15 | good | 100 |
| | | A | A | A | A | | | | A+ |
| Example 6 | 6 | 45 | 5 | 35 | 9.8 | 1.0 | >1.0 × 10\hat{ }15 | good | 100 |
| | | A | A | A | A | | | | A+ |
| Example 7 | 7 | 50 | 7 | 35 | 8.9 | 1.0 | >1.0 × 10\hat{ }15 | good | 100 |
| | | B | B | A | A | | | | A+ |
| Example 8 | 8 | 55 | 9 | 35 | 7.6 | 1.0 | >1.0 × 10\hat{ }15 | good | 100 |
| | | B | B | A | A | | | | A+ |
| Example 9 | 9 | 38 | 3 | 40 | 18.3 | 1.0 | >1.0 × 10\hat{ }15 | good | 100 |
| | | A | A | A | B | | | | A+ |
| Example 10 | 10 | 43 | 3 | 40 | 8.7 | 1.0 | >1.0 × 10\hat{ }15 | good | 100 |
| | | A | A | A | A | | | | A+ |
| Example 11 | 11 | 38 | 3 | 40 | 18.5 | 1.0 | >1.0 × 10\hat{ }15 | good | 100 |
| | | A | A | A | B | | | | A+ |
| Example 12 | 12 | 30 | 3 | 40 | 6.6 | 1.0 | >1.0 × 10\hat{ }15 | good | 100 |
| | | A+ | A | A | A | | | | A+ |

TABLE 4-1

| | | | | | | | | | Content ratio | Content ratio | |
|---|---|---|---|---|---|---|---|---|---|---|---|
| | | | Composition [parts by mass] | | | | | | of (C1) | of (C2) α- | Content ratio |
| | | Pig- | | (B) | (C1) | (C2) α- | | | oxime ester | hydroxy- | of (Da) black |
| | | ment | (A) | Radical | Oxime | hydroxy- | | | initiator in | ketone | pigment in |
| | | disper- | Alkali- | polymer- | ester | ketone | | (E) | (C) photo | initiator in (C) | all solid |
| | Compo- | sion | soluble | izable | photo | photo | (Da) Black | Disper- | initiator | photo initiator | contents |
| | sition | liquid | resin | compound | initiator | initiator | pigment | sant | (%) | (%) | [mass %] |
| Example 13 | 13 | Bk-2 | PI-1 | DPHA (10) | O-1 | H-1 | Bk-S0100CF | S-20000 | 75 | 25 | 22.0 |
| | | | (65) | DPCA-60 (25) | (9.0) | (3.0) | (34.8) | (11.6) | | | |
| Example 14 | 14 | Bk-2 | PI-1 | DPHA (35) | O-2 | H-1 | Bk-S0100CF | S-20000 | 75 | 25 | 22.0 |
| | | | (65) | | (9.0) | (3.0) | (34.8) | (11.6) | | | |
| Example 15 | 15 | Bk-2 | PI-1 | DPHA (35) | O-3 | H-1 | Bk-S0100CF | S-20000 | 75 | 25 | 22.0 |
| | | | (65) | | (9.0) | (3.0) | (34.8) | (11.6) | | | |
| Example 16 | 16 | Bk-2 | PI-1 | DPHA (35) | O-1 | H-2 | Bk-S0100CF | S-20000 | 75 | 25 | 22.0 |
| | | | (65) | | (9.0) | (3.0) | (34.8) | (11.6) | | | |
| Example 17 | 17 | Bk-2 | PI-1 | DPHA (35) | O-1 | H-3 | Bk-S0100CF | S-20000 | 75 | 25 | 22.0 |
| | | | (65) | | (9.0) | (3.0) | (34.8) | (11.6) | | | |
| Example 18 | 18 | Bk-1 | PI-1 | DPHA (35) | O-1 | H-1 | Bk-S0100CF | S-20000 | 75 | 25 | 22.0 |
| | | | (65) | | (9.0) | (3.0) | (34.9) | (11.6) | | | |
| Example 19 | 19 | Bk-3 | PI-1 | DPHA (35) | O-1 | H-1 | Bk-S0100CF | S-20000 | 75 | 25 | 45.0 |
| | | | (65) | | (9.0) | (3.0) | (103.7) | (16.0) | | | |
| Example 20 | 20 | Bk-4 | PI-1 | DPHA (35) | O-1 | H-1 | Bk-S0084 | S-20000 | 75 | 25 | 29.0 |
| | | | (65) | | (9.0) | (3.0) | (52.9) | (17.6) | | | |
| Example 21 | 21 | Bk-5 | PI-1 | DPHA (35) | O-1 | H-1 | Bk-A1103 | S-20000 | 75 | 25 | 25.0 |
| | | | (65) | | (9.0) | (3.0) | (42.0) | (14.0) | | | |
| Example 22 | 22 | Bk-6 | PI-1 | DPHA (35) | O-1 | H-1 | TPK-1227 | S-20000 | 75 | 25 | 16.0 |
| | | | (65) | | (9.0) | (3.0) | (22.8) | (7.6) | | | |
| Example 23 | 23 | Bk-7 | PI-1 | DPHA (35) | O-1 | H-1 | P.R. 254 | S-20000 | 75 | 25 | 34.0 |
| | | | (65) | | (9.0) | (3.0) | (24.4) | (23.2) | | | |
| | | | | | | | P.Y. 139 | | | | |
| | | | | | | | (10.4) | | | | |
| | | | | | | | P.B. 15:6 | | | | |
| | | | | | | | (34.8) | | | | |
| Example 24 | 24 | Bk-8 | PI-1 | DPHA (35) | O-1 | H-1 | P.V. 23 | S-20000 | 75 | 25 | 34.0 |
| | | | (65) | | (9.0) | (3.0) | (34.8) | (23.2) | | | |
| | | | | | | | P.Y. 139 | | | | |
| | | | | | | | (34.8) | | | | |
| Example 25 | 34 | Bk-2 | PI-1 | DPHA (35) | O-1 | H-4 | Bk-S0100CF | S-20000 | 75 | 25 | 22.0 |
| | | | (65) | | (9.0) | (3.0) | (34.8) | (11.6) | | | |
| Example 26 | 35 | Bk-2 | PI-1 | DPHA (35) | O-1 | H-5 | Bk-S0100CF | S-20000 | 75 | 25 | 22.0 |
| | | | (65) | | (9.0) | (3.0) | (34.8) | (11.6) | | | |
| Example 27 | 36 | Bk-2 | PI-1 | DPHA (35) | O-1 | H-6 | Bk-S0100CF | S-20000 | 75 | 25 | 22.0 |
| | | | (65) | | (9.0) | (3.0) | (34.8) | (11.6) | | | |
| Example 28 | 37 | Bk-2 | PI-1 | DPHA (35) | O-1 | H-7 | Bk-S0100CF | S-20000 | 75 | 25 | 22.0 |
| | | | (65) | | (9.0) | (3.0) | (34.8) | (11.6) | | | |

TABLE 4-2

| | | Photosensitive characteristics/Cured film characteristics | | | | | | Light-emitting characteristics | |
|---|---|---|---|---|---|---|---|---|---|
| | | | | Cross-sectional | Heat resistance | | | of organic EL display device | |
| | | | Develop- | shape of pattern | High-temperature | | Insulation | | Characteristics |
| | | | ment | after | weight residual ratio | Light- | properties | | after |
| | Compo- | Sensitivity | residue | thermosetting | difference | blocking | Surface resistivity | Initial | durability test |
| | sition | [mJ/cm²] | [%] | [°] | [mass %] | OD value | [Ω/□] | characteristics | [%] |
| Example 13 | 13 | 30 | 0 | 20 | 6.4 | 1.0 | >1.0 × 10\hat{ }15 | good | 100 |
| | | A+ | A+ | A+ | A | | | | A+ |
| Example 14 | 14 | 40 | 5 | 40 | 8.1 | 1.0 | >1.0 × 10\hat{ }15 | good | 100 |
| | | A | A | A | A | | | | A+ |
| Example 15 | 15 | 60 | 10 | 47 | 9.3 | 1.0 | >1.0 × 10\hat{ }15 | good | 100 |
| | | C | B | B | A | | | | A+ |
| Example 16 | 16 | 45 | 5 | 35 | 7.1 | 1.0 | >1.0 × 10\hat{ }15 | good | 100 |
| | | A | A | A | A | | | | A+ |
| Example 17 | 17 | 40 | 2 | 30 | 6.5 | 1.0 | >1.0 × 10\hat{ }15 | good | 100 |
| | | A | A | A+ | A | | | | A+ |
| Example 18 | 18 | 40 | 5 | 40 | 9.6 | 1.0 | >1.0 × 10\hat{ }15 | good | 100 |
| | | A | A | A | A | | | | A+ |
| Example 19 | 19 | 65 | 7 | 35 | 12.5 | 2.0 | >1.0 × 10\hat{ }15 | good | 100 |
| | | C | B | A | A | | | | A+ |
| Example 20 | 20 | 44 | 5 | 40 | 7.9 | 1.0 | >1.0 × 10\hat{ }15 | good | 100 |
| | | A | A | A | A | | | | A+ |
| Example 21 | 21 | 44 | 5 | 39 | 8.0 | 1.0 | >1.0 × 10\hat{ }15 | good | 100 |
| | | A | A | A | A | | | | A+ |
| Example 22 | 22 | 60 | 5 | 40 | 10.6 | 1.0 | 1.0 × 10\hat{ }13 | good | 80 |
| | | B | A | A | A | | | | B |
| Example 23 | 23 | 55 | 5 | 36 | 10.8 | 1.0 | 1.0 × 10\hat{ }14 | good | 90 |
| | | B | A | A | A | | | | A |
| Example 24 | 24 | 55 | 5 | 36 | 10.7 | 1.0 | 1.0 × 10\hat{ }14 | good | 90 |
| | | B | A | A | A | | | | A |
| Example 25 | 34 | 40 | 3 | 33 | 7.0 | 1.0 | >1.0 × 10\hat{ }15 | good | 100 |
| | | A | A | A | A | | | | A+ |
| Example 26 | 35 | 40 | 3 | 32 | 7.1 | 1.0 | >1.0 × 10\hat{ }15 | good | 100 |
| | | A | A | A | A | | | | A+ |
| Example 27 | 36 | 45 | 5 | 43 | 7.9 | 1.0 | >1.0 × 10\hat{ }15 | good | 100 |
| | | A | A | A | A | | | | A+ |
| Example 28 | 37 | 45 | 5 | 42 | 8.7 | 1.0 | >1.0 × 10\hat{ }15 | good | 100 |
| | | A | A | A | A | | | | A+ |

TABLE 5-1

| | | | | | | | | | | | Content | Content |
|---|---|---|---|---|---|---|---|---|---|---|---|---|
| | | | | | | | | | | Content | ratio of | ratio |
| | | | | | | | | | | ratio | (C2) α- | of (Da) |
| | | | Composition [parts by mass] | | | | | | | of (C1) | hydroxy- | black |
| | | Pig- | | (B) | (C1) | (C2) α- | (C) Photo | | | oxime ester | ketone | pigment |
| | | ment | (A) | Radical | oxime | hydroxy- | initiator | | | initiator in | initiator in | in |
| | | disper- | Alkali- | polymer- | ester | ketone | other than | (Da) | (E) | (C) photo | (C) photo | all solid |
| | Compo- | sion | soluble | izable | photo | photo | (C1) and | Black | Disper- | initiator | initiator | contents |
| | sition | liquid | resin | compound | initiator | initiator | (C2) | pigment | sant | (%) | (%) | [mass %] |
| Comparative | 25 | Bk-2 | PI-1 | DPHA | O-1 | — | — | Bk-S0100CF | S-20000 | 100 | 0 | 22.0 |
| Example 1 | | | (65) | (35) | (12.0) | | | (34.8) | (11.6) | | | |
| Comparative | 26 | Bk-2 | PI-1 | DPHA | O-1 | H-1 | — | Bk-S0100CF | S-20000 | 50 | 50 | 22.0 |
| Example 2 | | | (65) | (35) | (6.0) | (6.0) | | (34.8) | (11.6) | | | |
| Comparative | 27 | Bk-2 | PI-1 | DPHA | O-1 | H-1 | — | Bk-S0100CF | S-20000 | 25 | 75 | 22.0 |
| Example 3 | | | (65) | (35) | (3.0) | (9.0) | | (34.8) | (11.6) | | | |
| Comparative | 28 | Bk-2 | PI-1 | DPHA | — | H-1 | — | Bk-S0100CF | S-20000 | 0 | 100 | 22.0 |
| Example 4 | | | (65) | (35) | | (12.0) | | (34.8) | (11.6) | | | |
| Comparative | 29 | Bk-2 | PI-1 | DPHA | O-1 | H-1 | — | Bk-S0100CF | S-20000 | 75 | 25 | 22.0 |
| Example 5 | | | (12) | (35) | (9.0) | (3.0) | | (34.8) | (11.6) | | | |
| | | | AC-1 | | | | | | | | | |
| | | | (53) | | | | | | | | | |
| Comparative | 30 | Bk-2 | PI-1 | DPHA | — | H-1 | B-1 | Bk-S0100CF | S-20000 | 0 | 25 | 22.0 |
| Example 6 | | | (65) | (35) | | (3.0) | (9.0) | (34.8) | (11.6) | | | |
| Comparative | 31 | Bk-2 | PI-1 | DPHA | O-1 | — | B-1 | Bk-S0100CF | S-20000 | 75 | 0 | 22.0 |
| Example 7 | | | (65) | (35) | (9.0) | | (3.0) | (34.8) | (11.6) | | | |
| Comparative | 32 | — | PI-1 | DPHA | O-1 | H-1 | — | — | — | 75 | 25 | 0.0 |
| Example 8 | | | (65) | (35) | (9.0) | (3) | | | | | | |
| Comparative | 33 | Bk-3 | PI-1 | DPHA | O-1 | H-1 | — | Bk-S0100CF | S-20000 | 75 | 25 | 60.0 |
| Example 9 | | | (65) | (35) | (9) | (3) | | (218.4) | (33.6) | | | |

TABLE 5-2

| | | Photosensitive characteristics/Cured film characteristics | | | | | | Light-emitting characteristics of | |
|---|---|---|---|---|---|---|---|---|---|
| | | | | | Heat resistance | | Insulation | organic EL display device | |
| | | | Develop- | Cross-sectional | High-temperature | | properties | | Characteristics |
| | | | ment | shape of | weight residual | Light- | Surface | | after durability |
| | Compo- | Sensitivity | residue | pattern | ratio difference | blocking OD | resistivity | Initial | test |
| | sition | [mJ/cm²] | [%] | [°] | [mass %] | value | [Ω/□] | characteristics | [%] |
| Comparative | 25 | 25 | 35 | 70 | 7 | 1.0 | >1.0 × 10\hat{ }15 | good | 95 |
| Example 1 | | A+ | D | C | A | | | | A |
| Comparative | 26 | 65 | 13 | 35 | 7.6 | 1.0 | >1.0 × 10\hat{ }15 | good | 100 |
| Example 2 | | C | C | A | A | | | | A+ |
| Comparative | 27 | 150 | 13 | 35 | 10.1 | 1.0 | >1.0 × 10\hat{ }15 | good | 100 |
| Example 3 | | D | C | A | A | | | | A+ |
| Comparative | 28 | 220 | 13 | 30 | 12.2 | 1.0 | >1.0 × 10\hat{ }15 | good | 100 |
| Example 4 | | E | C | A+ | A | | | | A+ |
| Comparative | 29 | 35 | 35 | 20 | 36.8 | 1.0 | >1.0 × 10\hat{ }15 | good | 30 |
| Example 5 | | A | D | A+ | D | | | | E |
| Comparative | 30 | 200 | 5 | 40 | 9.0 | 1.0 | 1.0 × 10\hat{ }14 | good | 95 |
| Example 6 | | E | A | A | A | | | | A |
| Comparative | 31 | 35 | 36 | 37 | 17.2 | 1.0 | >1.0 × 10\hat{ }15 | good | 90 |
| Example 7 | | A | D | A | B | | | | A |
| Comparative | 32 | 25 | 0 | 20 | 4 | — | >1.0 × 10\hat{ }15 | good | 100 |
| Example 8 | | A+ | A+ | A+ | A+ | | | | A+ |
| Comparative | 33 | 300 | 30 | 35 | 17.5 | 3.6 | >1.0 × 10\hat{ }15 | good | 90 |
| Example 9 | | E | C | A | B | | | | A |

### Example 29

(Method of Producing Organic EL Display Device Having No Polarization Layer)

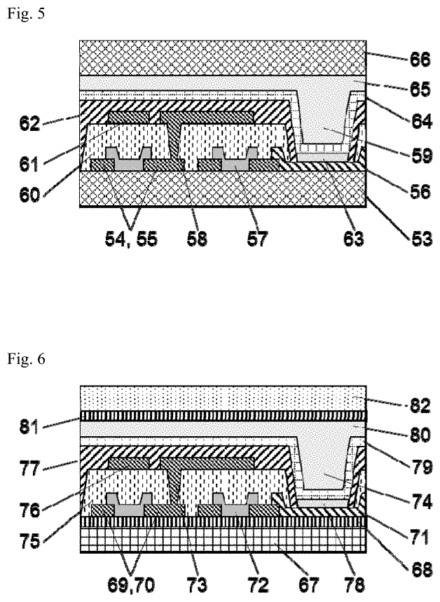

A schematic view of an organic EL display device to be produced is depicted in FIG. 5. First, a laminate film of chromium and gold was formed on a 38×46 mm non-alkali glass substrate 53 by electron beam vapor deposition, and a source electrode 54 and a drain electrode 55 were formed by etching. Next, APC (silver/palladium/copper at 98.07:0.87:1.06 (mass ratio)) was formed into a 100 nm film using a sputter and patterned by etching to form an APC layer, and furthermore, ITO was formed into a 10 nm film on the APC layer using a sputter followed by etching to form a reflecting electrode 56 as a first electrode. After the surface of the electrode was cleaned by oxygen plasma, an amorphous IGZO was formed into a film by sputtering, followed by etching to form an oxide semiconductor layer 57 between the source and drain electrodes. Next, a positive photosensitive polysiloxane material (SP-P2301; manufactured by Toray Industries, Inc.) was formed into a film by spin coating, and a via hole 58 and a pixel region 59 were opened by photolithography, followed by thermosetting to form a gate insulation layer 60. Then, gold was formed into a film by electron beam vapor deposition, and a gate electrode 61 was formed by etching to produce an oxide TFT array.

Using the above-mentioned composition 3 and using the method described in Example 1, a coating film was formed and prebaked on the oxide TFT array, subjected to patterning exposure via a photomask having a predetermined pattern, developed, and rinsed to open pixel regions, followed by thermosetting to form a TFT protection layer/pixel division layer 62 having light-blocking ability. In the above-mentioned manner, a pixel division layer was formed so as to be limited to the effective area on the substrate, wherein the pixel division layer was shaped in such a manner that the openings having a width of 70 μm and a length of 260 μm were arranged at intervals of 155 μm in the width direction and intervals of 465 μm in the length direction, and each opening allowed the reflecting electrode to be exposed. In this regard, this opening finally resulted in a light-emitting pixel of an organic EL display device. In addition, the effective area on the substrate was 16 mm square, and the pixel division layer was formed to have a thickness of approximately 1.0 μm.

Next, the compound (HT-1) as a hole injection layer, the compound (HT-2) as a hole transporting layer, the compound (GH-1) as a host material, the compound (GD-1) as a dopant material, and the compound (ET-1) and compound (LiQ) as electron transporting materials were used to form an organic EL light-emitting layer 63 in accordance with the method of producing an organic EL display device described in the above-mentioned (9).

Then, MgAg (magnesium/silver=10/1 (volume ratio)) at 10:1 was formed into a 10 nm film by vapor deposition, followed by etching to form a transparent electrode 64 as a second electrode. Then, an organic EL sealing material (STRUCT BOND (registered trademark) XMF-T; manufactured by Mitsui Chemicals, Inc.) was used under a low-humidity nitrogen atmosphere to form a sealing film 65. Furthermore, a non-alkali glass substrate 66 was adhered to the sealing film, and four 5 mm square top emission type organic EL display devices having no polarization layer were produced on one substrate. The film thickness mentioned here refers to a value displayed on a crystal oscillation type film thickness monitor.

(Light-Emitting Characteristics Evaluation)

The organic EL display device produced in the above-mentioned manner was allowed to emit light by DC drive at 10 mA/cm², and measured for the brightness (Y′) exhibited by irradiating the pixel division layer with external light and the brightness (Y₀) exhibited by irradiating the pixel division layer with no external light. As an index of decrease in reflection of external light, the contrast was calculated in accordance with the following equation. Here, the value was rounded to two decimal places.

Contrast=Y₀/Y′

The results were rated as below-mentioned; the contrast of 0.80 or more was rated as acceptable, falling under A+, A, and B; the contrast of 0.90 or more was rated as good in external light decreasing effect, falling under A+ and A; and the contrast of 0.95 or more was rated as excellent in external light decreasing effect, falling under A+. The organic EL display device produced in the above-mentioned manner exhibited a contrast of 0.90, and verified the capability to decrease the reflection of external light.

A+: a contrast of 0.95 to 1.00
A: a contrast of 0.90 to 0.94
B: a contrast of 0.80 to 0.89
C: a contrast of 0.70 to 0.79
D: a contrast of 0.50 to 0.69
E: a contrast of 0.01 to 0.49

### Example 30

(Method of Producing Flexible Organic EL Display Device Having No Polarization Layer)

A schematic view of an organic EL display device to be produced is depicted in FIG. 6. First, a PI film substrate 67 was tentatively fixed by an adhesive layer on a 38×46 mm non-alkali glass substrate, and dehydrated by baking using a hot plate (SCW-636; manufactured by Dainippon Screen Co., Ltd.) at 130° C. for 120 seconds. Next, a silicon oxide film 68 was formed as a gas barrier layer on the PI film substrate 67 by a CVD method. A laminate film of chromium and gold was formed on the gas barrier layer by electron beam vapor deposition, and a source electrode 69 and a drain electrode 70 were formed by etching. Next, APC (silver/palladium/copper at 98.07:0.87:1.06 (mass ratio)) was formed into a 100 nm film using a sputter and patterned by etching to form an APC layer, and furthermore, ITO was formed into a 10 nm film on the APC layer using a sputter followed by etching to form a reflecting electrode 71 as a first electrode. After the surface of the electrode was cleaned by oxygen plasma, an amorphous IGZO was formed into a film by sputtering, followed by etching to form an oxide semiconductor layer 72 between the source and drain electrodes. Next, a positive photosensitive polysiloxane material (SP-P2301; manufactured by Toray Industries, Inc.) was formed into a film by spin coating, and a via hole 73 and a pixel region 74 were opened by photolithography, followed by thermosetting to form a gate insulation layer 75. Then, gold was formed into a film by electron beam vapor deposition, and a gate electrode 76 was formed by etching to produce an oxide TFT array.

Using the above-mentioned composition 3 and using the method described in Example 1, a coating film was formed and prebaked on the oxide TFT array, subjected to patterning exposure via a photomask having a predetermined pattern, developed, and rinsed to open pixel regions, followed by thermosetting to form a TFT protection layer/pixel division layer 77 having light-blocking ability. In the above-mentioned manner, a pixel division layer was formed so as to be limited to the effective area on the substrate, wherein the pixel division layer was shaped in such a manner that the openings having a width of 70 μm and a length of 260 μm were arranged at intervals of 155 μm in the width direction and intervals of 465 μm in the length direction, and each opening allowed the reflecting electrode to be exposed. In this regard, this opening finally resulted in a light-emitting pixel of an organic EL display device. In addition, the effective area on the substrate was 16 mm square, and the pixel division layer was formed to have a thickness of approximately 1.0 μm.

Next, the compound (HT-1) as a hole injection layer, the compound (HT-2) as a hole transporting layer, the compound (GH-1) as a host material, the compound (GD-1) as a dopant material, and the compound (ET-1) and compound (LiQ) as electron transporting materials were used to form an organic EL light-emitting layer 78 in accordance with the method of producing an organic EL display device described in the above-mentioned (9).

Then, MgAg (magnesium/silver=10/1 (volume ratio)) was formed into a 10 nm film by vapor deposition, followed by etching to form a transparent electrode 79 as a second electrode. Then, an organic EL sealing material (STRUCT BOND (registered trademark) XMF-T; manufactured by Mitsui Chemicals, Inc.) was used under a low-humidity nitrogen atmosphere to form a sealing film 80. Furthermore, a PET film substrate 82 having a silicon oxide film 81 formed as a gas barrier layer was adhered to the sealing film, the non-alkali glass substrate was peeled away from the PI film substrate 67, and four 5 mm square top emission type flexible organic EL display devices having no polarization layer were produced on one substrate. The film thickness mentioned here refers to a value displayed on a crystal oscillation type film thickness monitor.

(Light-Emitting Characteristics Evaluation)

The organic EL display device produced in the above-mentioned manner was allowed to emit light by DC drive at 10 mA/cm², and measured for the brightness (Y′) exhibited by irradiating the pixel division layer with external light and the brightness (Y₀) exhibited by irradiating the pixel division layer with no external light. As an index of decrease in reflection of external light, the contrast was calculated in accordance with the following equation. Here, the value was rounded to two decimal places.

Contrast=Y₀/Y′

The results were rated as below-mentioned; the contrast of 0.80 or more was rated as acceptable, falling under A+, A, and B; the contrast of 0.90 or more was rated as good in external light decreasing effect, falling under A+ and A; and the contrast of 0.95 or more was rated as excellent in external light decreasing effect, falling under A+. The organic EL display device produced in the above-mentioned manner exhibited a contrast of 0.90, and verified the capability to decrease the reflection of external light.

A+: a contrast of 0.95 to 1.00
A: a contrast of 0.90 to 0.94
B: a contrast of 0.80 to 0.89
C: a contrast of 0.70 to 0.79
D: a contrast of 0.50 to 0.69
E: a contrast of 0.01 to 0.49

(Flexibility Evaluation)

The organic EL display device produced in the above-mentioned manner was allowed to emit light by DC drive at 10 mA/cm². The organic EL display device that was emitting light was curved into a U-shape with the face of the PET film, i.e. the display surface, facing outward, and retained in the state for 60 seconds, resulting in a verification that the display device did not emit abnormal light and had flexibility was made.

### REFERENCE SIGNS LIST

1 Glass substrate
2 TFT
3 Cured film for TFT planarization
4 Reflecting electrode
5a Prebaked film
5b Cured pattern
6 Mask
7 Activated actinic rays
8 Organic EL light-emitting layer
9 Transparent electrode
10 Cured film for planarization
11 Cover glass
12 Glass substrate
13 BLU
14 Glass substrate having BLU
15 Glass substrate
16 TFT
17 Cured film for TFT planarization
18 Transparent electrode
19 Planarization film
20 Alignment film
21a Prebaked film
21b Cured pattern
22 Mask
23 Activated actinic rays
24 Glass substrate having BCS
25 Glass substrate having BLU and BCS
26 Glass substrate
27 Color filter
28 Cured pattern
29 Cured film for planarization
30 Alignment film
31 Color filter substrate
32 Glass substrate having BLU, BCS, and BM
33 Liquid crystal layer
34 Glass substrate
35 PI film substrate
36 Oxide TFT
37 Cured film for TFT planarization
38 Reflecting electrode
39a Prebaked film
39b Cured pattern
40 Mask
41 Activated actinic rays
42 EL light-emitting layer
43 Transparent electrode
44 Cured film for planarization
45 Glass substrate
46 PET film substrate
47 Non-alkali Glass substrate
48 First electrode
49 Auxiliary electrode
50 Insulation layer
51 Organic EL layer
52 Second electrode
53 Non-alkali Glass substrate
54 Source electrode
55 Drain electrode
56 Reflecting electrode
57 Oxide semiconductor layer
58 Via hole
59 Pixel region
60 Gate insulation layer
61 Gate electrode
62 TFT protection layer/pixel division layer
63 Organic EL light-emitting layer
64 Transparent electrode
65 Sealing film
66 Non-alkali Glass substrate
67 PI film substrate
68 Silicon oxide film
69 Source electrode
70 Drain electrode
71 Reflecting electrode
72 Oxide semiconductor layer
73 Via hole
74 Pixel region
75 Gate insulation layer
76 Gate electrode
77 TFT protection layer/pixel division layer
78 Organic EL light-emitting layer
79 Transparent electrode
80 Sealing film
81 Silicon oxide film
82 PET film substrate

1. A negative photosensitive resin composition comprising: (A) an alkali-soluble resin, (B) a radical polymerizable compound, (C) a photo initiator, and (Da) a black pigment;
wherein said (A) alkali-soluble resin contains one or more selected from (A1-1) a polyimide, (A1-2) a polyimide precursor, (A1-3) a polybenzoxazole, and (A1-4) a polybenzoxazole precursor; and
wherein said (C) photo initiator contains at least (C1) an oxime ester photo initiator and (C2) an α-hydroxyketone photo initiator,
wherein the content ratio of said (C1) oxime ester photo initiator is 51 to 95 mass % in said (C) photo initiator, and
the content ratio of said (Da) black pigment is 5 to 50 mass % in all the solid contents of said negative photosensitive resin composition.

2. The negative photosensitive resin composition according to claim 1,
wherein the content ratio of said (C1) oxime ester photo initiator in said (C) photo initiator is 60 to 85 mass %, and
the content ratio of said (C2) α-hydroxyketone photo initiator in said (C) photo initiator is 15 to 40 mass %.

3. The negative photosensitive resin composition according to claim 1, wherein one molecule of said (C2) α-hydroxyketone photo initiator has two or more α-hydroxyketone structures.

4. The negative photosensitive resin composition according to claim 1,
wherein said (B) radical polymerizable compound contains (B1) a flexible-chain-containing aliphatic radical polymerizable compound, and said (B1) flexible-chain-containing aliphatic radical polymerizable compound has at least one modified chain selected from the group consisting of lactone modified chains and lactam modified chains.

5. The negative photosensitive resin composition according to claim 1, wherein said (Da) black pigment contains one or both of (Da-1) a black organic pigment and (Da-3) a mixture of two or more pigments of different colors mixed to assume a black color.

6. The negative photosensitive resin composition according to claim 1, wherein said (Da) black pigment contains one or more selected from the group consisting of (Da-1a) benzofuranone black pigments, (Da-1b) perylene black pigments, and (Da-1c) azo black pigments.

7. The negative photosensitive resin composition according to claim 1, which is used to form a pixel division layer of an organic EL display device having a flexible substrate containing a polyimide.

8. A cured film obtained by curing said negative photosensitive resin composition according to claim 1.

9. The cured film according to claim 8, having an optical density of 0.3 to 3.0 per 1 μm of film thickness.

10. An element comprising said cured film according to claim 8.

11. A display device comprising said cured film according to claim 8.

12. The display device according to claim 11, wherein said cured film is used as a pixel division layer, and the opening ratio of the opening of said pixel division layer in the display area is 20% or less.

13. The display device according to claim 11, wherein said display device is an organic EL display device or a liquid crystal display.

14. The display device according to claim 13, wherein a substrate for said organic EL display device has flexibility.

15. A method of producing a display device, comprising the steps of:
(1) forming a coating film of said negative photosensitive resin composition according to claim 1 on a substrate;
(2) irradiating said coating film of said negative photosensitive resin composition with activated actinic rays via a photomask;
(3) carrying out development using an alkaline solution to form a pattern of said negative photosensitive resin composition; and
(4) heating said pattern to obtain a cured pattern of said negative photosensitive resin composition.
